(19) United States
(12) Patent Application Publication
(10) Pub. No.: US 2026/0113921 A1
(43) Pub. Date: Apr. 23, 2026

(54) SEMICONDUCTOR DEVICE AND METHOD OF MANUFACTURING THE SAME

(71) Applicant: SAMSUNG ELECTRONICS CO., LTD., Suwon-si (KR)

(72) Inventors: Youngjin YANG, Suwon-si (KR); Wooseok PARK, Suwon-si (KR); Nakyoung Yang, Suwon-si (KR); Myungil KANG, Suwon-si (KR); Seunghun LEE, Suwon-si (KR); Doyoung CHOI, Suwon-si (KR)

(73) Assignee: SAMSUNG ELECTRONICS CO., LTD., Suwon-si (KR)

(21) Appl. No.: 19/304,119

(22) Filed: Aug. 19, 2025

(30) Foreign Application Priority Data
Oct. 18, 2024 (KR) 10-2024-0143252

(51) Int. Cl. H10B 10/00

(52) U.S. Cl. CPC H10B 10/125

(57) ABSTRACT

A semiconductor device includes active patterns disposed on a substrate, source/drain patterns disposed on the active patterns, channel patterns disposed on the active patterns and connected to the source/drain patterns, gate electrodes disposed on the channel patterns, active contacts disposed on source/drain patterns, an interlayer insulating layer disposed on the gate electrodes, a wiring layer disposed on the interlayer insulating layer and including a plurality of lines, and a node connection pattern connected to the gate electrode on one of the active patterns and the active contact on another of the active patterns. The interlayer insulating layer is disposed between the wiring layer and the node connection pattern to insulate the node connection pattern from the wiring layer. A level of an upper surface of the node connection pattern is different from levels of upper surfaces of other active contacts that are not connected to the node connection pattern.

### CROSS-REFERENCE TO RELATED APPLICATIONS

This U.S. non-provisional patent application claims priority under 35 U.S.C. § 119 of Korean Patent Application No. 10-2024-0143252, filed on Oct. 18, 2024, the contents of which are hereby incorporated by reference in its entirety.

### BACKGROUND

Embodiments of the present disclosure described herein relate to a semiconductor device and a method of manufacturing the same, and more particularly, relate to an SRAM cell of a semiconductor device and a method of manufacturing the semiconductor device.

A semiconductor device includes an integrated circuit with metal-oxide semiconductor field effect transistors (MOSFETs). As the size and design rules of the semiconductor device are gradually reduced, the scaling down of MOSFETs and a wiring structure connected to the MOSFETs is also accelerating. Accordingly, various methods are being studied to more easily form semiconductor devices while overcoming the limitations associated with the high integration of semiconductor devices.

### SUMMARY

Embodiments of the present disclosure provide a semiconductor device with a reduced size.

Embodiments of the present disclosure provide a method of easily manufacturing the semiconductor device.

According to an embodiment, a semiconductor device includes active patterns disposed on a front surface of a substrate, source/drain patterns disposed on the active patterns, channel patterns disposed on the active patterns and connected to the source/drain patterns, gate electrodes disposed on the channel patterns, active contacts disposed on the source/drain patterns, an interlayer insulating layer disposed on the gate electrodes, a first wiring layer disposed on the interlayer insulating layer and including a plurality of lines, and a node connection pattern connected to the gate electrode on one of the active patterns and the active contact on another of the active patterns. The interlayer insulating layer is disposed between the first wiring layer and the node connection pattern to insulate the node connection pattern from the first wiring layer. A level of an upper surface of the node connection pattern is different from levels of upper surfaces of other active contacts that are not connected to the node connection pattern.

According to an embodiment, a semiconductor device includes first and second active patterns disposed on a PMOS area of a substrate, third and fourth active patterns disposed on an NMOS area of the substrate, first, second, third, and fourth source/drain patterns disposed on the first, second, third, and fourth active patterns, active contacts disposed on the first to fourth source/drain patterns, first, second, third, and fourth channel patterns disposed on the first, second, third, and fourth active patterns, a first common gate electrode crossing the first and third active patterns and covering the first and third channel patterns, a second common gate electrode crossing the second and fourth active patterns and covering the second and fourth channel patterns, a first node contact connecting the second common gate electrode and the active contact on the first source/drain pattern adjacent to the second common gate electrode, a second node contact connecting the first common gate electrode and the active contact on the second source/drain pattern adjacent to the first common gate electrode, an interlayer insulating layer disposed on the first and second common gate electrodes, and a first wiring layer disposed on the interlayer insulating layer and including a plurality of wirings. Levels of upper surfaces of the first and second node contacts are different from levels of upper surfaces of other active contacts that are not connected to the first and second node contacts.

According to an embodiment, a semiconductor device includes active patterns disposed on a front surface of a substrate, source/drain patterns disposed on the active patterns, channel patterns disposed on the active patterns and connected to the source/drain patterns, gate electrodes disposed on the channel patterns, active contacts disposed on the source/drain patterns, an interlayer insulating layer disposed on the gate electrodes, a wiring layer disposed on the interlayer insulating layer and comprising a plurality of lines, and a node connection pattern connected to the gate electrode on one of the active patterns and the active contact on another of the active patterns. The interlayer insulating layer is disposed between the wiring layer and the node connection pattern, and the active contact connected to the node connection pattern protrudes further than one of the active contacts not connected to the node connection pattern, with respect to the substrate.

According to an embodiment, a method of manufacturing a semiconductor device includes forming an active pattern, a source/drain pattern disposed on the active pattern, a channel pattern connected to the source/drain pattern, a gate electrode disposed on the channel pattern, and an active contact disposed on the source/drain pattern on a substrate, removing a portion of the gate electrode and a portion of the active pattern to form a via hole through which a portion of the gate electrode and a portion of the active pattern are exposed, filling the via hole to form a node connection pattern, forming a pillar on the node connection pattern, etching the active contact and the gate electrode using the pillar as a mask to form a recess region, forming an interlayer insulating layer to fill the recess region, removing the pillar, filling an area from which the pillar is removed with an insulating material, and forming a first wiring layer on the interlayer insulating layer.

According to an embodiment, the semiconductor device with a reduced size is provided. In addition, the method of easily manufacturing the semiconductor device is provided.

### BRIEF DESCRIPTION OF THE FIGURES

The above and other objects and features of the present disclosure will become apparent by describing in detail embodiments thereof with reference to the accompanying drawings.

FIG. 1 is an equivalent circuit diagram illustrating an SRAM cell of a semiconductor device according to embodiment of the present disclosure;

FIG. 2 is a plan view illustrating a semiconductor device according to embodiment of the present disclosure;

FIGS. 3A to 3D are cross-sectional views respectively taken along lines A-A′, B-B′, C-C′, and D-D′ of FIG. 2;

FIG. 4A is an enlarged cross-sectional view illustrating a portion P1 of FIG. 3A;

FIG. 4B is an enlarged cross-sectional view illustrating a portion P2 of FIG. 3C;

FIG. 5 is a plan view illustrating a semiconductor device according to an embodiment of the present disclosure;

FIGS. 6A to 6D are cross-sectional views respectively taken along lines A-A′, B-B′, C-C′, and D-D′ of FIG. 5;

FIG. 7 is a plan view illustrating a semiconductor device according to an embodiment of the present disclosure;

FIGS. 8A to 8D are cross-sectional views respectively taken along lines A-A′, B-B′, C-C′, and D-D′ of FIG. 7;

FIG. 9 is a plan view illustrating a semiconductor device according to an embodiment of the present disclosure;

FIGS. 10A to 10D are cross-sectional views respectively taken along lines A-A′, B-B′, C-C′, and D-D′ of FIG. 9;

FIG. 11 is a plan view illustrating a semiconductor device according to an embodiment of the present disclosure;

FIGS. 12A to 12D are cross-sectional views respectively taken along lines A-A′, B-B′, C-C′, and D-D′ of FIG. 11;

FIG. 13 is a plan view illustrating a semiconductor device according to an embodiment of the present disclosure;

FIGS. 14A to 14D are cross-sectional views respectively taken along lines A-A′, B-B′, C-C′, and D-D′ of FIG. 13; and

FIGS. 15 to 37D are views sequentially illustrating a method of manufacturing a semiconductor device according to an embodiment of the present disclosure.

### DETAILED DESCRIPTION

Hereinafter, embodiments of the present disclosure will be described with reference to accompanying drawings.

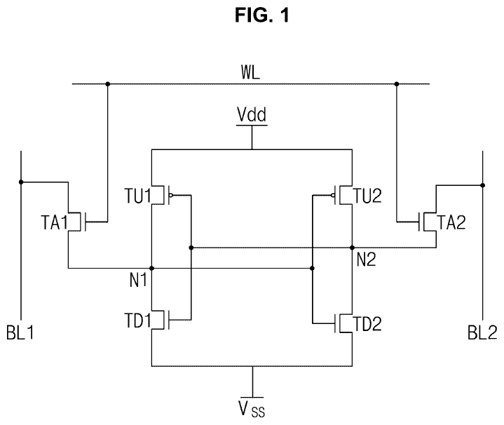

FIG. 1 is an equivalent circuit diagram illustrating an SRAM cell according to embodiment of the present disclosure. Referring to FIG. 1, the SRAM cell according to the embodiment of the present disclosure may include a first pull-up transistor TU1, a first pull-down transistor TD1, a second pull-up transistor TU2, a second pull-down transistor TD2, a first access transistor TA1, and a second access transistor TA2. The first and second pull-up transistors TU1 and TU2 may be PMOS transistors. The first and second pull-down transistors TD1 and TD2 and the first and second access transistors TA1 and TA2 may be NMOS transistors.

A first source/drain of the first pull-up transistor TU1 and a first source/drain of the first pull-down transistor TD1 may be connected to a first node N1. A second source/drain of the first pull-up transistor TU1 may be connected to a power line Vdd, and a second source/drain of the first pull-down transistor TD1 may be connected to a ground line Vss. A gate of the first pull-up transistor TU1 and a gate of the first pull-down transistor TD1 may be electrically connected to each other. The first pull-up transistor TU1 and the first pull-down transistor TD1 may form a first inverter. The gates of the first pull-up and first pull-down transistors TU1 and TD1, which are connected to each other, may correspond to an input terminal of the first inverter, and the first node N1 may correspond to an output terminal of the first inverter.

A first source/drain of the second pull-up transistor TU2 and a first source/drain of the second pull-down transistor TD2 may be connected to a second node N2. A second source/drain of the second pull-up transistor TU2 may be connected to the power line Vdd, and a second source/drain of the second pull-down transistor TD2 may be connected to the ground line Vss. A gate of the second pull-up transistor TU2 and a gate of the second pull-down transistor TD2 may be electrically connected to each other. Accordingly, the second pull-up transistor TU2 and the second pull-down transistor TD2 may form a second inverter. The gates of the second pull-up and second pull-down transistors TU2 and TD2, which are connected to each other, may correspond to an input terminal of the second inverter, and the second node N2 may correspond to an output terminal of the second inverter.

The first and second inverters may be coupled with each other to form a latch structure. That is, the gates of the first pull-up and first pull-down transistors TU1 and TD1 may be electrically connected to the second node N2, and the gates of the second pull-up and second pull-down transistors TU2 and TD2 may be electrically connected to the first node N1. A first source/drain of the first access transistor TA1 may be connected to the first node N1, and a second source/drain of the first access transistor TA1 may be connected to a first bit line BL1. A first source/drain of the second access transistor TA2 may be connected to the second node N2, and a second source/drain of the second access transistor TA2 may be connected to a second bit line BL2. Gates of the first and second access transistors TA1 and TA2 may be electrically connected to a word line WL. Thus, the SRAM cell according to the present disclosure may be implemented.

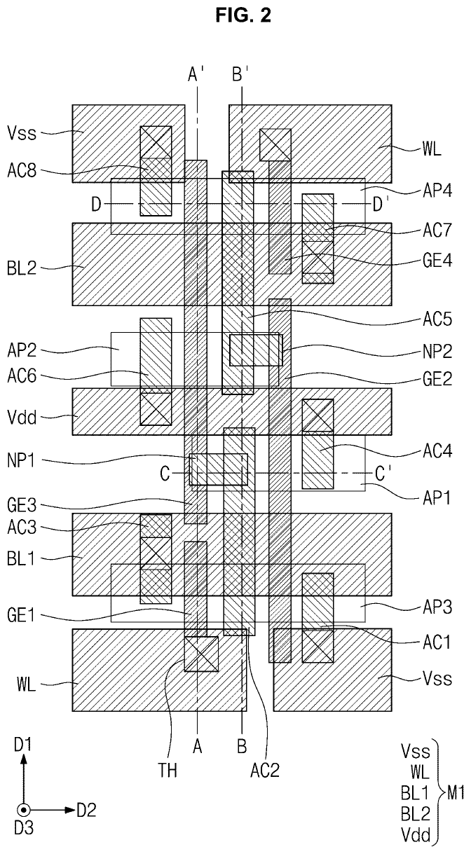

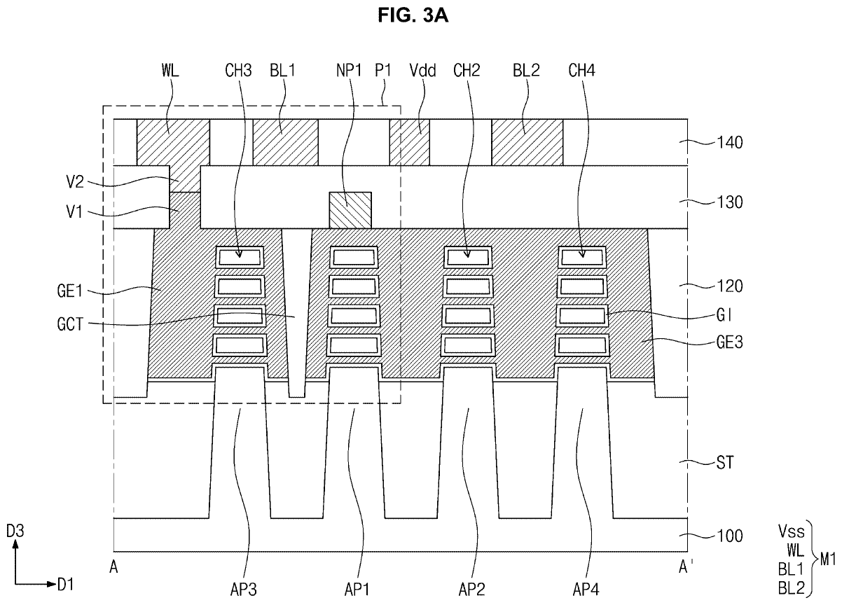

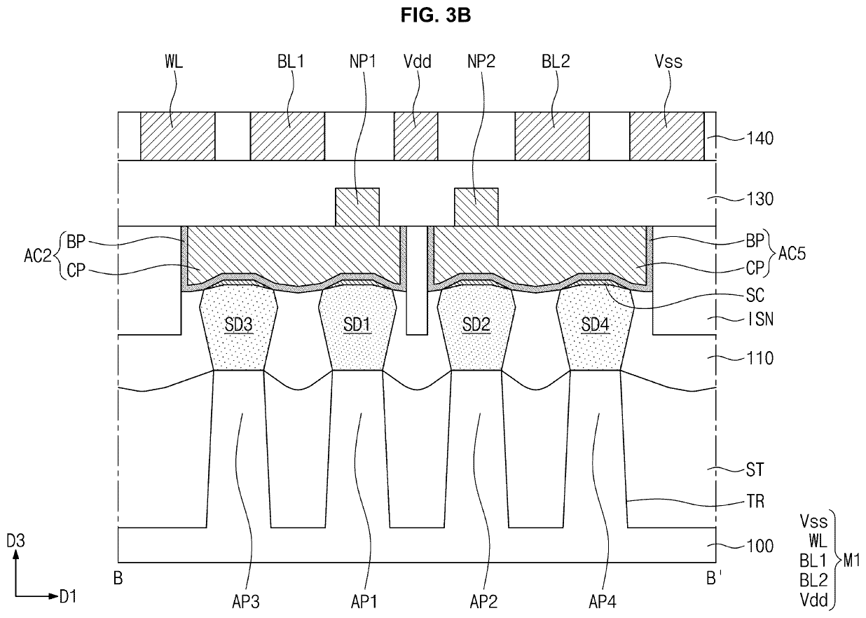

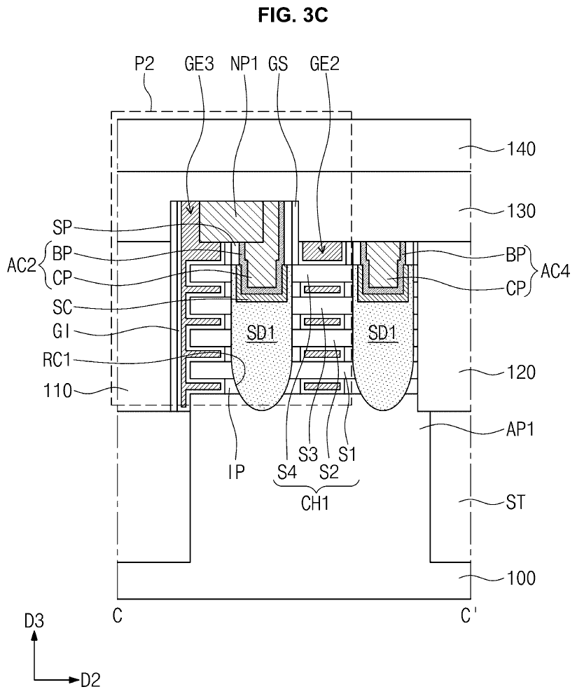

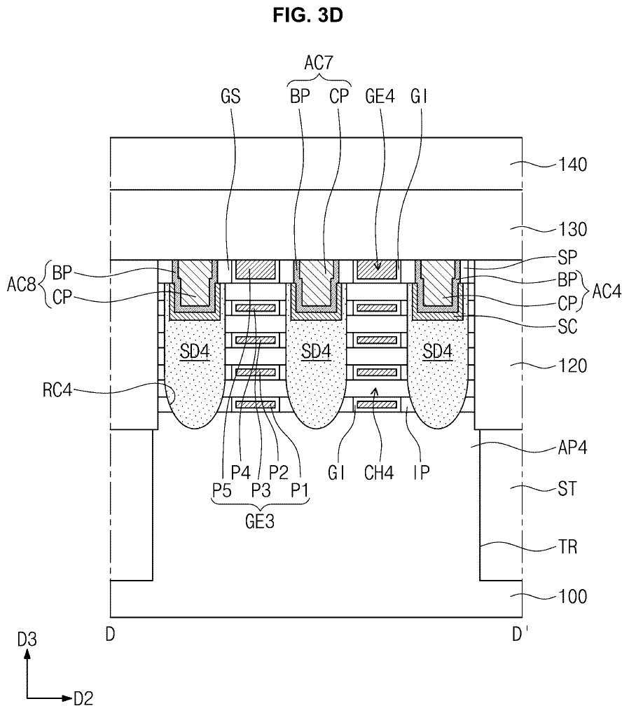

FIG. 2 is a plan view illustrating the semiconductor device according to embodiment of the present disclosure and shows the SRAM cell corresponding to the circuit diagram of FIG. 1. FIGS. 3A to 3D are cross-sectional views respectively taken along lines A-A′, B-B′, C-C′, and D-D′ of FIG. 2.

Referring to FIGS. 1, 2, and 3A to 3D, the SRAM cell may be provided on a substrate 100.

According to an embodiment of the present disclosure, the SRAM cell may be provided in plural on the substrate 100; however, in the following drawings, one SRAM cell is shown for the sake of explanation. When viewed in a plane, the SRAM cells may be arranged on the substrate 100 in a matrix form, and two SRAM cells adjacent to each other in a row direction and/or a column direction may have a mirror-symmetric shape.

The substrate 100 may be a semiconductor substrate or a compound semiconductor substrate that includes silicon, germanium, silicon germanium, or the like. The substrate 100 may include, but not be limited to, single crystalline semiconductor materials such as Si, Ge, SiGe, GaAs, InSb, GaP, GaSb, InAlAs, InGaAs, GaSbP, GaAsSb, and InP. In an embodiment, the substrate 100 may be a silicon substrate.

First, second, third, and fourth active patterns AP1, AP2, AP3, and AP4 may be defined by a trench TR formed in the substrate 100. The first active pattern AP1 and the second active pattern AP2 may correspond to a PMOS transistor area, and the third active pattern AP3 and the fourth active pattern AP4 may correspond to an NMOS transistor area. The first, second, third, and fourth active patterns AP1, AP2, AP3, and AP4 may extend in a second direction D2. The first, second, third, and fourth active patterns AP1, AP2, AP3, and AP4 may be a part of the substrate 100 and may protrude vertically. The first, second, third, and fourth active patterns AP1, AP2, AP3, and AP4 may be arranged along a first direction D1 in order of the third active pattern AP3, the first active pattern AP1, the second active pattern AP2, and the fourth active pattern AP4 and may be spaced apart from each other by a predetermined distance.

A first channel pattern CH1 disposed under a second gate electrode GE2 may form a channel region of the first pull-up transistor TU1. A third channel pattern CH3 disposed under the second gate electrode GE2 may form a channel region of the first pull-down transistor TD1. The third channel pattern CH3 disposed under a first gate electrode GE1 may form a channel region of the first access transistor TA1. A second channel pattern CH2 disposed under a third gate electrode GE3 may form a channel region of the second pull-up transistor TU2. A fourth channel pattern CH4 disposed under the third gate electrode GE3 may form a channel region of the second pull-down transistor TD2. The fourth channel pattern CH4 disposed under a fourth gate electrode GE4 may form a channel region of the second access transistor TA2.

The trenches TR may be filled with a device isolation layer ST. The device isolation layer ST may include a silicon oxide layer. Upper portions of the first, second, third, and fourth active patterns AP1, AP2, AP3, and AP4 may protrude vertically above the device isolation layer ST. The device isolation layer ST may not cover the upper portions of the first, second, third, and fourth active patterns AP1, AP2, AP3, and AP4. The device isolation layer ST may cover lower side surfaces of the first, second, third, and fourth active patterns AP1, AP2, AP3, and AP4.

The first, second, third, and fourth channel patterns CH1, CH2, CH3, and CH4 may be provided above the first, second, third, and fourth active patterns AP1, AP2, AP3, and AP4, respectively. The first and second channel patterns CH1 and CH2 may be provided to the PMOS transistor area in which the first and second active patterns AP1 and AP2 are provided, and the third and fourth channel patterns CH3 and CH4 may be provided to the NMOS transistor area in which the third and fourth active patterns AP3 and AP4 are provided. Each of the first, second, third, and fourth channel patterns CH1, CH2, CH3, and CH4 may include first, second, third, and fourth semiconductor patterns S1, S2, S3, and S4 sequentially stacked. The first, second, third, and fourth semiconductor patterns S1, S2, S3, and S4 may be spaced apart from each other in a vertical direction, i.e., a third direction D3.

Each of the first, second, third, and fourth semiconductor patterns S1, S2, S3, and S4 may include silicon (Si), germanium (Ge), or silicon-germanium (SiGe). As an example, each of the first, second, third, and fourth semiconductor patterns S1, S2, S3, and S4 may include crystalline silicon.

A plurality of first recesses RC1 may be formed in the upper portion of the first active pattern AP1. First source/drain patterns SD1 may be provided in the first recesses RC1, respectively. The first source/drain patterns SD1 may be impurity regions of a first conductivity type (e.g., p-type). The first channel pattern CH1 may be interposed between a pair of the first source/drain patterns SD1. The first channel pattern CH1 may include the first, second, third, and fourth semiconductor patterns S1, S2, S3, and S4 stacked one another. The pair of the first source/drain patterns SD1 may be connected to each other by the first channel pattern CH1.

In the same way, second, third, and fourth recesses RC2, RC3, and RC4 may be formed in the upper portions of the second, third, and fourth active patterns AP2, AP3, and AP4, respectively. Second, third, and fourth source/drain patterns SD2, SD3, and SD4 may be disposed in the second, third, and fourth recesses RC2, RC3, and RC4, respectively. The second source/drain patterns SD2 may be impurity regions of the first conductivity type (e.g., p-type). The third and fourth source/drain patterns SD3 and SD4 may be impurity regions of a second conductivity type (e.g., N-type).

The first, second, third, and fourth source/drain patterns SD1, SD2, SD3, and SD4 may be epitaxial patterns, which are formed by a selective epitaxial growth (SEG) process. As an example, an upper surface of each of the first, second, third, and fourth source/drain patterns SD1, SD2, SD3, and SD4 may be positioned at substantially the same level as an upper surface of the fourth semiconductor pattern S4 that is the uppermost semiconductor pattern. In an embodiment, the upper surface of each of the first, second, third, and fourth source/drain patterns SD1, SD2, SD3, and SD4 may be higher than the upper surface of an uppermost semiconductor pattern SP.

The first, second, third, and fourth source/drain patterns SD1, SD2, SD3, and SD4 may include the same semiconductor material as or different semiconductor material from the substrate 100. The first and second source/drain patterns SD1 and SD2 may include a semiconductor material (e.g., SiGe) whose lattice constant is greater than that of the substrate 100. In this case, the pair of the first source/drain patterns SD1 may exert a compressive stress on the first channel patterns CH1 disposed therebetween. In addition, a pair of the second source/drain patterns SD2 may exert a compressive stress on the second channel pattern CH2 disposed therebetween. The third and fourth source/drain patterns SD3 and SD4 may include the same semiconductor material (e.g., Si) as the substrate 100. As an example, the third and fourth source/drain patterns SD3 and SD4 may include single crystalline silicon.

Although not shown in figures, each of the first source/drain patterns SD1 may include a buffer layer covering an inner side surface of the first recess RC1 and a main layer filling a remaining space of the first recess RC1. In addition, each of the second source/drain patterns SD2 may include a buffer layer covering an inner side surface of the second recess RC2 and a main layer filling a remaining space of the second recess RC2.

The buffer layer may have a U-shape corresponding to a profile of each of the first recess RC1 and the second recess RC2. Each of the buffer layer and the main layer may include silicon-germanium (SiGe). In detail, the buffer layer may contain a relatively low concentration of germanium (Ge). In an embodiment, the buffer layer may contain only silicon (Si) without germanium (Ge). A concentration of germanium (Ge) in the buffer layer may be in a range from about 0 at % to about 10 at %. The main layer may contain a relatively high concentration of germanium (Ge). A concentration of germanium (Ge) in the main layer may be in a range from about 30 at % to about 70 at %. The concentration of germanium (Ge) in the main layer may increase along the third direction D3. For example, a portion of the main layer, which is adjacent to the buffer layer, may have the concentration of germanium (Ge) of about 40 at %, while an upper portion of the main layer may have the concentration of germanium (Ge) of about 60 at %. The buffer and main layers may contain a p-type impurity (e.g., boron) that allows the first and second source/drain patterns SD1 and SD2 to have a p-type conductivity. The impurity concentration (e.g., in atomic percent) in the main layer may be higher than the impurity concentration in the buffer layer.

The first, second, third, and fourth gate electrodes GE1, GE2, GE3, and GE4 may cross the first, second, third, and fourth active patterns AP1, AP2, AP3, and AP4 and may extend in the first direction D1. When viewed in the plane, the first gate electrode GE1 may cross the third active pattern AP3, the second gate electrode GE2 may cross the third active pattern AP3 and the first active pattern AP1, the third gate electrode GE3 may cross the first active pattern AP1 and the fourth active pattern AP4, and the fourth gate electrode GE4 may cross the fourth active pattern AP4. In the present disclosure, the second gate electrode GE2 may be referred to as a first common gate electrode, and the third gate electrode GE3 may be referred to as a second common gate electrode.

The first, second, third, and fourth gate electrodes GE1, GE2, GE3, and GE4 may include at least one of a conductive metal nitride, e.g., titanium nitride or tantalum nitride, and a metal material, e.g., titanium, tantalum, tungsten, copper, or aluminum.

The first gate electrode GE1 and the third gate electrode GE3 may be aligned with each other in the first direction D1. The second gate electrode GE2 and the fourth gate electrode GE4 may be aligned with each other in the first direction D1. A space between the first gate electrode GE1 and the third gate electrode GE3 may be referred to as a gate cutting region, and a second interlayer insulating layer 120 including a gate cutting pattern GCT may be disposed in the gate cutting region to separate the first gate electrode GE1 from the third gate electrode GE3. In addition, a space between the second gate electrode GE2 and the fourth gate electrode GE4 may be referred to as a gate cutting region, and the second interlayer insulating layer 120 including the gate cutting pattern GCT may be disposed in the gate cutting region to separate the second gate electrode GE2 from the fourth gate electrode GE4.

The first gate electrode GE1 may vertically overlap the third channel pattern CH3, and the second gate electrode GE2 may vertically overlap the third, first, and second channel patterns CH3, CH1, and CH2 sequentially in the first direction D1. The third gate electrode GE3 may vertically overlap the first, second, and fourth channel patterns CH1, CH2, and CH4, and the fourth gate electrode GE4 may vertically overlap the fourth channel pattern CH4.

The first gate electrode GE1 above the third active pattern AP3 may be a gate of the first access transistor TA1. The second gate electrode GE2 above the third active pattern AP3 may be a gate of the second pull-down transistor TD2, and the second gate electrode GE2 above the first active pattern AP1 may be a gate of the first pull-up transistor TU1. The third gate electrode GE3 above the second active pattern AP2 may be a gate of the second pull-up transistor TU2, and the third gate electrode GE3 above the fourth active pattern AP4 may be a gate of the first pull-down transistor TD1. The fourth gate electrode GE4 above the fourth active pattern AP4 may be a gate of the second access transistor TA2.

Each of the first, second, third, and fourth gate electrodes GE1, GE2, GE3, and GE4 may include a first portion P1 interposed between the substrate 100 and the first semiconductor pattern S1, a second portion P2 interposed between the first semiconductor pattern S1 and the second semiconductor pattern S2, a third portion P3 interposed between the second semiconductor pattern S2 and the third semiconductor pattern S3, a fourth portion P4 interposed between the third semiconductor pattern S3 and the fourth semiconductor pattern S4, and a fifth portion P5 disposed on the fourth semiconductor pattern S4. In the present embodiment, each of the first, second, third, and fourth gate electrodes GE1, GE2, GE3, and GE4 may be disposed on an upper surface, a bottom surface, and opposite side surfaces of each of the first, second, third, and fourth semiconductor patterns S1, S2, S3, and S4. In other words, an SRAM transistor according to the present embodiment may be a three-dimensional field effect transistor (e.g., MBCFET) in which a gate electrode is provided to three-dimensionally surround the channel.

A pair of gate spacers GS may be respectively disposed on opposite side surfaces of the fifth portion of each of the first, second, third, and fourth gate electrodes GE1, GE2, GE3, and GE4. The gate spacers GS may extend along the gate electrode GE and in the first direction D1. The gate spacers GS may include at least one of SiCN, SiCON, and SiN. In an embodiment, the gate spacers GS may be a multi-layer structure, which includes at least two different materials selected from SiCN, SiCON, and SiN.

A gate insulating layer GI may be interposed between each of the first, second, third, and fourth gate electrodes GE1, GE2, GE3, and GE4 and each of the first, second, third, and fourth channel patterns CH1, CH2, CH3, and CH4. The gate insulating layer GI may cover the upper surface, the bottom surface, and the opposite side surfaces of each of the first, second, third, and fourth semiconductor patterns S1, S2, S3, and S4. The gate insulating layer GI may cover an upper surface of the device isolation layer ST under the gate electrode GE.

The gate insulating layer GI may include an interfacial layer directly covering surfaces of the first, second, third, and fourth channel patterns CH1, CH2, CH3, and CH4 and a high-k dielectric layer disposed on the interfacial layer. According to an embodiment, the high-k dielectric layer may have a thickness greater than that of the interfacial layer. The interfacial layer may include a silicon oxide layer or a silicon oxynitride layer.

The high-k dielectric layer may include a high-k dielectric material whose dielectric constant is higher than that of silicon oxide. For example, the high-k dielectric material may include at least one of hafnium oxide, hafnium silicon oxide, hafnium zirconium oxide, hafnium tantalum oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, or lead zinc niobate.

Each of the first, second, third, and fourth gate electrodes GE1, GE2, GE3, and GE4 may include a first metal pattern, a second metal pattern, and an electrode pattern. The first metal pattern may be disposed on the gate insulating layer GI. As an example, the gate insulating layer GI may be disposed between the first metal pattern and the second channel pattern CH2.

The gate insulating layer GI and the first metal pattern may be chamfered, and thus, upper portions of the gate insulating layer GI and the first metal pattern may be lower than an upper surface of the gate electrode GE. As an example, the first metal pattern may include an upper surface that is recessed, and the recessed upper surface may be lower than a lowermost portion of the upper surface of the gate electrode GE.

The first metal pattern may include a metal nitride having a relatively high work function. In other words, the first metal pattern may include a P-type work-function metal. As an example, the first metal pattern may include titanium nitride (TiN), tantalum nitride (TaN), titanium oxynitride (TiON), titanium silicon nitride (TiSiN), titanium aluminum nitride (TiAlN), tungsten carbon nitride (WCN), or molybdenum nitride (MoN).

The second metal pattern may be disposed on the first metal pattern. The second metal pattern may cover the recessed upper surface of the first metal pattern. The second metal pattern may include a metal carbide having a relatively low work function. In other words, the second metal pattern may include an N-type work-function metal. The second metal pattern may include a metal carbide doped with or containing silicon and/or aluminum. As an example, the second metal pattern may include titanium carbide doped with aluminum (TiAlC), tantalum carbide doped with aluminum (TaAlC), vanadium carbide doped with aluminum (ValC), titanium carbide doped with silicon (TiSiC), or tantalum carbide doped with silicon (TaSiC). In an embodiment, the second metal pattern may include titanium carbide doped with aluminum (TiAlSiC) and silicon or tantalum carbide doped with aluminum and silicon (TaAlSiC). In an embodiment, the second metal pattern may include titanium doped with aluminum (TiAl).

In the second metal pattern, the work function of the second metal pattern may be controlled by controlling the doping concentration of the dopant, e.g., silicon or aluminum. As an example, the concentration of impurity, e.g., silicon or aluminum, in the second metal pattern may be in a range from about 0.1 at % to about 25 at %.

The electrode pattern may be disposed on the second metal pattern. The electrode pattern may have a resistance lower than the first and second metal patterns. As an example, the electrode pattern may include at least one low-resistance metal among aluminum (Al), tungsten (W), titanium (Ti), and tantalum (Ta).

Inner spacers IP may be provided between the first, second, third, and fourth source/drain patterns SD1, SD2, SD3, and SD4. The inner spacers IP may be interposed between the first to fifth portions P1 to P5 of some gate electrodes among the first, second, third, and fourth gate electrodes GE1, GE2, GE3, and GE4 and the first, second, third, and fourth source/drain patterns SD1, SD2, SD3, and SD4. The inner spacers IP may be directly in contact with the first, second, third, and fourth source/drain patterns SD1, SD2, SD3, and SD4, respectively. Each of the first, second, third, fourth, and fifth portions P1, P2, P3, P4, and P5 of some gate electrodes may be spaced apart from each of the first, second, third, and fourth source/drain patterns SD1, SD2, SD3, and SD4 by the inner spacer IP. The inner spacers IP may include one of SiN, SiCN, or SiOCN.

A first interlayer insulating layer 110 may be disposed above the substrate 100. The first interlayer insulating layer 110 may be disposed on the device isolation layer ST and may cover portions of the first, second, third, and fourth source/drain patterns SD1, SD2, SD3, and SD4.

The second interlayer insulating layer 120 including the gate cutting pattern GCT may be disposed on the first interlayer insulating layer 110. The second interlayer insulating layer 120 may be disposed on a portion of the first interlayer insulating layer 110. For instance, the second interlayer insulating layer 120 may be disposed in an area other than areas where the first, second, third, and fourth gate electrodes GE1, GE2, GE3, and GE4 and the first and second source/drain patterns SD1 and SD2 are formed.

An active contact separation pattern ISN may be disposed on the second interlayer insulating layer 120. The active contact separation pattern ISN may be disposed in an area other than areas where first, second, third, fourth, fifth, sixth, seventh, and eighth active contacts AC1, AC2, AC3, AC4, AC5, AC6, AC7, and AC8 are formed to isolate the first to eighth active contacts AC1 to AC8 from each other. The second interlayer insulating layer 120 may include one or more dielectric layers. According to an embodiment, the second interlayer insulating layer 120 may include one or more layers of SiO₂, SiN, SiCN, SiOC, SiOCN, or other suitable dielectric materials.

The first to eighth active contacts AC1 to AC8 may be disposed on the first, second, third, and fourth source/drain patterns SD1, SD2, SD3, and SD4. The first to eighth active contacts AC1 to AC8 may be electrically connected to corresponding source/drain patterns among the first, second, third, and fourth source/drain patterns SD1, SD2, SD3, and SD4.

Each of the first to eighth active contacts AC1 to AC8 may be a self-aligned contact. In other words, the first to eighth active contacts AC1 to AC8 may be formed self-aligned by the gate spacers GS.

Silicide patterns SC may be interposed between each of the first to eighth active contacts AC1 to AC8 and the first, second, third, and fourth source/drain patterns SD1, SD2, SD3, and SD4. Each of the active contacts AC1 to AC8 may be electrically connected to a corresponding source/drain pattern among the first, second, third, and fourth source/drain patterns SD1, SD2, SD3, and SD4 through the silicide pattern SC. The silicide pattern SC may include metal-silicide, for example, may include at least one of titanium-silicide, tantalum-silicide, tungsten-silicide, nickel-silicide, and cobalt-silicide.

Each of the first to eighth active contacts AC1 to AC8 may include a conductive pattern CP and a barrier pattern BP surrounding the conductive pattern CP. As an example, the conductive pattern CP may include at least one metal of aluminum, copper, tungsten, molybdenum, and cobalt. The barrier pattern BP may cover side surfaces and a bottom surface of the conductive pattern CP. The barrier pattern BP may include a metal layer/metal nitride layer. The metal layer may include at least one of titanium, tantalum, tungsten, nickel, cobalt, and platinum. The metal nitride layer may include at least one of a titanium nitride (TiN) layer, a tantalum nitride (TaN) layer, a tungsten nitride (WN) layer, a nickel nitride (NiN) layer, a cobalt nitride (CoN) layer, and a platinum nitride (PtN) layer.

In the first to eighth active contacts AC1 to AC8, a spacer SP may be disposed on an outer side surface of the barrier patterns BP. The spacer SP may be formed on the upper surface of the first, second, third, and fourth source/drain patterns SD1, SD2, SD3, and SD4, which is not covered by the silicide patterns SC, and may be disposed between the barrier patterns BP and the gate spacer GS. Due to the spacer SP, the conductive pattern CP and the barrier pattern BP may not be directly in contact with the corresponding source/drain pattern.

Among the first to eighth active contacts AC1 to AC8, upper surfaces of the first, third, fourth, sixth, seventh, and eighth active contacts AC1, AC3, AC4, AC6, AC7, and AC8 may be coplanar with an upper surface of the second interlayer insulating layer 120 and upper surfaces of the active contact separation pattern ISN. Upper surfaces of the second and fifth active contacts AC2 and AC5 may be provided at different levels from the upper surfaces of the first, third, fourth, sixth, seventh, and eighth active contacts AC1, AC3, AC4, AC6, AC7, and AC8. As an example, the upper surfaces of the second and fifth active contacts AC2 and AC5 may be provided at a higher position than the upper surfaces of the first, third, fourth, sixth, seventh, and eighth active contacts AC1, AC3, AC4, AC6, AC7, and AC8.

A first node connection pattern NP1 may be disposed on the third gate electrode GE3 and the second active contact AC2, and a second node connection pattern NP2 may be disposed on the second gate electrode GE2 and the fifth active contact AC5. The first node connection pattern NP1 may connect the third gate electrode and the second active contact AC2, and the second node connection pattern NP2 may connect the second gate electrode GE2 and the fifth active contact AC5. In the present disclosure, the second active contact AC2 may be referred to as a first node contact. In addition, the fifth active contact AC5 may be referred to as a second node contact.

The first node connection pattern NP1 may correspond to the first node N1 of FIG. 1, which electrically connects the source/drain of the first pull-up and first pull-down transistors TU1 and TD1 to the gate of the second pull-up and second pull-down transistors TU2 and TD2.

The second node connection pattern NP2 may correspond to the second node N2 of FIG. 1, which electrically connects the source/drain of the second pull-up and second pull-down transistors TU2 and TD2 to the gate of the first pull-up and first pull-down transistors TU1 and TD1.

A third interlayer insulating layer 130 may be disposed on the first, second, third, and fourth gate electrodes GE1, GE2, GE3, and GE4, the first and second node connection patterns NP1 and NP2, and the first to eighth active contacts AC1 to AC8.

A fourth interlayer insulating layer 140 may be disposed on the third interlayer insulating layer 130.

A first wiring layer M1 may be disposed in the fourth interlayer insulating layer 140. The first wiring layer M1 may include the word line WL, the first bit line BL1, the second bit line BL2, the power line Vdd, and the ground line Vss. One or more wiring layers may be disposed on the first wiring layer M1.

The first wiring layer M1 may include a variety of conductive materials. The first wiring layer M1 may include at least one of a conductive metal nitride (e.g., titanium nitride or tantalum nitride) and a metal material (e.g., titanium, tantalum, tungsten, copper, or aluminum).

The first bit line BL1, the second bit line BL2, and the power line Vdd may extend in the second direction D2 and may be parallel to each other. The word line WL and the ground line Vss may be aligned parallel to each other along the second direction D2.

Each of the word line WL, the first bit line BL1, the second bit line BL2, the power line Vdd, and the ground line Vss may be connected to a corresponding contact or electrode among the first to eighth active contacts AC1 to AC8 and the first, second, third, and fourth gate electrodes GE1, GE2, GE3, and GE4 via through-holes TH defined through the third interlayer insulating layer 130. A first via V1 and a second via V2, which are in contact with each other, may be disposed in each through-hole. The first via V1 may protrude upward from one of the first to eighth active contacts AC1 to AC8 and the first, second, third, and fourth gate electrodes GE1, GE2, GE3, and GE4, and the second via V2 may protrude downward from the first wiring layer M1.

As an example, the word line WL may be connected to the first gate electrode GE1 and the fourth gate electrode GE4 through the through-holes TH. The ground line Vss may be connected to the eighth active contact AC8 and the first active contact AC1 through the through-holes TH. The power line Vdd may be connected to the sixth active contact AC6 and the fourth active contact AC4 through the through-holes TH. The first bit line BL1 may be connected to the third active contact AC3 through the through-holes TH, and the second bit line BL2 may be connected to the seventh active contact AC7 through the through-holes TH.

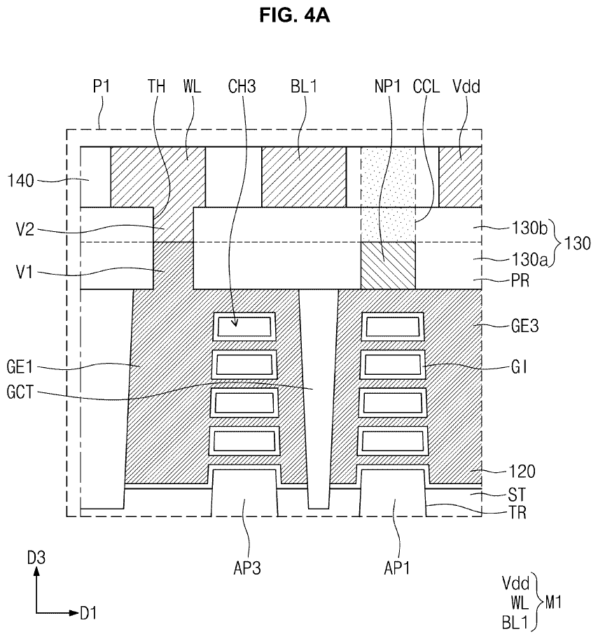

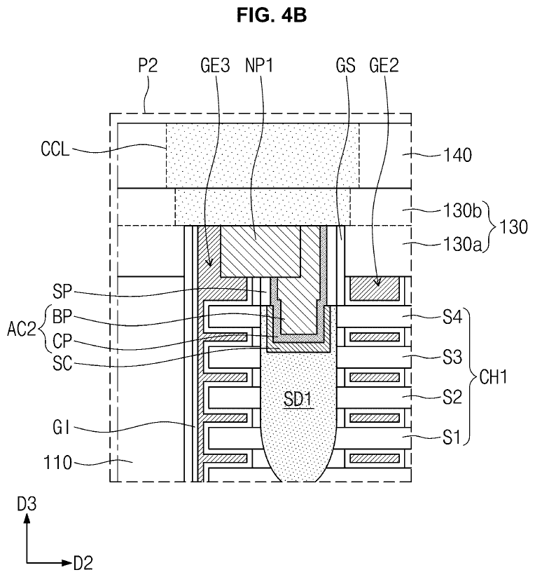

FIG. 4A is an enlarged cross-sectional view illustrating a portion P1 of FIG. 3A, and FIG. 4B is an enlarged cross-sectional view illustrating a portion P2 of FIG. 3C.

Referring to FIGS. 1, 2, 3A to 3D, 4A, and 4B, the first node connection pattern NP1 and the second node connection pattern NP2 may be disposed on the third gate electrode GE3 and the second gate electrode GE2, respectively.

The first node connection pattern NP1 may connect the third gate electrode GE3 and the second active contact AC2. The first node connection pattern NP1 may have a bar shape extending in the second direction D2. When viewed in the plane, one end of the first node connection pattern NP1 may overlap the third gate electrode GE3, and the other end of the first node connection pattern NP1 may overlap the second active contact AC2. When viewed in the cross-section, one side surface and a portion of a lower surface of the first node connection pattern NP1 may be in contact with the third gate electrode GE3, and the other side surface and the other portion of the lower surface of the first node connection pattern NP1 may be in contact with the second active contact AC2. As an example, the side surface of the first node connection pattern NP1 may be directly in contact with the conductive pattern CP of the first active contact AC1, and the lower surface of the first node connection pattern NP1 may be in contact with the conductive pattern CP and the barrier pattern BP of the second active contact AC2. The lower surface of the first node connection pattern NP1 may also be in contact with the gate insulating layer GI and the gate spacer GS. An upper surface of the first node connection pattern NP1 may be coplanar with an upper surface of the third gate electrode GE3 and the upper surface of the second active contact AC2.

According to an embodiment, the first node connection pattern NP1 may be provided separately from the third gate electrode GE3 and the second active contact AC2 and may be in contact with each of the third gate electrode GE3 and the second active contact AC2. That is, an interface between the first node connection pattern NP1 and the third gate electrode GE3 and an interface between the first node connection pattern NP1 and the second active contact AC2 may clearly exist. However, according to an embodiment, the first node connection pattern NP1 may be combined with the third gate electrode GE3 and/or the second active contact AC2 by a single metal contact. As an example, according to an embodiment, the first node connection pattern NP1 may be combined with the second active contact AC2 by a single metal contact.

According to an embodiment, the first node connection pattern NP1 may include the same material as at least a portion of the second active contact AC2. As an example, the first node connection pattern NP1 may include the same material as the conductive pattern CP of the second active contact AC2.

The second node connection pattern NP2 may connect the second gate electrode GE2 and the fifth active contact AC5. The second node connection pattern NP2 may have a bar shape extending in the second direction D2. When viewed in the plane, one end of the second node connection pattern NP2 may overlap the fifth active contact AC5, and the other end of the second node connection pattern NP2 may overlap the second gate electrode GE2.

The second node connection pattern NP2 may be in contact with each of the second gate electrode GE2 and the fifth active contact AC5. In addition, the second node connection pattern NP2 may be combined with the second gate electrode GE2 and/or the fifth active contact AC5 by a single metal contact.

Although not shown in figures, when viewed in the cross-section, one side surface and a portion of a lower surface of the second node connection pattern NP2 may be in contact with the fifth active contact AC5, and the other side surface and a portion of the lower surface of the second node connection pattern NP2 may be in contact with the second gate electrode GE2. According to an embodiment, the side surface of the second node connection pattern NP2 may be directly in contact with the conductive pattern CP of the fifth active contact AC5, and the lower surface of the second node connection pattern NP2 may be in contact with the conductive pattern CP and the barrier pattern BP of the fifth active contact AC5. The lower surface of the second node connection pattern NP2 may also be in contact with the gate insulating layer GI and the gate spacer GS. An upper surface of the second node connection pattern NP2 may be coplanar with an upper surface of the second gate electrode GE2 and the upper surface of the fifth active contact AC5.

The second node connection pattern NP2 may include the same material as at least a portion of the fifth active contact AC5. As an example, the second node connection pattern NP2 may include the same material as the conductive pattern CP of the fifth active contact AC5.

The third interlayer insulating layer 130 may be disposed on the first and second node connection patterns NP1 and NP2, the first to eighth active contacts AC1 to AC8, and the first, second, third, and fourth gate electrodes GE1, GE2, GE3, and GE4. In particular, the third interlayer insulating layer 130 may cover the upper surface of the first and second node connection patterns NP1 and NP2.

The third interlayer insulating layer 130 may include a main interlayer insulating layer 130b provided between the first wiring layer M1 and the first and second node connection patterns NP1 and NP2 and a recess filling insulating layer 130a disposed under the main interlayer insulating layer 130b. The main interlayer insulating layer 130b may be disposed on the first and second node connection patterns NP1 and NP2, and the recess filling insulating layer 130a may be disposed between the main interlayer insulating layer 130b and the upper surfaces of the gate electrodes and the active contacts, which are not connected to the first and second node connection patterns NP1 and NP2. In the present embodiment, for the convenience of explanation, the interlayer insulating layer 130 is shown as including the main interlayer insulating layer 130b and the recess filling insulating layer 130a, however, the main interlayer insulating layer 130b and the recess filling insulating layer 130a may be formed integrally with each other without being separated from each other. The recess filling insulating layer 130a may be disposed in a recess region RR recessed downward from a plane corresponding to the upper surface of the first and second node connection patterns NP1 and NP2. The recess region RR may correspond to an area between the main interlayer insulating layer and the upper surface of the first to fourth gate electrodes GE1 to GE4 and the upper surface of the first to eighth active contacts AC1 to AC8.

The through-holes TH that vertically penetrate the third interlayer insulating layer 130 may be provided inside the third interlayer insulating layer 130. The first via V1 and the second via V2 may be sequentially disposed in each of the through-holes TH. The first via V1 in each through-hole TH may be connected to one of the first to eighth active contacts AC1 to AC8 and the first, second, third, and fourth gate electrodes GE1, GE2, GE3, and GE4, and the second via V2 in each through-hole TH may be connected to one of the first wiring layers M1. An upper surface of the first vias V1 may be substantially coplanar with the upper surface of the first and second node connection patterns NP1 and NP2. An upper surface of the second vias V2 may be substantially coplanar with an upper surface of the third interlayer insulating layer 130.

Although not shown in figures, in the embodiments of the present disclosure, the first and/or second node connection patterns NP1 and/or NP2 may include the conductive pattern and the barrier pattern surrounding the conductive pattern. In this case, the first and/or second node connection patterns NP1 and/or NP2 may include the same material as the barrier pattern BP and the conductive pattern of the first to eighth active contacts AC1 to AC8.

According to some embodiments, the first wiring layer M1 may be used for node connection on the circuit of the SRAM cell. That is, node connection lines may be necessary to connect some of the gate electrodes and some of the active contacts, and the node connection lines may be some of lines in the first wiring layer M1.

A node connection line CCL, when formed as the line of the first wiring layer M1, is represented by a dotted line in FIGS. 4A and 4B.

Referring to FIGS. 4A and 4B, the node connection line CCL that connects the third gate electrode GE3 and the second active contact AC2 may be formed, and the node connection line CCL that connects the second gate electrode GE2 and the sixth active contact AC6 may be formed. The node connection lines CCL may be included in the first wiring layer M1 and formed on the third interlayer insulating layer 130 along with the first and second bit lines BL1 and BL2, the word line WL, the power line Vdd, and the ground line Vss. In the present embodiment, a portion the gate electrode (e.g., the third gate electrode GE3) and a portion of the active contacts (the second active contact AC2), which are connected by the node connection lines CCL, may be disposed under the third interlayer insulating layer 130. Accordingly, to connect the portion of the gate electrodes and the portion of active contacts, the gate spacer GP and other components are required to be removed. Furthermore, a process of forming a connection via in the third interlayer insulating layer 130 by removing a portion of the third interlayer insulating layer 130 is required. The process of removing the portion of the third interlayer insulating layer 130 means that an additional mask process is required.

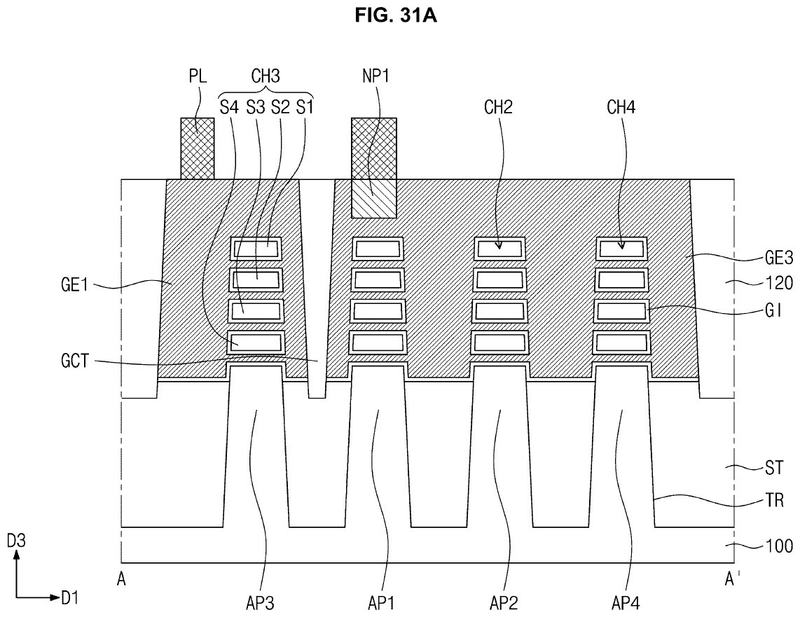

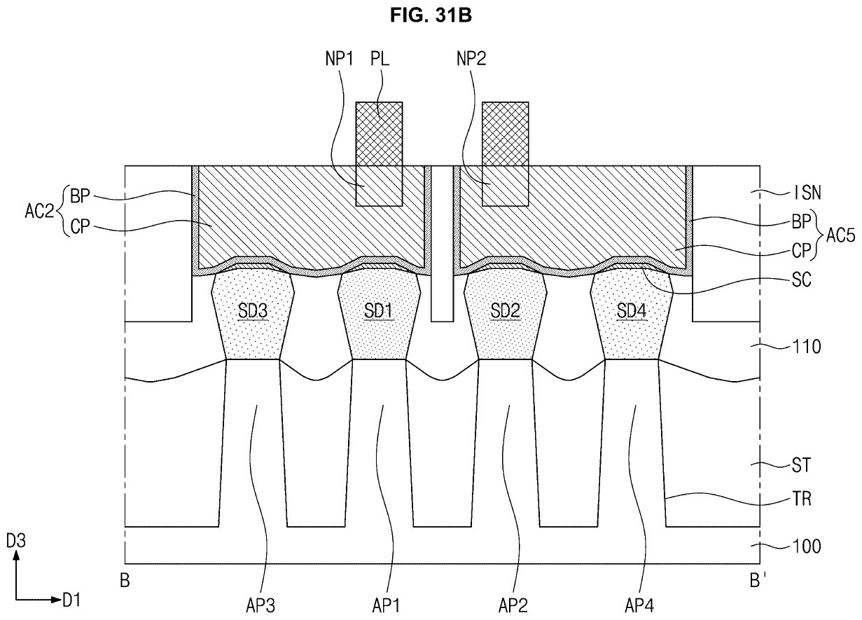

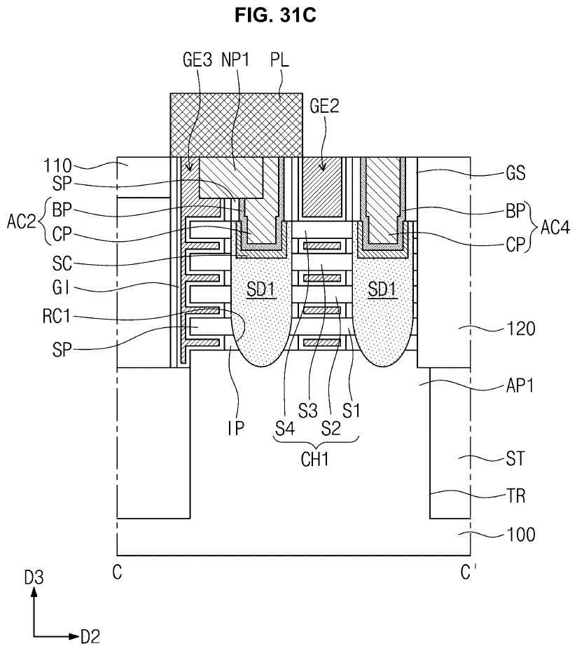

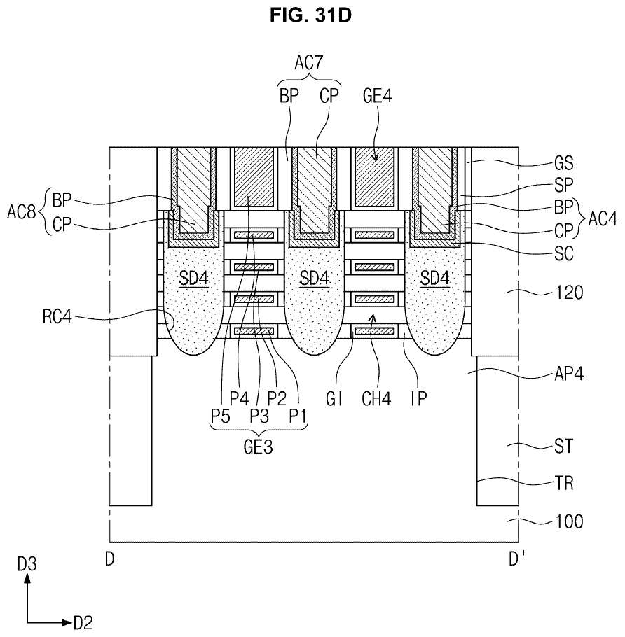

According to an embodiment of the present disclosure, the first node connection pattern NP1 and the second node connection pattern NP2 may connect the portion of the gate electrodes and the portion of the active patterns without being connected to the first wiring layer M1. That is, the first node connection pattern NP1 may be provided separately from the first wiring layer M1 between the third gate electrode GE3 and the second active contact AC2 and may connect the third gate electrode GE3 and the second active contact AC2. In addition, the second node connection pattern NP2 may be provided separately from the first wiring layer M1 between the second gate electrode GE2 and the sixth active contact AC6 and may connect the second gate electrode GE2 and the sixth active contact AC6. In the present embodiment, the first and second node connection patterns NP1 and NP2 may be physically and electrically insulated from the first wiring layer M1, and the third interlayer insulating layer 130 may be disposed between the first and second node connection patterns NP1 and NP2 and the first wiring layer M1 when viewed in the cross-section. Consequently, according to the present disclosure, the first and second node connection patterns NP1 and NP2 may be disposed under the third interlayer insulating layer 130, and the process of removing the portion of the third interlayer insulating layer 130 may be omitted. According to an embodiment, the first and second node connection patterns NP1 and NP2 may be easily formed instead of the node connection lines CCL by using the first wiring layer M1 and pillars PL (refer to FIGS. 31A to 31D), which are used to form the vias V1 and V2 for connecting the gate electrodes and the active contacts.

The semiconductor device according to embodiments of the present disclosure may be modified into various forms without departing from the concept of the present disclosure.

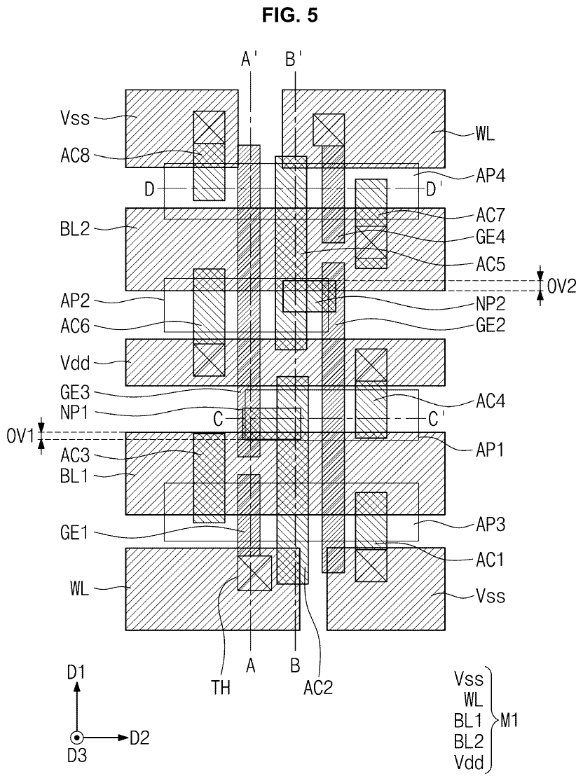

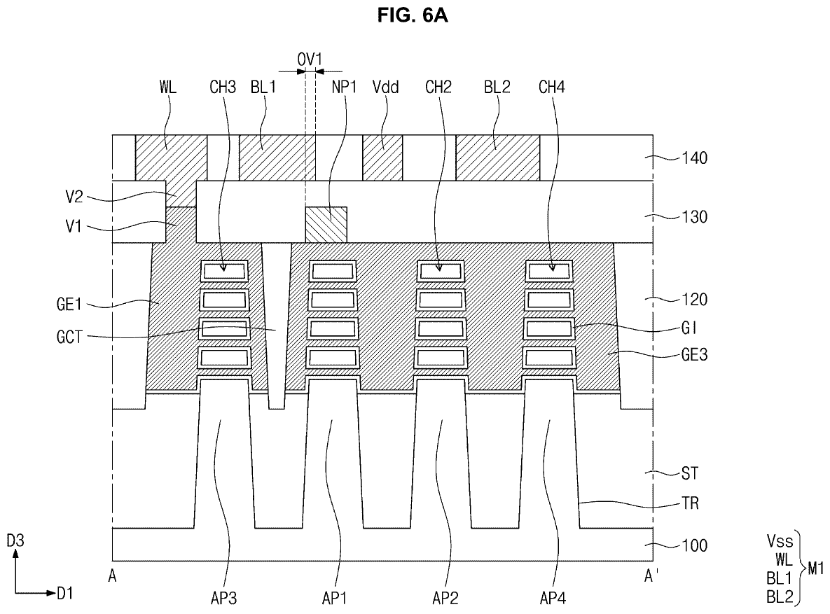

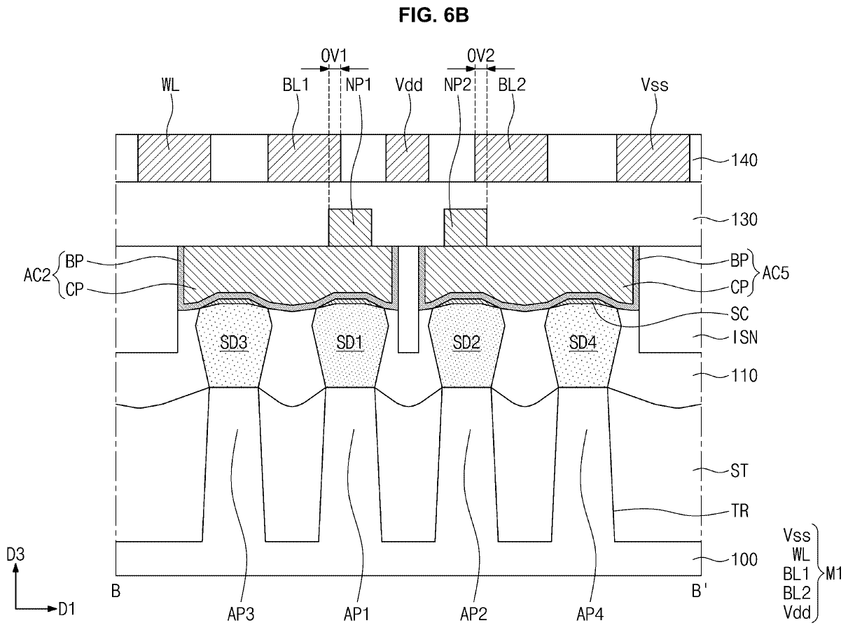

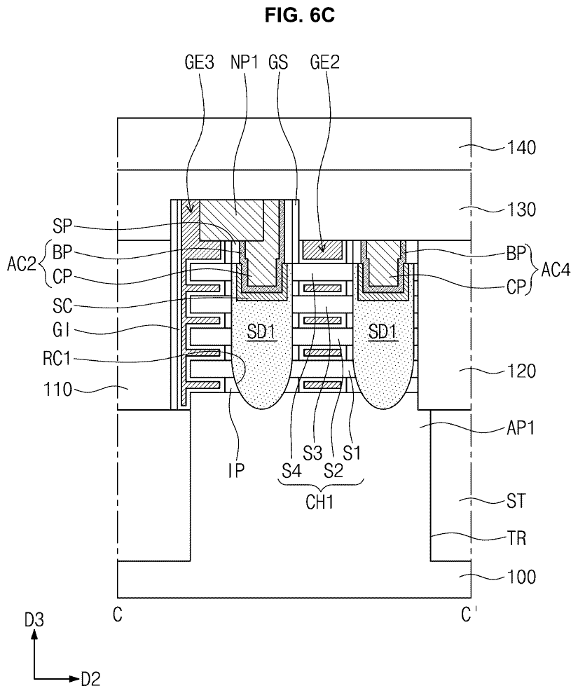

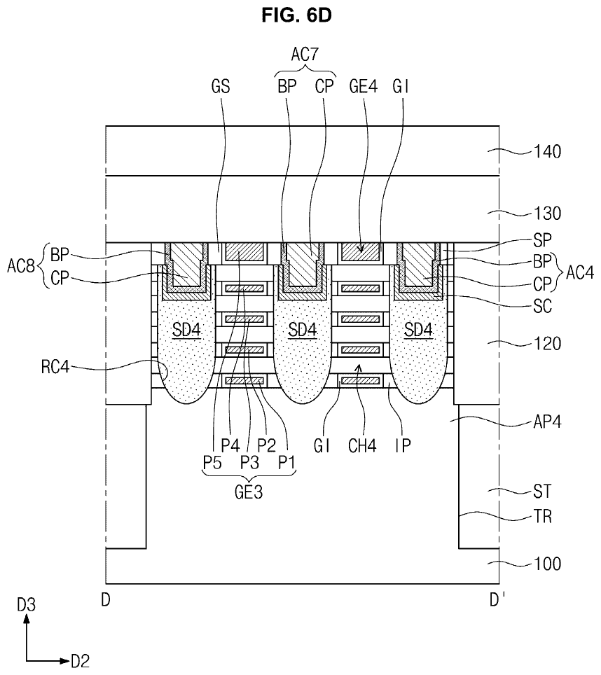

FIG. 5 is a plan view illustrating a semiconductor device according to an embodiment of the present disclosure. FIGS. 6A to 6D are cross-sectional views respectively taken along lines A-A′, B-B′, C-C′, and D-D′ of FIG. 5.

An SRAM cell according to the present embodiment may include substantially the same components as those of the SRAM cell illustrated in FIGS. 2 and 3A to 3D; however, the SRAM cell according to the present embodiment differs from the above-described embodiment in the size and arrangement relationship of some components. Hereinafter, for the convenience of explanation, different features from the above-described embodiment will be mainly described.

Referring to FIGS. 5 and 6A to 6D, first, second, third, and fourth active patterns AP1, AP2, AP3, and AP4 may be defined by a trench TR formed in a substrate 100.

First, second, third, and fourth gate electrodes GE1, GE2, GE3, and GE4 may cross the first, second, third, and fourth active patterns AP1, AP2, AP3, and AP4 and may extend in the first direction D1.

A first node connection pattern NP1 may be disposed on the third gate electrode GE3, and a second node connection pattern NP2 may be disposed on the second gate electrode GE2. The first node connection pattern NP1 may connect the third gate electrode GE3 and the second active contact AC2, and the second node connection pattern NP2 may connect the second gate electrode GE2 and the fifth active contact AC5.

A third interlayer insulating layer 130 may be disposed on the first and second node connection patterns NP1 and NP2. A fourth interlayer insulating layer 140 may be disposed on the third interlayer insulating layer 130, and a first wiring layer M1 may be disposed in the fourth interlayer insulating layer 140. The first wiring layer M1 may include a word line WL, a first bit line BL1, a second bit line BL2, a power line Vdd, and a ground line Vss.

In the present embodiment, at least one of the first node connection pattern NP1 and the second node connection pattern NP2 may overlap at least one of elements of the first wiring layer M1 when viewed in the plane. As an example, the first node connection pattern NP1 may overlap the first bit line BL1, and the second node connection pattern NP2 may overlap the second bit line BL2. In FIGS. 5, 6A, and 6B, an area where the first node connection pattern NP1 overlaps the first bit line BL1 and an area where the second node connection pattern NP2 overlaps the second bit line BL2 when viewed in the cross-section are indicated as a first overlapping area OV1 and a second overlapping area OV2, respectively.

According to an embodiment of the present disclosure, there is no need to form separate node connection lines in the first wiring layer M1 to connect some of the gate electrodes and some of the active contacts. As the node connection lines of the first wiring layer M1 are omitted, a gap between the first bit line BL1 and the power line and a gap between the power line and the second bit line BL2 may decrease. In addition, the first and second node connection patterns NP1 and NP2 may be formed to overlap one or more of the lines of the first wiring layer M1. As a result, the size of the SRAM cell, e.g., a width in the first direction D1 of the SRAM cell, may be reduced.

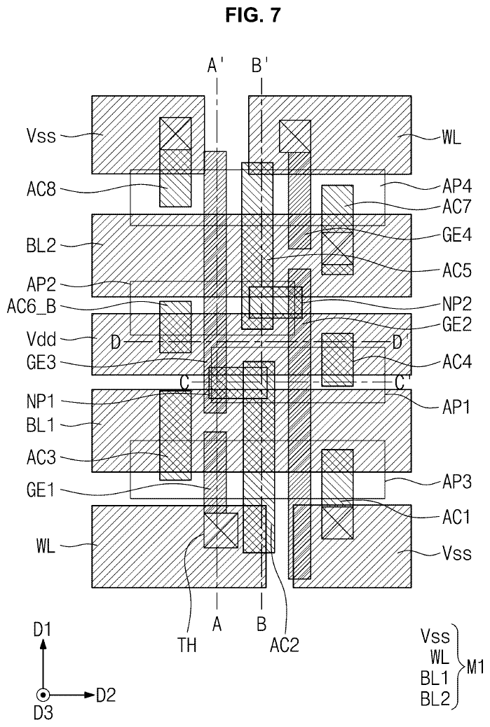

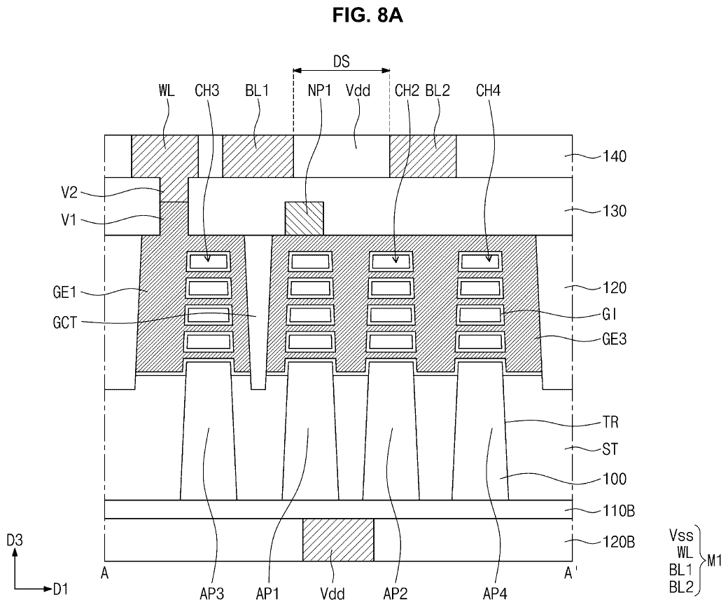

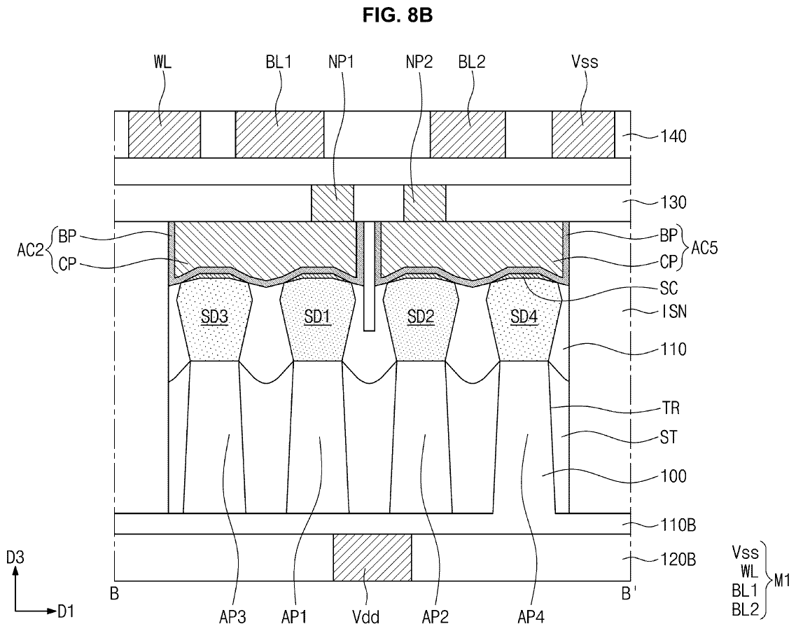

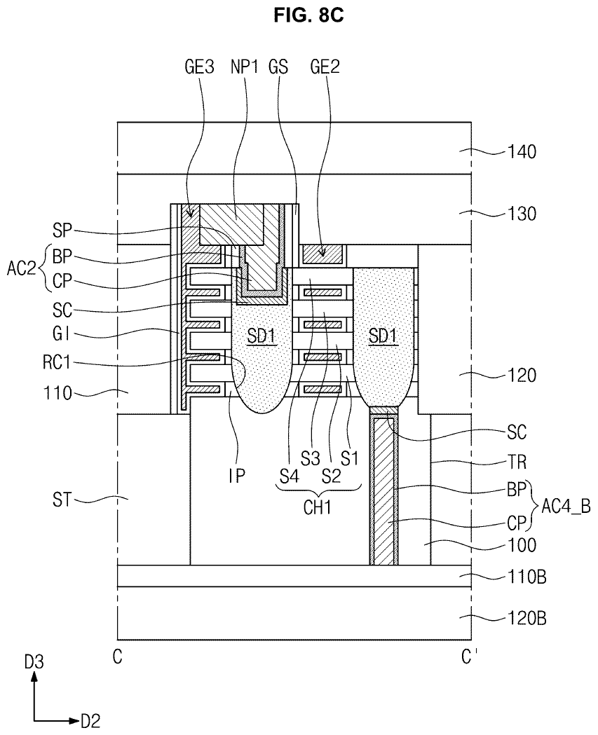

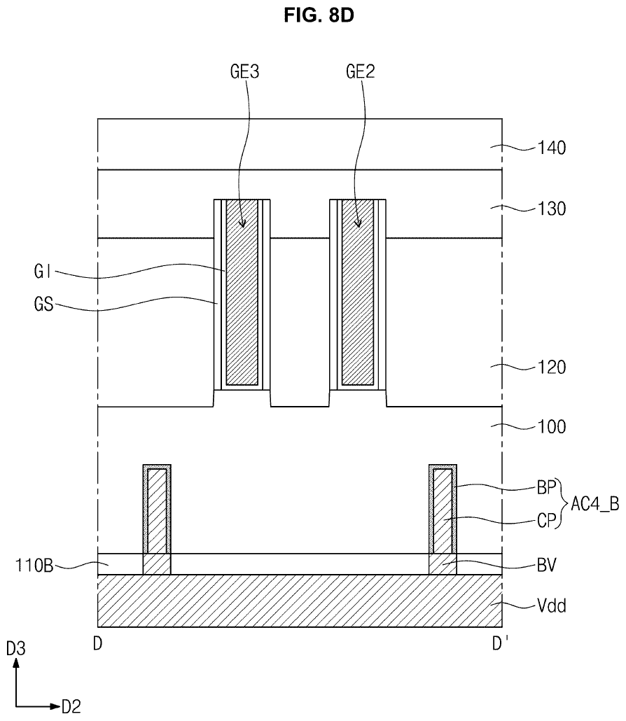

FIG. 7 is a plan view illustrating a semiconductor device according to an embodiment of the present disclosure. FIGS. 8A to 8D are cross-sectional views respectively taken along lines A-A′, B-B′, C-C′, and D-D′ of FIG. 7.

Referring to FIGS. 7 and 8A to 8D, first, second, third, and fourth active patterns AP1, AP2, AP3, and AP4 may be defined by a trench TR formed in a substrate 100. The first active pattern AP1 and the second active pattern AP2 may correspond to a PMOS transistor area, and the third active pattern AP3 and the fourth active pattern AP4 may correspond to an NMOS transistor area.

The first, second, third, and fourth active patterns AP1, AP2, AP3, and AP4 may extend in the second direction D2. The trenches TR may be filled with a device isolation layer ST. The device isolation layer ST may penetrate through a front surface and a rear surface of the substrate 100. To allow the device isolation layer ST to penetrate the front surface and the rear surface of the substrate 100, the substrate 100 may be patterned to form the trenches TR having a selected depth in the substrate 100, the device isolation layer ST may be formed in the trenches TR, and the rear surface of the substrate 100 may be patterned until the device isolation layer ST is exposed.

First, second, third, and fourth source/drain patterns SD1, SD2, SD3, and SD4 may be connected to a word line WL, first and second bit lines BL1 and BL2, a ground line Vss, and a power line Vdd through corresponding active contacts. In the present embodiment, a first wiring layer M1 may include the first and second bit lines BL1 and BL2, the word line WL, and the ground line Vss, and the power line Vdd may not be included in the first wiring layer M1. In detail, the first and second bit lines BL1 and BL2, the word line WL, and the ground line Vss may be formed on the front surface of the substrate 100, and the power line Vdd may be formed on the rear surface of the substrate 100. In the present embodiment, when a surface of the substrate 100 on which transistors including first, second, third, and fourth gate electrodes GE1, GE2, GE3, and GE4 and first, second, third, and fourth channel patterns CH1, CH2, CH3, and CH4 are formed is referred to as the front surface, the rear surface may be a surface opposite to the front surface.

Since the power line Vdd is formed on the rear surface of the substrate 100, a fourth active contact AC4 and a sixth active contact AC6 that are connected to the power line Vdd among first to eighth active contacts AC1 to AC8 of the above-described embodiments may have a rear surface active contact structure. The rear surface active contact structure means that the first source/drain pattern SD1 is connected to the line of the rear surface of the substrate 100. The rear surface active contact structure may include a fourth rear surface active contact AC4_B connecting one of the first source/drain patterns SD1 to the power line Vdd and a sixth rear surface active contact AC6_B connecting one of the second source/drain patterns SD2 to the power line Vdd. The fourth and sixth rear surface active contacts AC4_B and AC6_B may be disposed in the substrate 100 and may extend from the rear surface of the substrate 100 to a lower portion of the first source/drain patterns SD1 along the third direction D3.

One or more rear surface wiring layers may be provided on the rear surface of the substrate 100. The rear surface wiring layer may include at least one wiring. For example, the rear surface wiring layer may include a backside power delivery network. The power line Vdd may be a portion of the rear surface wiring layer, and in detail, may be a portion of the backside power delivery network.

The power line Vdd may extend in the second direction D2. However, the direction in which the power line Vdd extends should not be limited thereto or thereby and the power line Vdd may extend in various directions depending on the configuration of the backside power delivery network. The power line Vdd may include a variety of conductive materials. The power line Vdd may include at least one of a conductive metal nitride (e.g., titanium nitride or tantalum nitride) and a metal material (e.g., titanium, tantalum, tungsten, copper, or aluminum).

Each of the fourth rear surface active contact AC4_B and the sixth rear surface active contact AC6_B may include a conductive pattern CP and a barrier pattern BP.

A first rear surface interlayer insulating layer 110B may be provided between the power line Vdd and the rear surface of the substrate 100. The power line Vdd may be electrically connected to the fourth and sixth rear surface active contacts AC4_B and AC6_B through rear surface vias BV penetrating the first rear surface interlayer insulating layer 110B and disposed in the first rear surface interlayer insulating layer 110B.

According to the present embodiment, the power line Vdd is disposed on the rear surface of the substrate 100, however, the present disclosure should not be limited thereto or thereby. According to an embodiment, another line among the lines of the first wiring layer M1 may be disposed on the rear surface of the substrate 100. As an example, the ground line Vss may be disposed on the rear surface. In this case, a power delivery network layer PDN may include lines to apply a ground voltage to the ground lines Vss in addition to lines to apply a power voltage to the power lines Vdd.

The word line WL, the first and second bit lines BL1 and BL2, and the ground line Vss, except the power line Vdd, may be connected to corresponding first, second, third, and fourth source/drain patterns SD1, SD2, SD3, and SD4 through the first, second, and third active contacts AC1, AC2, and AC3, the fifth active contact AC5, the seventh active contact AC7, and the eighth active contact AC8.

According to an embodiment, at least one of a first node connection pattern NP1 and a second node connection pattern NP2 may overlap at least one of elements of the first wiring layer M1 when viewed in the plane. As an example, the first node connection pattern NP1 may overlap the first bit line BL1, and the second node connection pattern NP2 may overlap the second bit line BL2.

According to the present embodiment, as the power line Vdd is disposed on the rear surface, a gap between the lines of the first wiring layer M1 may decrease. In particular, since the power line Vdd among the lines of the first wiring layer M1 is omitted, the gap between the first bit line BL1 and the second bit line BL2 may decrease. In addition, since the first and second node connection patterns NP1 and NP2 overlap some of the lines of the first wiring layer M1, e.g., the first bit line BL1 and/or the second bit line BL2, the gap between the lines of the first wiring layer M1 may further decrease. As a result, a scale of an SRAM cell, e.g., a width in the first direction D1 of the SRAM cell, may be reduced.

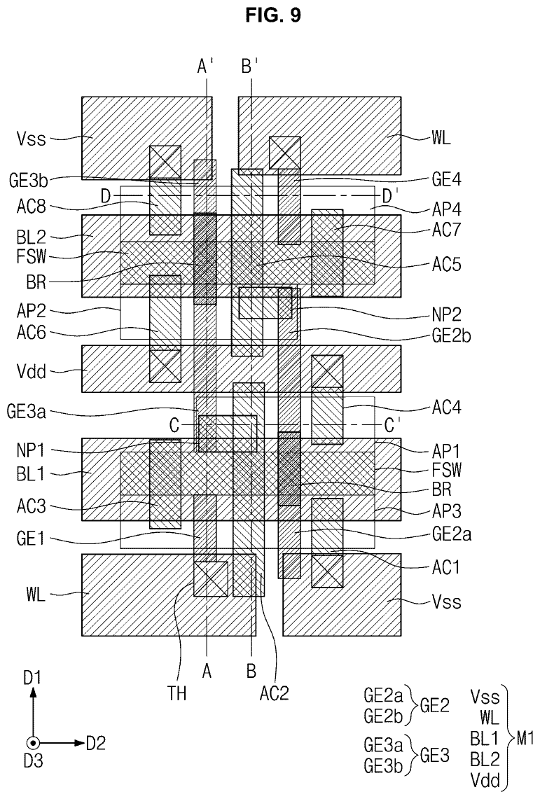

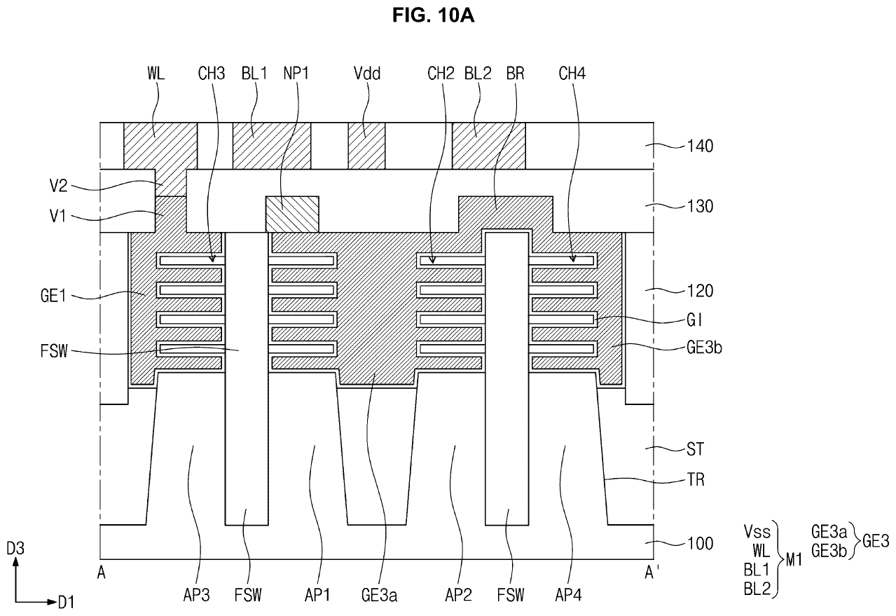

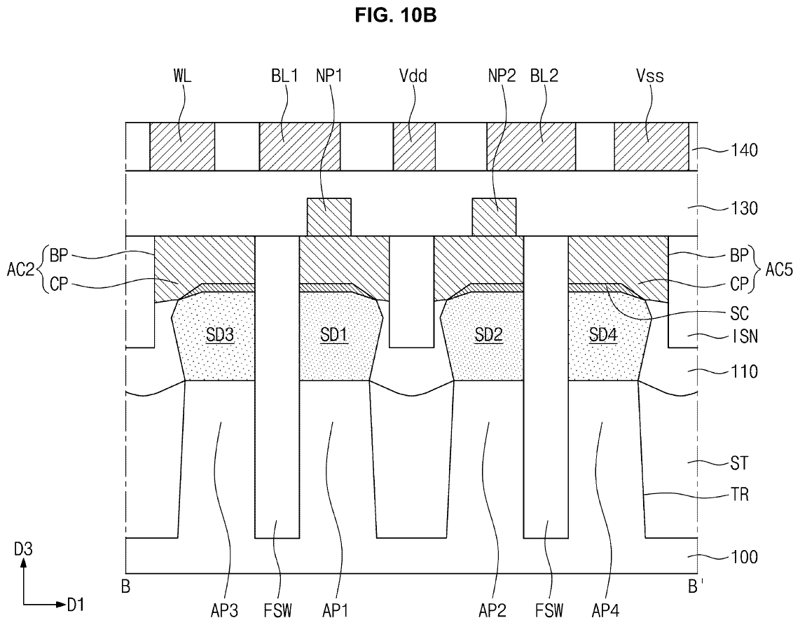

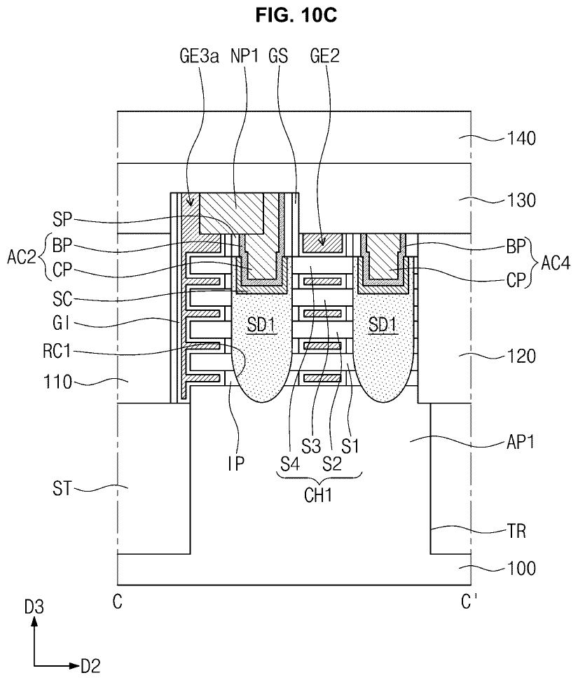

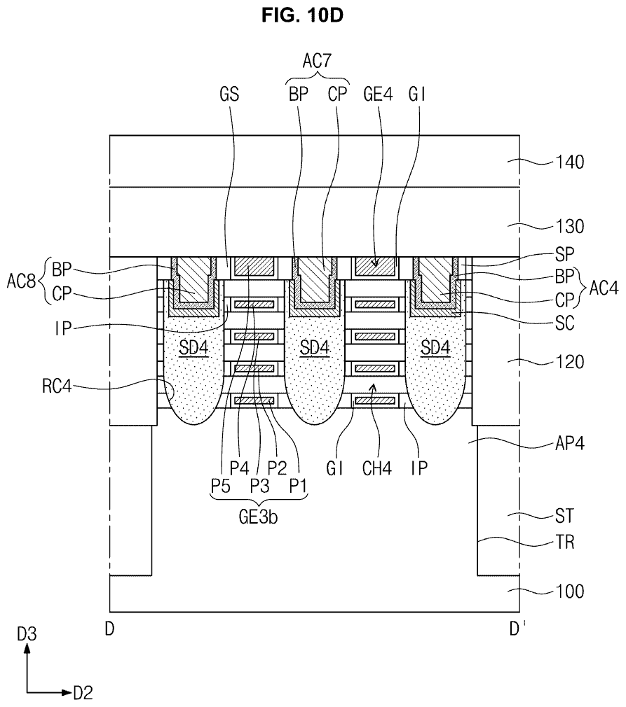

FIG. 9 is a plan view illustrating a semiconductor device according to an embodiment of the present disclosure. FIGS. 10A to 10D are cross-sectional views respectively taken along lines A-A′, B-B′, C-C′, and D-D′ of FIG. 9.

Referring to FIGS. 9 and 10A to 10D, the semiconductor device may have a forksheet structure. The forksheet structure may include a dielectric wall FSW that does not extend to source/drain patterns between two channel patterns adjacent to each other.

First, second, third, and fourth active patterns AP1, AP2, AP3, and AP4 may be defined by trenches TR form in a substrate 100.

First, second, third, and fourth gate electrodes GE1, GE2, GE3, and GE4 may cross the first, second, third, and fourth active patterns AP1, AP2, AP3, and AP4 and may extend in the first direction D1. The first active pattern AP1 and the second active pattern AP2 may be disposed in a PMOS transistor area, and the third active pattern AP3 and the fourth active pattern AP4 may be disposed in an NMOS transistor area. The first, second, third, and fourth active patterns AP1, AP2, AP3, and AP4 may extend in the second direction D2.

First, second, third, and fourth channel patterns CH1, CH2, CH3, and CH4 may be disposed on the first, second, third, and fourth active patterns AP1, AP2, AP3, and AP4, respectively. That is, the first and second channel patterns CH1 and CH2 may be disposed in the PMOS transistor areas, and the third and fourth channel patterns CH3 and CH4 may be disposed in the NMOS transistor areas. Each of the first, second, third, and fourth channel patterns CH1, CH2, CH3, and CH4 may include first, second, third, and fourth semiconductor patterns S1, S2, S3, and S4 sequentially stacked. The first, second, third, and fourth semiconductor patterns S1, S2, S3, and S4 may be spaced apart from each other in the vertical direction, i.e., the third direction D3.

The dielectric walls FSW may be disposed between some active areas and may extend in the second direction D2. The dielectric wall FSW may be disposed between the first active pattern AP1 formed in the PMOS transistor area and the third active pattern AP3 formed in the NMOS transistor area, and also may be disposed between the second active pattern AP2 formed in the PMOS transistor area and the fourth active pattern AP4 formed in the NMOS transistor area.

The dielectric wall FSW may include one or more dielectric layers. According to an embodiment, the dielectric wall FSW may include one or more layers including a low-k dielectric material. According to an embodiment, the dielectric wall FSW may include one or more layers including SiO₂, SiN, SiCN, SiOC, SiOCN, or other suitable dielectric materials with low dielectric constants. Although not shown in figures, the dielectric wall FSW may include a dielectric liner layer and a dielectric filling layer. The dielectric liner layer may be formed from a dielectric material that may be selectively removed from the dielectric filling layer. According to an embodiment, the dielectric liner layer may be a SiN layer, and the dielectric filling layer may include SiO₂.

The dielectric walls FSW may separate the channel patterns disposed in the PMOS transistor area and the channel patterns disposed in the NMOS transistor area. In detail, the dielectric walls FSW may separate the first channel patterns CH1 from the third channel patterns CH3 and may separate the second channel patterns CH2 from the fourth channel patterns CH4.

In addition, the dielectric walls FSW may separate the gate electrodes from each other. In detail, the dielectric walls FSW may separate the first gate electrode GE1 from the third gate electrode GE3 and may separate the second gate electrode GE2 from the fourth gate electrode GE4. Further, the dielectric walls FSW may separate the third gate electrode GE3 into two third sub-gate electrodes GE3a and GE3b and may separate the second gate electrode GE2 into two second sub-gate electrodes GE2a and GE2b. A gate insulating layer GI may be interposed between the dielectric walls FSW and each gate electrode.

According to an embodiment, the dielectric walls FSW may include the same material as a second interlayer insulating layer 120. The dielectric walls FSW may be formed through the same process as the second interlayer insulating layer 120.

Two gate electrodes provided with one dielectric wall FSW interposed therebetween and two channel patterns provided with one dielectric wall FSW interposed therebetween may form a single forksheet structure together with the dielectric wall FSW.

The two second sub-gate electrodes GE2a and GE2b may be connected to each other by a bridge BR. The bridge BR may overlap a portion of each of the second sub-gate electrodes GE2a and GE2b and may be disposed on the dielectric wall FSW provided between the second sub-gate electrodes GE2a and GE2b. In the same way, the third sub-gate electrodes GE3a and GE3b may also be connected to each other through the bridge BR.

The gate insulating layer GI may be interposed between each of the first, second, third, and fourth gate electrodes GE1, GE2, GE3, and GE4 and each of the first, second, third, and fourth channel patterns CH1, CH2, CH3, and CH4. The gate insulating layer GI may cover an upper surface, a bottom surface, and opposite side surfaces of each of the first, second, third, and fourth semiconductor patterns S1, S2, S3, and S4. The gate insulating layer GI may cover an upper surface of the device isolation layer ST. In the present embodiment, the gate insulating layer GI may not be provided between the first channel patterns CH1 and the dielectric walls FSW.

A plurality of first, second, third, and fourth recesses RC1, RC2, RC3, and RC4 may be formed on each of the first active patterns AP1. First, second, third, and fourth source/drain patterns SD1, SD2, SD3, and SD4 may be disposed in each of the first, second, third, and fourth recesses RC1, RC2, RC3, and RC4.

A first node connection pattern NP1 may be disposed on the third gate electrode GE3, and a second node connection pattern NP2 may be disposed on the second gate electrode GE2. The first node connection pattern NP1 may connect the third gate electrode GE3 and a second active contact AC2, and the second node connection pattern may connect the second gate electrode GE2 and a fifth active contact AC5.

According to an embodiment, the bridges BR that connect the second sub-gate electrodes GE2a and GE2b and the third sub-gate electrodes GE3a and GE3b may be disposed at the same level as the first and second node connection patterns NP1 and NP2. According to an embodiment, upper surfaces of the second sub-gate electrodes GE2a and GE2b and the third sub-gate electrodes GE3a and GE3b may be coplanar with upper surfaces of the first and second node connection patterns NP1 and NP2.

A third interlayer insulating layer 130 may be disposed on the first and second node connection patterns NP1 and NP2 and the bridges BR.

A fourth interlayer insulating layer 140 may be disposed on the third interlayer insulating layer 130, and a first wiring layer M1 may be disposed in the fourth interlayer insulating layer 140. The first wiring layer M1 may include a word line WL, a first bit line BL1, a second bit line BL2, a power line Vdd, and a ground line Vss.

According to an embodiment of the present disclosure, as transistors constituting the semiconductor device have the forksheet structure, a distance between the gate electrodes adjacent to each other and between the channel patterns adjacent to each other may be reduced. In addition, since the first and second node connection patterns NP1 and NP2 overlap a portion of the first wiring layer M1, e.g., the first and/or second bit lines BL1 and/or BL2, a gap between lines of the first wiring layer M1 may be further reduced. As a result, a scale of an SRAM cell, e.g., a width in the first direction D1 of the SRAM cell, may be reduced.

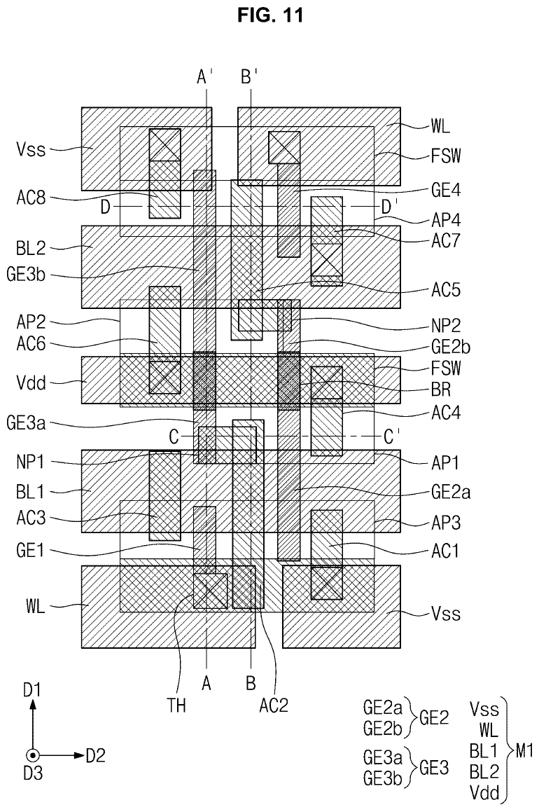

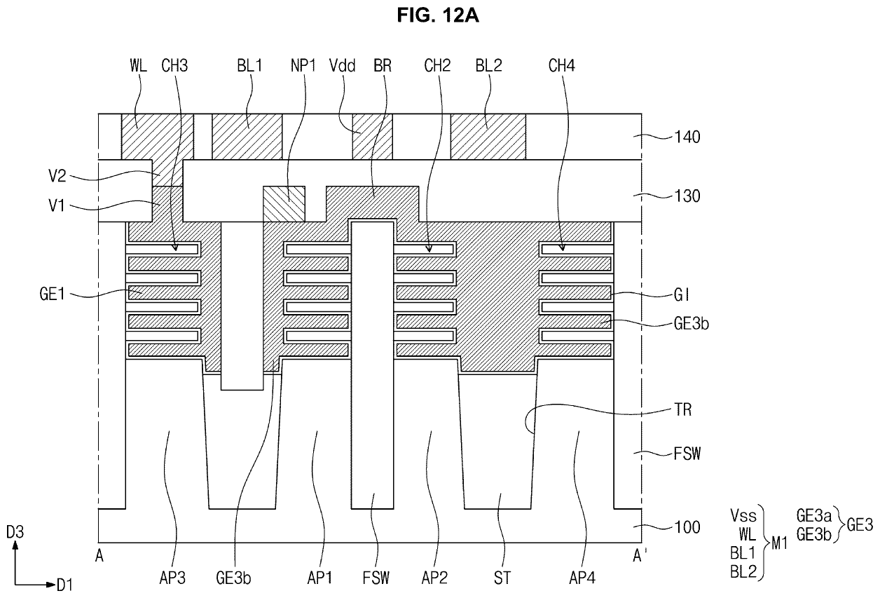

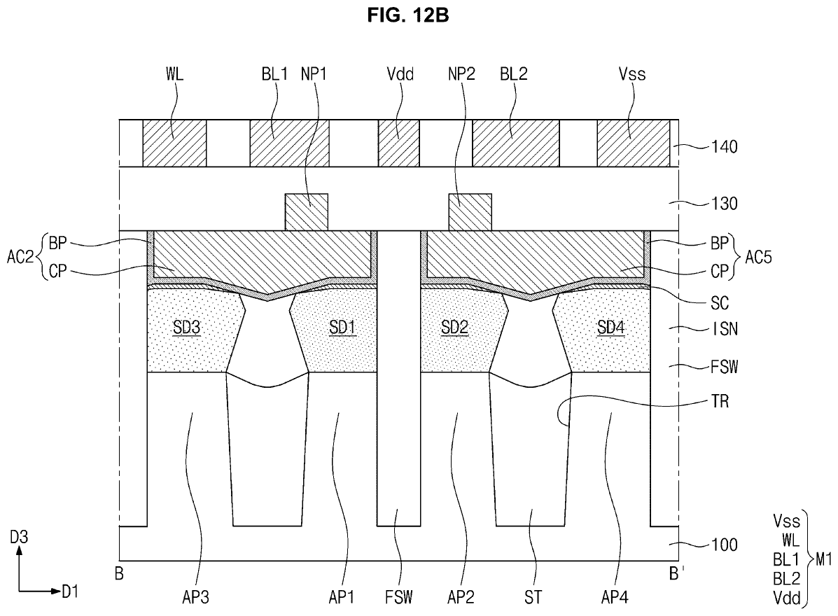

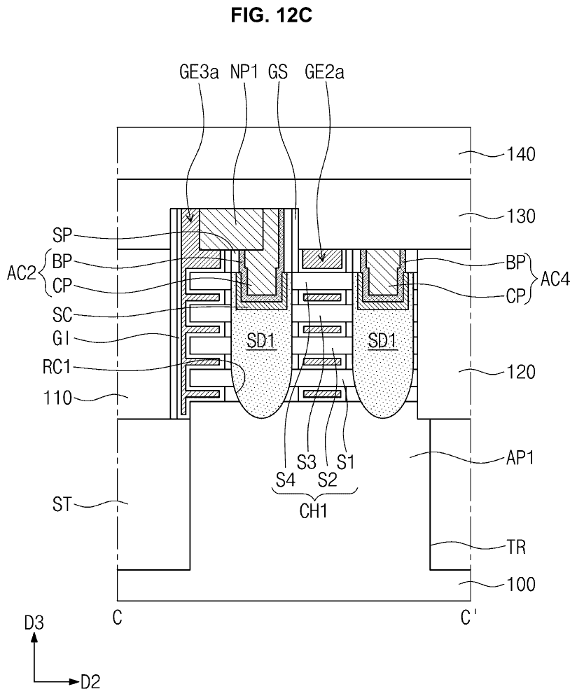

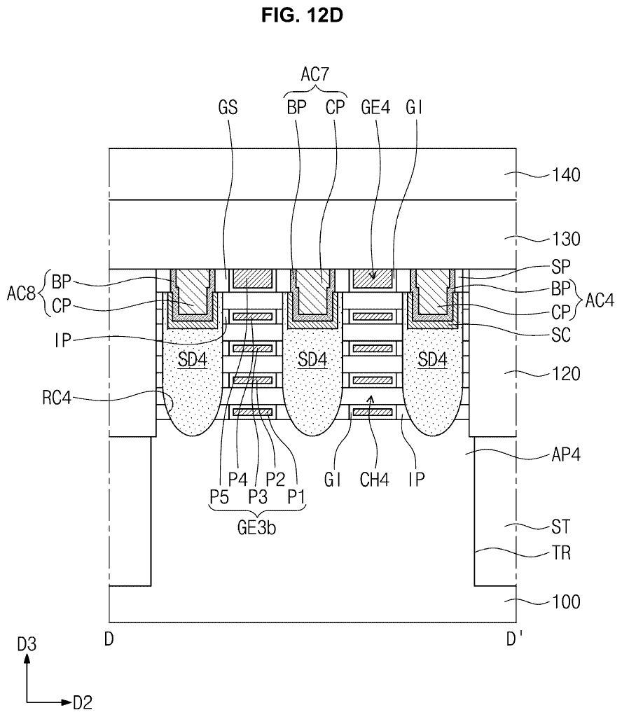

FIG. 11 is a plan view illustrating a semiconductor device according to an embodiment of the present disclosure. FIGS. 12A to 12D are cross-sectional views respectively taken along lines A-A′, B-B′, C-C′, and D-D′ of FIG. 11.

Referring to FIGS. 11 and 12A to 12D, the semiconductor device may have a forksheet structure, but may be provided in a structure different from the above-described embodiment.

First, second, third, and fourth active patterns AP1, AP2, AP3, and AP4 may be defined by trenches TR formed in a substrate 100.

First, second, third, and fourth gate electrodes GE1, GE2, GE3, and GE4 may cross the first, second, third, and fourth active patterns AP1, AP2, AP3, and AP4 and may extend in the first direction D1. The first active pattern AP1 and the second active pattern AP2 may be disposed in a PMOS transistor area, and the third active pattern AP3 and the fourth active pattern AP4 may be disposed in an NMOS transistor area. The first, second, third, and fourth active patterns AP1, AP2, AP3, and AP4 may extend in the second direction D2.

First, second, third, and fourth channel patterns CH1, CH2, CH3, and CH4 may be disposed on the first, second, third, and fourth active patterns AP1, AP2, AP3, and AP4, respectively. That is, the first and second channel patterns CH1 and CH2 may be disposed in the PMOS transistor areas, and the third and fourth channel patterns CH3 and CH4 may be disposed in the NMOS transistor areas. Each of the first, second, third, and fourth channel patterns CH1, CH2, CH3, and CH4 may include first, second, third, and fourth semiconductor patterns S1, S2, S3, and S4 sequentially stacked. The first, second, third, and fourth semiconductor patterns S1, S2, S3, and S4 may be spaced apart from each other in the vertical direction, i.e., the third direction D3.

Dielectric walls FSW may be disposed between some active areas and may extend in the second direction D2. The dielectric wall FSW may be provided between the first active pattern AP1 formed in the PMOS transistor area and the second active pattern AP2 formed in the PMOS transistor area.

According to an embodiment, the dielectric wall FSW may be disposed between the third active pattern AP3 formed in the NMOS transistor area and the third active pattern AP3 formed in the NMOS transistor area of an adjacent cell having a mirror-symmetric shape. In addition, the dielectric wall FSW may be disposed between the fourth active pattern AP4 formed in the NMOS transistor area and the fourth active pattern AP4 formed in the NMOS transistor area of an adjacent cell having a mirror-symmetric shape.

The dielectric walls FSW may be disposed on a device isolation layer ST and may separate channel patterns disposed in the PMOS transistor area from channel patterns disposed in the NMOS transistor area. In detail, each of the dielectric walls FSW may separate the first channel patterns CH1 from the third channel patterns CH3 and may separate the second channel patterns CH2 from the fourth channel patterns CH4.

In addition, the dielectric walls FSW may separate the gate electrodes from each other. In detail, the dielectric walls FSW may separate the first gate electrode GE1 from the third gate electrode GE3 and may separate the second gate electrode GE2 from the fourth gate electrode GE4. Further, the dielectric walls FSW may separate the third gate electrode GE3 into two third sub-gate electrodes GE3a and GE3b and may separate the second gate electrode GE2 into two second sub-gate electrodes GE2a and GE2b. A gate insulating layer GI may be interposed between the dielectric walls FSW and each corresponding gate electrode.

Two gate electrodes provided with one dielectric wall FSW interposed therebetween and two channel patterns provided with one dielectric wall FSW interposed therebetween may form a single forksheet structure together with the dielectric wall FSW.

The two second sub-gate electrodes GE2a and GE2b may be connected to each other by a bridge BR. The bridge BR may overlap a portion of each of the second sub-gate electrodes GE2a and GE2b and may be disposed on the dielectric wall FSW disposed between the second sub-gate electrodes GE2a and GE2b. In the same way, the third sub-gate electrodes GE3a and GE3b may also be connected to each other through the bridge BR.

The gate insulating layer GI may be interposed between each of the first, second, third, and fourth gate electrodes GE1, GE2, GE3, and GE4 and each of the first, second, third, and fourth channel patterns CH1, CH2, CH3, and CH4. The gate insulating layer GI may cover an upper surface, a bottom surface, and opposite side surfaces of each of the first, second, third, and fourth semiconductor patterns S1, S2, S3, and S4. The gate insulating layer GI may cover an upper surface of the device isolation layer ST. In the present embodiment, the gate insulating layer GI may not be disposed between the first channel patterns CH1 and the dielectric walls FSW.

A plurality of first, second, third, and fourth recesses RC1, RC2, RC3, and RC4 may be formed on each of the first active patterns AP1. First, second, third, and fourth source/drain patterns SD1, SD2, SD3, and SD4 may be disposed in each of the first, second, third, and fourth recesses RC1, RC2, RC3, and RC4.

A first node connection pattern NP1 may be disposed on the third gate electrode GE3, and a second node connection pattern NP2 may be disposed on the second gate electrode GE2. The first node connection pattern NP1 may connect the third gate electrode GE3 and a second active contact AC2, and the second node connection pattern may connect the second gate electrode GE2 and a fifth active contact AC5.

According to an embodiment, the bridges BR connecting the second sub-gate electrodes GE2a and GE2b to each other and the third sub-gate electrodes GE3a and GE3b to each other may be disposed at the same level as the first and second node connection patterns NP1 and NP2. According to an embodiment, upper surfaces of the second sub-gate electrodes GE2a and GE2b and the third sub-gate electrodes GE3a and GE3b may be coplanar with upper surfaces of the first and second node connection patterns NP1 and NP2.

A third interlayer insulating layer 130 may be disposed on the first and second node connection patterns NP1 and NP2 and the bridges BR.

A fourth interlayer insulating layer 140 may be disposed on the third interlayer insulating layer 130, and a first wiring layer M1 may be disposed in the fourth interlayer insulating layer 140. The first wiring layer M1 may include a word line WL, a first bit line BL1, a second bit line BL2, a power line Vdd, and a ground line Vss.

According to an embodiment of the present disclosure, as transistors constituting the semiconductor device have the forksheet structure, a distance between the gate electrodes adjacent to each other and between the channel patterns adjacent to each other may be reduced. In addition, since the first and second node connection patterns NP1 and NP2 overlap a portion of the first wiring layer M1, e.g., the first and/or second bit lines BL1 and/or BL2, a gap between lines of the first wiring layer M1 may be further reduced. As a result, a scale of an SRAM cell, e.g., a width in the first direction D1 of the SRAM cell, may be reduced.

In the present embodiment, for the convenience of explanation, only one SRAM cell is shown; however, the present disclosure should not be limited thereto or thereby. The semiconductor device may include a plurality of SRAM cells, and two SRAM cells adjacent to each other in a row direction and/or in a column direction may have the mirror-symmetric shape with respect to each other. In addition, two SRAM cells adjacent to each other may share a portion of the forksheet structure. As an example, the dielectric wall FSW disposed at the uppermost position with respect to the first direction D1 may be a portion of a forksheet structure of another cell disposed above in the first direction D1. In addition, the dielectric wall FSW disposed at the lowermost position with respect to the first direction D1 may be a portion of a forksheet structure of another cell disposed below in the first direction D1.

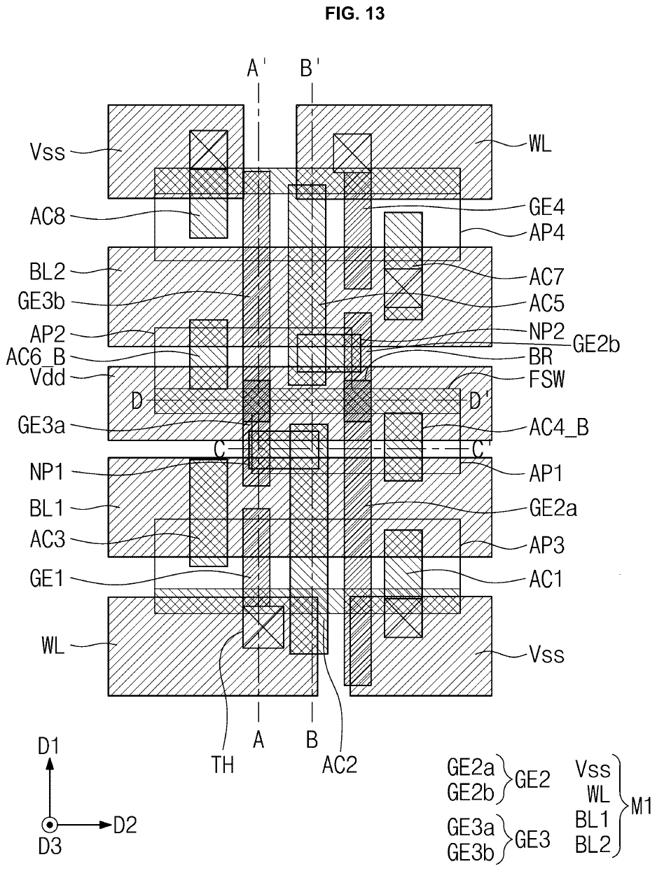

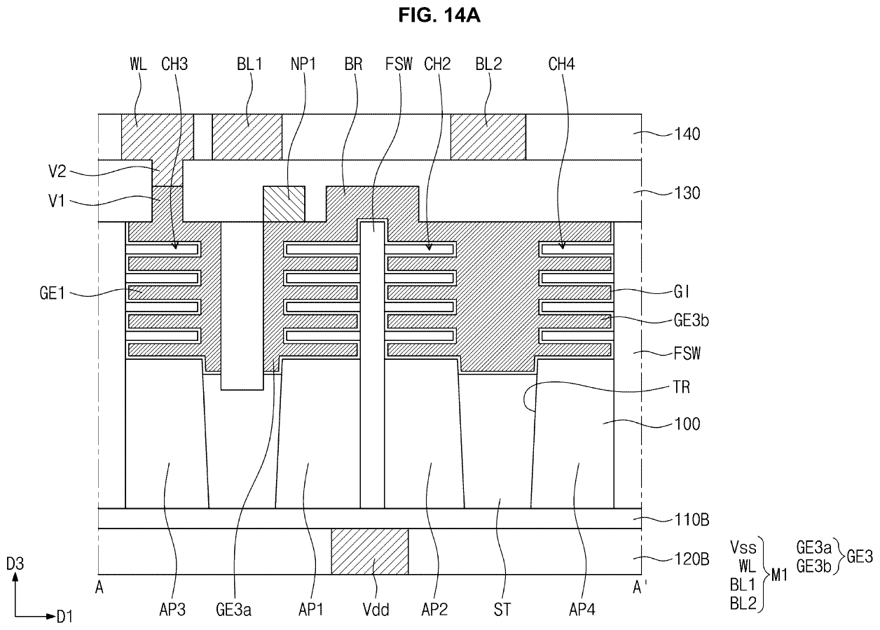

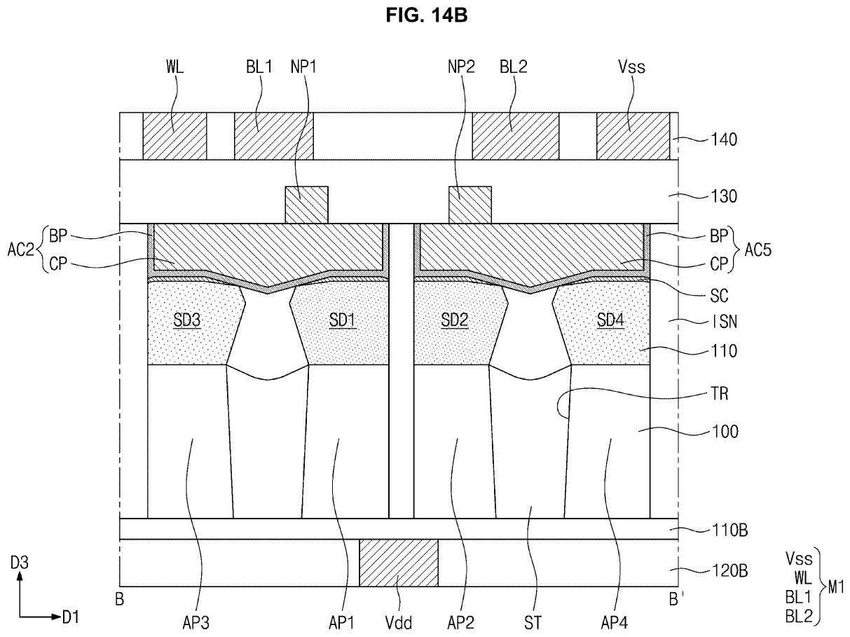

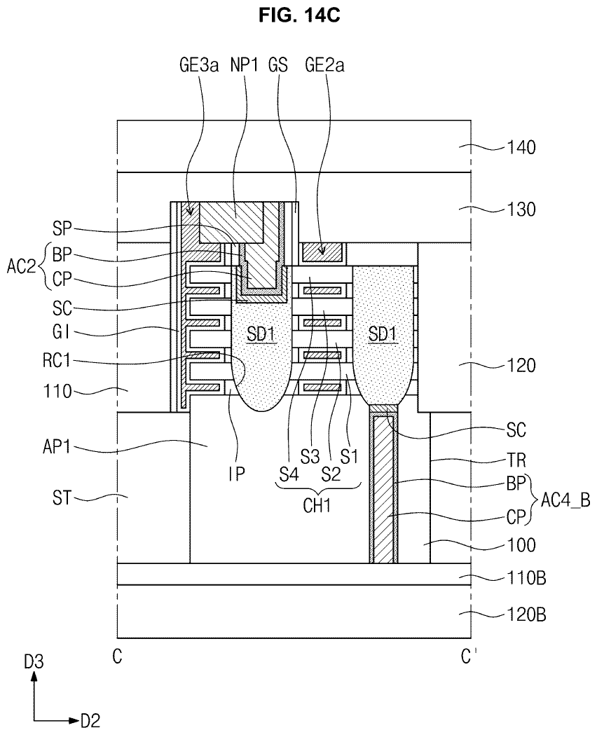

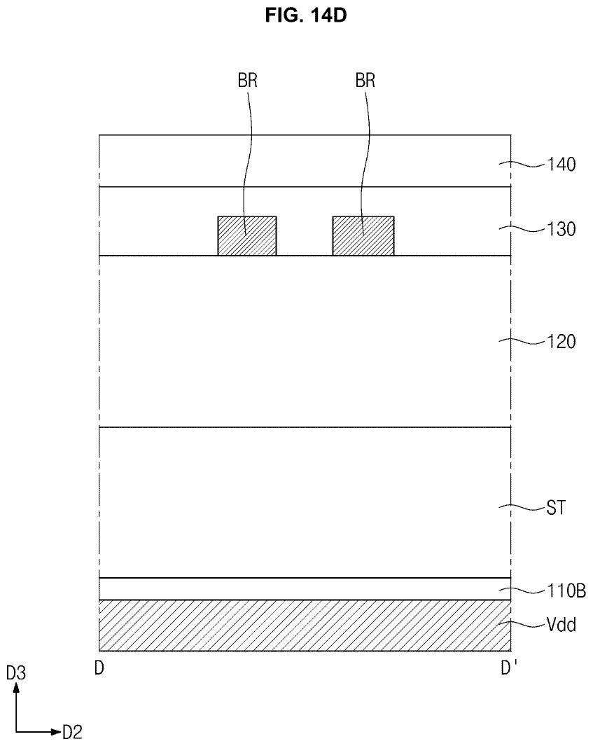

FIG. 13 is a plan view illustrating a semiconductor device according to an embodiment of the present disclosure. FIGS. 14A to 14D are cross-sectional views respectively taken along lines A-A′, B-B′, C-C′, and D-D′ of FIG. 13.

Referring to FIGS. 13 and 14A to 14D, the semiconductor device may have a forksheet structure, but may be provided in a structure different from the above-described embodiment.

First, second, third, and fourth active patterns AP1, AP2, AP3, and AP4 may be defined by trenches TR formed in a substrate 100. The first active pattern AP1 and the second active pattern AP2 may be disposed in a PMOS transistor area, and the third active pattern AP3 and the fourth active pattern AP4 may be disposed in an NMOS transistor area.

The first, second, third, and fourth active patterns AP1, AP2, AP3, and AP4 may extend in the second direction D2. The trenches TR may be filled with a device isolation layer ST. The device isolation layer ST may penetrate through a front surface and a rear surface of the substrate 100. To allow the device isolation layer ST to penetrate the front surface and the rear surface of the substrate 100, the substrate 100 may be patterned to form the trenches TR having a selected depth in the substrate 100, the device isolation layer ST may be formed in the trenches TR, and the rear surface of the substrate 100 may be patterned until the device isolation layer ST is exposed.

First, second, third, and fourth channel patterns CH1, CH2, CH3, and CH4 may be disposed on the first, second, third, and fourth active patterns AP1, AP2, AP3, and AP4, respectively. That is, the first and second channel patterns CH1 and CH2 may be disposed in the PMOS transistor areas, and the third and fourth channel patterns CH3 and CH4 may be disposed in the NMOS transistor areas. Each of the first, second, third, and fourth channel patterns CH1, CH2, CH3, and CH4 may include first, second, third, and fourth semiconductor patterns S1, S2, S3, and S4 sequentially stacked.

Dielectric walls FSW may be disposed between some active areas and may extend in the second direction D2. The dielectric wall FSW may be disposed between the first active pattern AP1 disposed in the PMOS transistor area and the second active pattern AP2 disposed in the PMOS transistor area.

According to an embodiment, the dielectric wall FSW may be disposed between the third active pattern AP3 formed in the NMOS transistor area and the third active pattern AP3 formed in the NMOS transistor area of an adjacent cell having a mirror-symmetric shape. In addition, the dielectric wall FSW may be disposed between the fourth active pattern AP4 formed in the NMOS transistor area and the fourth active pattern AP4 formed in the NMOS transistor area of an adjacent cell having a mirror-symmetric shape.

The dielectric walls FSW may be disposed on the device isolation layer ST and may separate channel patterns disposed in the PMOS transistor area from channel patterns disposed in the NMOS transistor area. In detail, the dielectric walls FSW may separate the first channel patterns CH1 from the third channel patterns CH3 and may separate the second channel patterns CH2 from the third channel patterns CH3.

In addition, the dielectric walls FSW may separate the gate electrodes from each other. In detail, the dielectric walls FSW may separate the first gate electrode GE1 from the third gate electrode GE3 and may separate the second gate electrode GE2 from the fourth gate electrode GE4. Further, the dielectric walls FSW may separate the third gate electrode GE3 into two third sub-gate electrodes GE3a and GE3b and may separate the second gate electrode GE2 into two second sub-gate electrodes GE2a and GE2b. A gate insulating layer GI may be interposed between the dielectric walls FSW and each gate electrode.

Two gate electrodes provided with one dielectric wall FSW interposed therebetween and two channel patterns provided with one dielectric wall FSW interposed therebetween may form a single forksheet structure together with the dielectric wall FSW.

The two second sub-gate electrodes GE2a and GE2b may be connected to each other by a bridge BR. The bridge BR may overlap a portion of each of the second sub-gate electrodes GE2a and GE2b and may be disposed on the dielectric wall FSW disposed between the second sub-gate electrodes GE2a and GE2b. In the same way, the third sub-gate electrodes GE3a and GE3b may also be connected to each other through the bridge BR.

The gate insulating layer GI may be interposed between each of the first, second, third, and fourth gate electrodes GE1, GE2, GE3, and GE4 and each of the first, second, third, and fourth channel patterns CH1, CH2, CH3, and CH4. The gate insulating layer GI may cover an upper surface, a bottom surface, and opposite side surfaces of each of the first, second, third, and fourth semiconductor patterns S1, S2, S3, and S4. The gate insulating layer GI may cover an upper surface of the device isolation layer ST. In the present embodiment, the gate insulating layer GI may not be disposed between the first channel patterns CH1 and the dielectric walls FSW.

A plurality of first, second, third, and fourth recesses RC1, RC2, RC3, and RC4 may be formed on each of the first active patterns AP1. First, second, third, and fourth source/drain patterns SD1, SD2, SD3, and SD4 may be disposed in each of the first, second, third, and fourth recesses RC1, RC2, RC3, and RC4.

A first node connection pattern NP1 may be disposed on the third gate electrode GE3, and a second node connection pattern NP2 may be disposed on the second gate electrode GE2. The first node connection pattern NP1 may connect the third gate electrode GE3 and a second active contact AC2, and the second node connection pattern may connect the second gate electrode GE2 and a fifth active contact AC5.

The first, second, third, and fourth source/drain patterns SD1, SD2, SD3, and SD4 may be connected to a word line WL, first and second bit lines BL1 and BL2, a ground line Vss, and a power line Vdd through multiple active contacts. In the present embodiment, a first wiring layer M1 may include the first and second bit lines BL1 and BL2, the word line WL, and the ground line Vss, and the power line Vdd may not be included in the first wiring layer M1. In detail, the first and second bit lines BL1 and BL2, the word line WL, and the ground line Vss may be formed on the front surface of the substrate 100, and the power line Vdd may be formed on the rear surface of the substrate 100.

Since the power line Vdd is formed on the rear surface of the substrate 100, a fourth active contact AC4 and a sixth active contact AC6, which are connected to the power line Vdd among first to eighth active contacts AC1 to AC8, may have a rear surface active contact structure.

One or more rear surface wiring layers may be provided on the rear surface of the substrate 100. The rear surface wiring layer may include a backside power delivery network. The power line Vdd may be a portion of the rear surface wiring layer, and in detail, may be a portion of the backside power delivery network.

A first rear surface interlayer insulating layer 110B may be provided between the power line Vdd and the rear surface of the substrate 100. The power line Vdd may be electrically connected to fourth and sixth rear surface active contacts AC4_B and AC6_B through a rear surface via penetrating the first rear surface interlayer insulating layer 110B and disposed in the first rear surface interlayer insulating layer 110B.

According to the present embodiment, the power line Vdd is disposed on the rear surface of the substrate 100; however, the present disclosure should not be limited thereto or thereby. According to an embodiment, another line among the lines of the first wiring layer M1 may be disposed on the rear surface of the substrate 100. As an example, the ground line Vss may be disposed on the rear surface. In this case, a power delivery network layer PDN may include lines to apply a ground voltage to the ground lines Vss in addition to lines to apply a power voltage to the power lines Vdd.

According to the present embodiment, as the semiconductor device has the forksheet structure and the power line Vdd is disposed on the rear surface, a gap between the lines of the first wiring layer M1 may be further reduced, and a scale of an SRAM cell, e.g., a width in the first direction D1 of the SRAM cell, may be reduced.

Hereinafter, a method of manufacturing the semiconductor device according to an embodiment of the present disclosure will be described. The manufacturing method of the semiconductor device will be described with reference to the embodiment illustrated in FIGS. 1, 2, and 3A to 3D as a representative example to avoid redundancy in explanation.

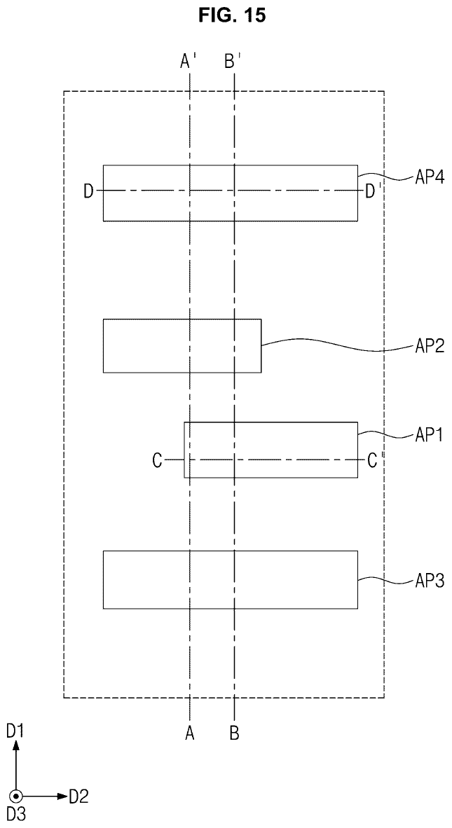

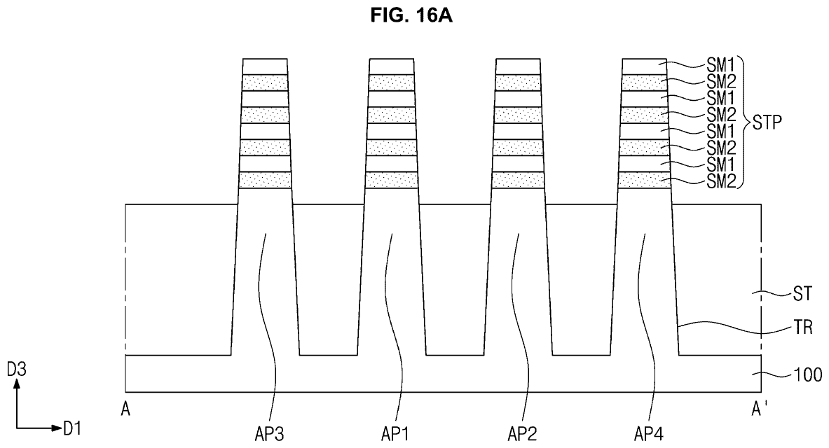

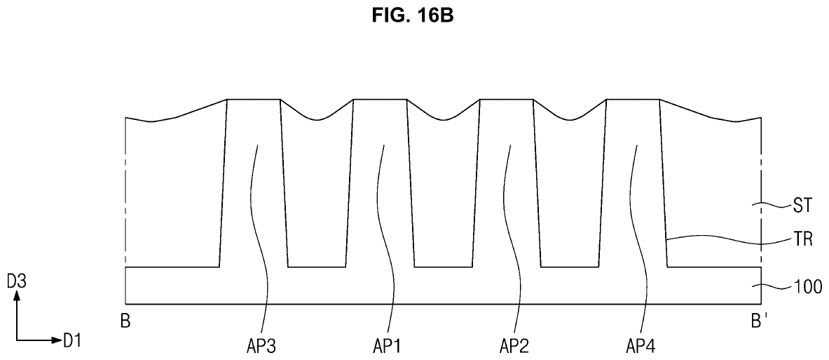

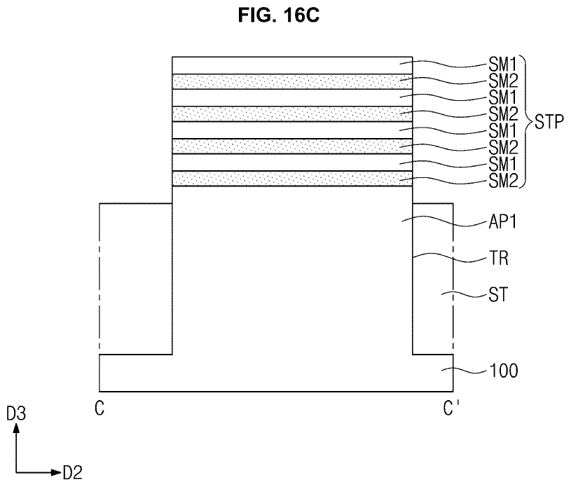

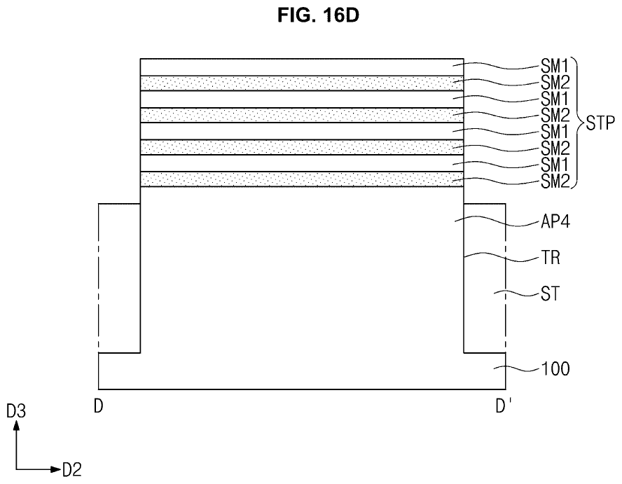

Referring to FIGS. 15 and 16A to 16D, first semiconductor layers SM1 and second semiconductor layers SM2 may be alternately stacked with each other on the substrate 100. The second semiconductor layers SM2 may include a material having an etch selectivity or different oxidation rate with respect to the first semiconductor layers SM1. The number of the first semiconductor layers SM1 and the number of the second semiconductor layers SM2 may be greater or fewer than those illustrated.

The first semiconductor layers SM1 may include one of silicon (Si), germanium (Ge), and silicon-germanium (SiGe), and the second semiconductor layers SM2 may include another of silicon (Si), germanium (Ge), and silicon-germanium (SiGe). As an example, the first semiconductor layers SM1 may include silicon (Si), and the second semiconductor layers SM2 may include silicon-germanium (SiGe). The concentration of germanium (Ge) in each of the second semiconductor layers SM2 may be in a range from about 10 at % to about 30 at %.

The first and second semiconductor layers SM1 and SM2 may be formed by a molecular beam epitaxy (MBE) process, a metalorganic chemical vapor deposition (MOCVD) process, and/or other suitable epitaxial growth processes.

Mask patterns may be formed above the PMOS transistor areas and the NMOS transistor areas of the substrate 100. The mask pattern may have a line shape or a bar shape extending in the second direction D2.

A patterning process may be performed using the mask patterns as an etching mask to form the trenches TR that define the first, second, third, and fourth active patterns AP1, AP2, AP3, and AP4. The trenches TR may be formed between the first, second, third, and fourth active patterns AP1, AP2, AP3, and AP4. Due to the trenches TR, the first active pattern AP1 and the second active pattern AP2 may be formed in the PMOS transistor area, and the third active pattern AP3 and the fourth active pattern AP4 may be formed in the NMOS transistor area. When viewed in the plane, the first, second, third, and fourth active patterns AP1, AP2, AP3, and AP4 may extend parallel to each other in the second direction D2 and may have a bar shape. The first, second, third, and fourth active patterns AP1, AP2, AP3, and AP4 may be arranged along the first direction D1 in order of the third active pattern AP3, the first active pattern AP1, the second active pattern AP2, and the fourth active pattern AP4 and may be spaced apart from each other.

A stack pattern STP may be formed on each of the first, second, third, and fourth active patterns AP1, AP2, AP3, and AP4. The stack pattern STP may include the first semiconductor layers SM1 and the second semiconductor layers SM2 alternately stacked with the first semiconductor layers SM1. The stack pattern STP may be formed together during the process of forming the first, second, third, and fourth active patterns AP1, AP2, AP3, and AP4.

The device isolation layer ST may be formed to fill the trenches TR. In detail, an insulating layer may be formed on the front surface of the substrate 100 to cover the first, second, third, and fourth active patterns AP1, AP2, AP3, and AP4 and the stack patterns STP. The insulating layer may be recessed until the stack patterns STP are exposed, and thus, the device isolation layer ST may be formed. The device isolation layer ST may be formed by a high density plasma chemical vapor deposition (HDP-CVD), a flowable CVD (FCVD), or other suitable deposition processes.

The device isolation layer ST may include silicon oxide, silicon nitride, silicon oxynitride, fluorine-doped silicate glass (FSG), low-k dielectrics, or combinations thereof. According to an embodiment, the device isolation layer ST may include a silicon oxide layer. The stack patterns STP may be exposed above the device isolation layer ST. In other words, the stack patterns STP may protrude vertically above the device isolation layer ST.

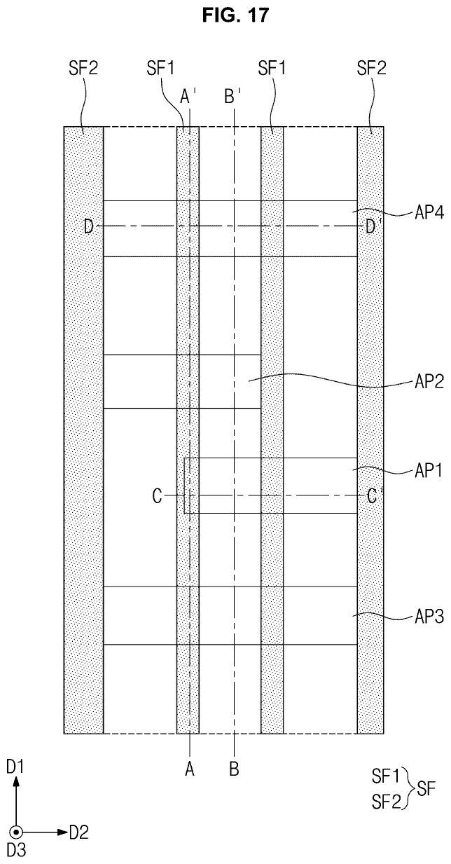

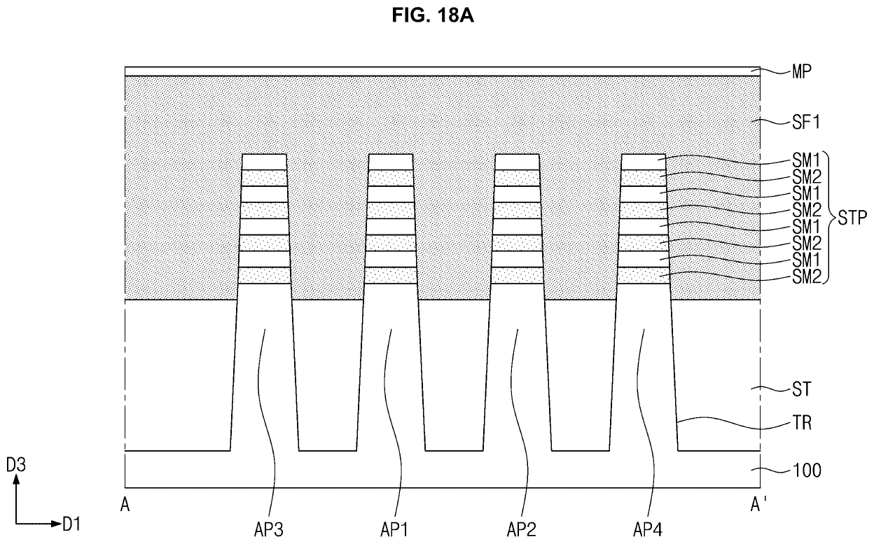

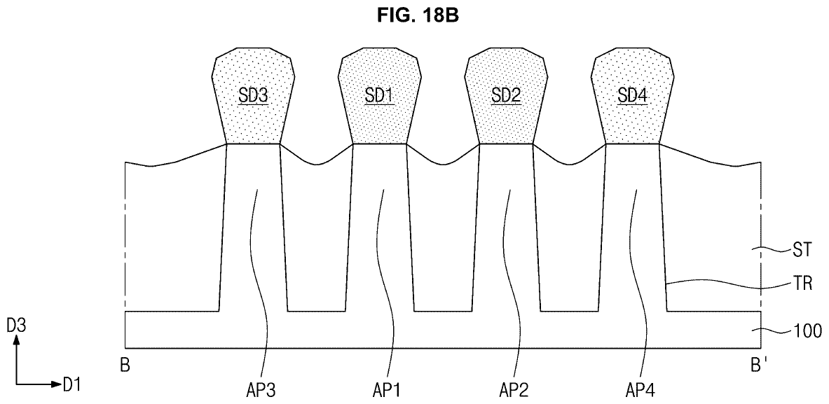

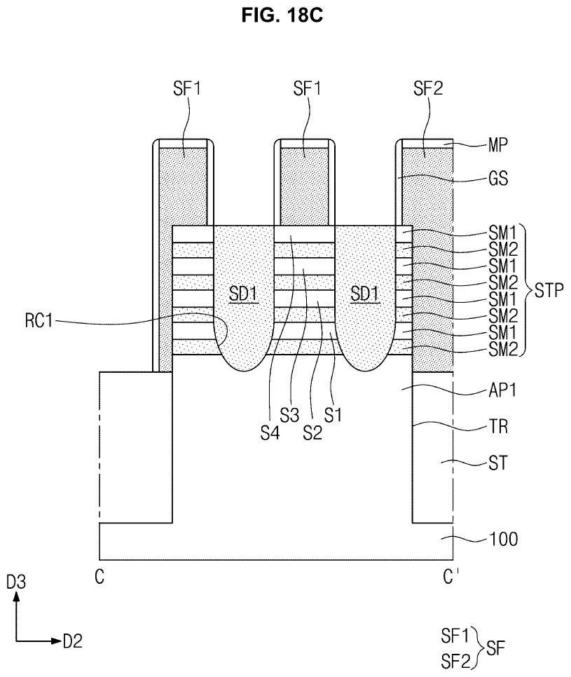

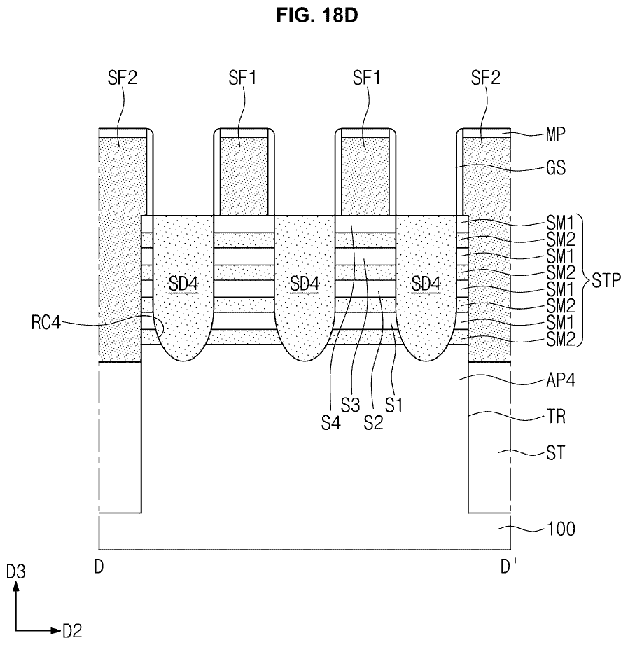

Referring to FIGS. 17 and 18A to 18D, sacrificial patterns SF may be formed on the substrate 100 to cross the first, second, third, and fourth active patterns AP1, AP2, AP3, and AP4. The sacrificial patterns SF may include a variety of materials, for example, may include polysilicon.

Each of the sacrificial patterns SF may have a line shape or a bar shape extending in the first direction D1. The sacrificial patterns SF may include gate sacrificial patterns SF1 and dummy sacrificial patterns SF2. The gate sacrificial patterns SF1 may be formed in areas where the gate electrodes are to be formed. The gate sacrificial patterns SF1 may cover an upper surface and a side surface of the stack pattern STP. The dummy sacrificial patterns SF2 may cover the side surface of the stack pattern STP in an area where the gate sacrificial patterns SF1 are not formed.

In detail, the forming of the sacrificial patterns SF may include forming a sacrificial layer on the front surface of the substrate 100, forming hard mask patterns MP on the sacrificial layer, and patterning the sacrificial layer using the hard mask patterns MP as an etching mask. The sacrificial layer may be deposited using a CVD including an LPCVD and a PECVD, a PVD, an ALD, or other suitable processes. A portion of the sacrificial layer may be removed by a plasma dry etching process and/or a wet etching process. In some embodiments, the sacrificial layer may include polysilicon. When the sacrificial layer includes polysilicon, the wet etching process may be performed to selectively remove the portion of the sacrificial layer, and a variety of etching solutions, e.g., a tetramethylammonium hydroxide (TMAH) solution, may be used.

A pair of gate spacers GS may be formed on opposite side surfaces of each of the sacrificial patterns SF. The forming of the gate spacers GS may include conformally forming a gate spacer layer on the front surface of the substrate 100 and anisotropically etching the gate spacer layer. The gate spacer layer may include at least one of SiCN, SiCON, and SiN. In an embodiment, the gate spacer layer may have a multi-layer structure of at least two of SiCN, SiCON, and SiN.

The first recesses RC1 may be formed in the stack pattern STP on the first active pattern AP1. The second recesses RC2 may be formed in the stack pattern STP of the second active pattern AP2, and in the same way, the third and fourth recesses RS3 and RS4 may be formed in the stack pattern STP on the third and fourth active patterns AP3 and AP4. In detail, the stack pattern STP on the first, second, third, and fourth active patterns AP1, AP2, AP3, and AP4 may be etched using the hard mask patterns MP and the gate spacers GS as an etching mask to form the first, second, third, and fourth recesses RC1, RC2, RC3, and RC4. The first recess RC1 may be formed between the pair of sacrificial patterns SF. The second, third, and fourth recesses RC2, RC3, and RC4 in the stack pattern STP on the second, third, and fourth active patterns AP2, AP3, and AP4 may be formed through the same method as the first recesses RC1. The first, second, third, and fourth recesses RC1, RC2, RC3, and RC4 may be formed a dry etching process and/or a wet etching process, which are suitable to remove the first and second semiconductor layers SM1 and SM2 together or separately.

The first, second, third, and fourth semiconductor patterns S1, S2, S3, and S4, which are sequentially stacked between the first recesses RC1 adjacent to each other, may be formed from the first semiconductor layers SM1. In addition, the first, second, third, and fourth semiconductor patterns S1, S2, S3, and S4, which are sequentially stacked between the second recesses RC2 adjacent to each other, may be formed from the first semiconductor layers SM1. In the same way, the first, second, third, and fourth semiconductor patterns S1, S2, S3, and S4, which are sequentially stacked between the third recesses RC3 adjacent to each other and between the fourth recesses RC4 adjacent to each other, may be formed from the first semiconductor layers SM1.

The first source/drain patterns SD1 may be formed in the first recesses RC1, respectively. The first source/drain patterns SD1 may be formed at one side or at each of opposite sides of the gate sacrificial patterns SF1 among the sacrificial patterns SF. In detail, a first SEG process using an inner side wall of the first recess RC1 as a seed layer may be performed to form the buffer layer. The buffer layer may be grown using the first, second, third, and fourth semiconductor patterns S1, S2, S3, and S4 and the substrate 100, which are exposed by the first recess RC1, as seeds. As an example, the first SEG process may include a chemical vapor deposition (CVD) process or a molecular beam epitaxy (MBE) process.

The buffer layer may include a semiconductor material (e.g., SiGe) whose lattice constant is greater than that of the substrate 100. The buffer layer may include a relatively low concentration of germanium (Ge). A germanium concentration of the buffer layer may be in a range from about 0 at % to about 10 at %. In an embodiment, the buffer layer may include only silicon (Si) without germanium (Ge).

A second SEG process may be performed on the buffer layer to form the main layer. The main layer may be formed to completely or nearly completely fill the first recess RC1. The main layer may include a relatively high concentration of germanium (G3). In an embodiment, a germanium concentration of the main layer may be in a range from about 30 at % to about 70 at %.

During the forming of the buffer layer and the main layer, impurities (e.g., boron, gallium, or indium) that allows the first source/drain pattern SD1 to have a P-type conductivity may be implanted into the first source/drain pattern SD1 through an in-situ method. In an embodiment, after the first source/drain patterns SD1 are formed, the impurity may be implanted into the first source/drain patterns SD1.

In the same manner as the first source/drain patterns SD1, the second source/drain patterns SD2 may be formed in the second recesses RC2.

The third source/drain patterns SD3 may be formed in the third recesses RS3, respectively. The third source/drain patterns SD3 may be formed at each of opposite sides of the gate sacrificial patterns SF1 among the sacrificial patterns SF. In detail, the third source/drain pattern SD3 may be formed by performing a selective epitaxial growth SEG process using an inner side wall of the third recess RS3 as a seed layer. As an example, the third source/drain pattern SD3 may include the same semiconductor material, e.g., Si, as the substrate 100.

During the forming of the third source/drain pattern SD3, impurities (e.g., phosphorus, arsenic, or antimony) that allow the third source/drain pattern SD3 to have an N-type conductivity may be implanted into the third source/drain pattern SD3 through an in-situ method. In an embodiment, after the third source/drain patterns SD3 are formed, the impurities may be implanted into the third source/drain patterns SD3.

In the same manner as the third source/drain patterns SD3, the fourth source/drain patterns SD4 may be formed in the fourth recesses RC4.

According to an embodiment of the present disclosure, before the forming of the first, second, third, and fourth source/drain patterns SD1, SD2, SD3, and SD4, a portion of the second semiconductor layer SM2 exposed through the first, second, third, and fourth recesses RC1, RC2, RC3, and RC4 may be replaced with an insulating material to form the inner spacer IP. Consequently, the inner spacers IP may be formed between each of the first, second, third, and fourth source/drain patterns SD1, SD2, SD3, and SD4 and the second semiconductor layers SM2, respectively.

According to an embodiment of the present disclosure, the first and second source/drain patterns SD1 and SD2 and the third and fourth source/drain patterns SD3 and SD4 may be sequentially formed through different processes from each other. In other words, the first and second source/drain patterns SD1 and SD2 and the third and fourth source/drain patterns SD3 and SD4 may not be substantially simultaneously formed.

As the first source/drain patterns SD1 are formed, the first channel pattern CH1 may be defined between the pair of the first source/drain patterns SD1. As the second source/drain patterns SD2 are formed, the second channel pattern CH2 may be defined between the pair of the second source/drain patterns SD2. As the third source/drain patterns SD3 are formed, the third channel pattern CH3 may be defined between the pair of the third source/drain patterns SD3. As the fourth source/drain patterns SD4 are formed, the fourth channel pattern CH4 may be defined between the pair of the fourth source/drain patterns SD4.

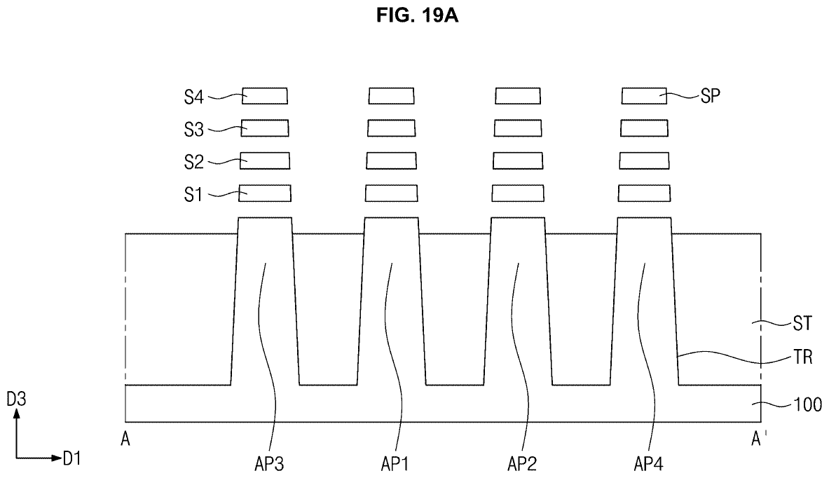

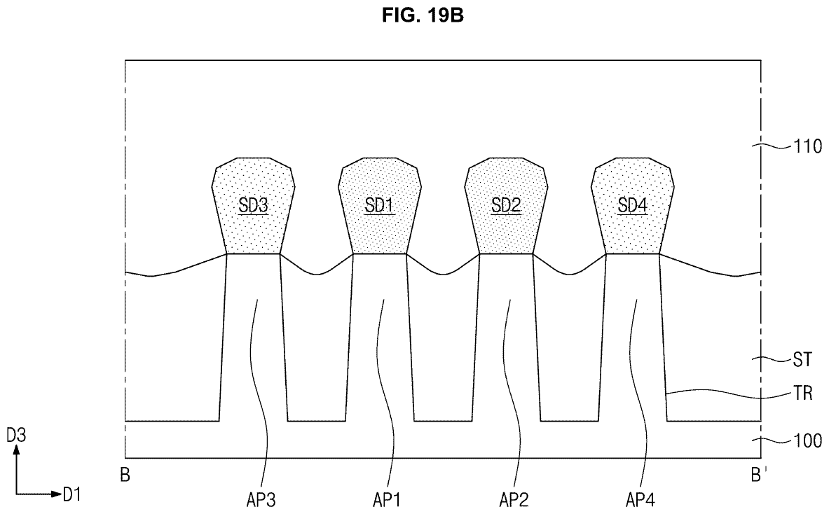

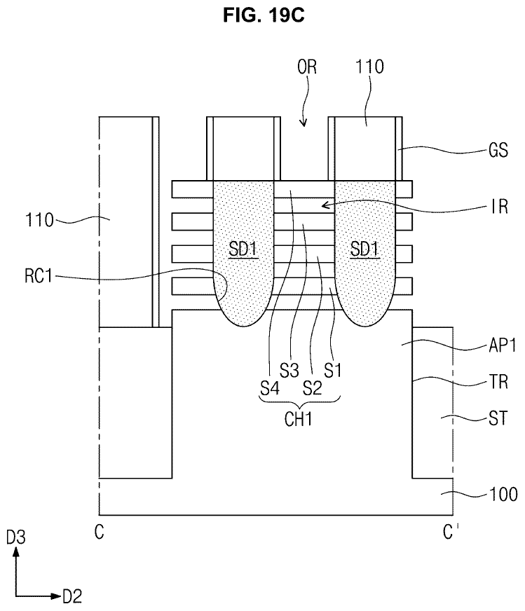

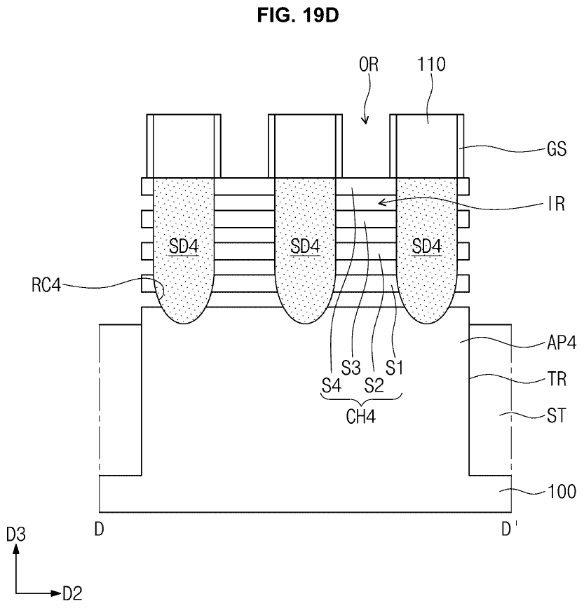

Referring to FIGS. 17 and 19A to 19D, the first interlayer insulating layer 110 may be formed to cover the first, second, third, and fourth source/drain patterns SD1, SD2, SD3, and SD4, the hard mask patterns MP, and the gate spacers GS. As an example, the first interlayer insulating layer 110 may include a silicon oxide layer. The first interlayer insulating layer 110 may include a contact-etching preventing layer and an interlayer dielectric layer. The contact-etching preventing layer may include Si₃N₄, SiON, SiCN, or any other suitable material and may be formed by a CVD, PVD, or ALD process. The interlayer dielectric layer may include a compound containing Si, O, C, and/or H, such as silicon oxide, SiCOH, and SiOC.

The first interlayer insulating layer 110 may be planarized until upper surfaces of the sacrificial patterns SF are exposed. The planarization of the first interlayer insulating layer 110 may be performed through an etch back or chemical-mechanical polishing (CMP) process. The hard mask patterns MP may be removed during the planarization process. As a result, the upper surface of the first interlayer insulating layer 110 may be coplanar with the upper surfaces of the sacrificial patterns SF and the upper surfaces of the gate spacers GS.

Then, the sacrificial patterns SF may be selectively removed using a photolithography process. As the sacrificial patterns SF are selectively removed, an outer region OR where the first and second channel patterns CH1 and CH2 are exposed may be formed. The sacrificial patterns SF may be removed by a wet etching process. In the wet etching process, an etchant that selectively etches polysilicon may be used.

Then, the second semiconductor layers SM2 exposed through the outer region OR may be selectively removed, and thus, inner regions IR may be formed. The outer region OR may be a region that meets an upper region of the fourth semiconductor pattern S4 and the side surfaces of the first, second, third, and fourth semiconductor patterns S1, S2, S3, and S4. The inner regions IR may be areas between the substrate 100 and the first semiconductor pattern S1 and between the first, second, third, and fourth semiconductor patterns S1, S2, S3, and S4 adjacent to each other. In detail, an etching process that selectively etches the second semiconductor layers SM2 may be performed, and thus, only the second semiconductor layers SM2 may be removed while the first, second, third, and fourth semiconductor patterns S1, S2, S3, and S4 remain intact. The etching process may have a high etch rate for silicon-germanium with a relatively high germanium concentration. As an example, the etching process may have a high etch rate for silicon-germanium with the germanium concentration higher than about 10 at %. Meanwhile, the first source/drain pattern SD1 may be protected during the etching process due to the buffer layer with a relatively low germanium concentration. According to an embodiment, the second semiconductor layers SM2 may be selectively etched using wet etchants, including but not limited to ammonium hydroxide (NH₄OH), tetramethylammonium hydroxide (TMAH), ethylenediaminepyrocatechol (EDP), or potassium hydroxide (KOH) solutions.

As the second semiconductor layers SM2 are selectively etched, only the first, second, third, and fourth semiconductor patterns S1, S2, S3, and S4, which are stacked one on another, may remain on each of the first, second, third, and fourth active patterns AP1, AP2, AP3, and AP4.

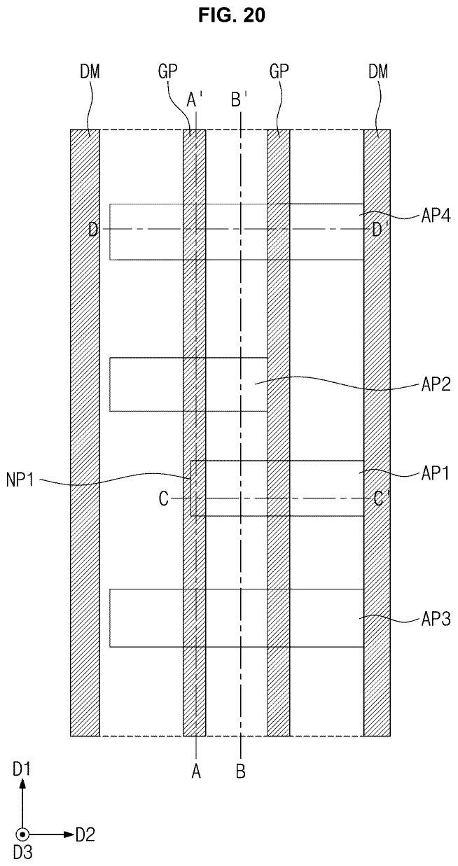

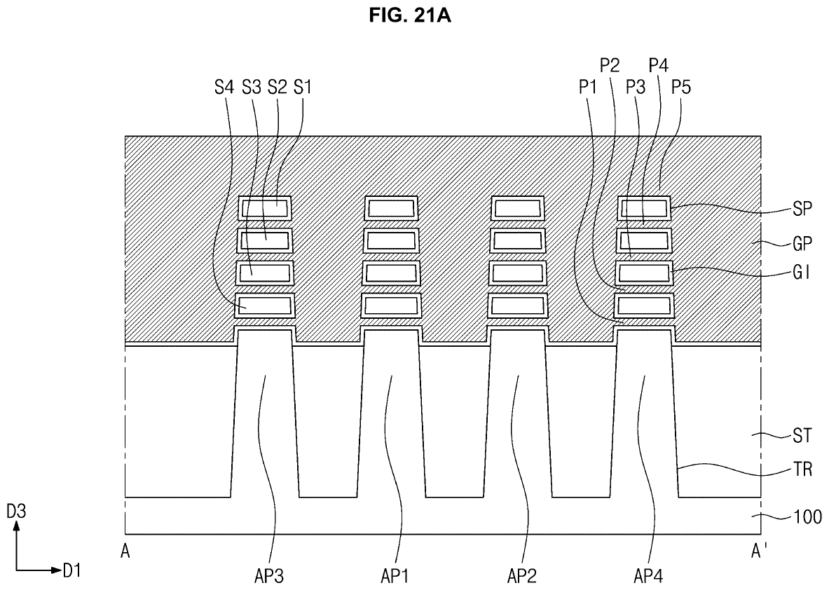

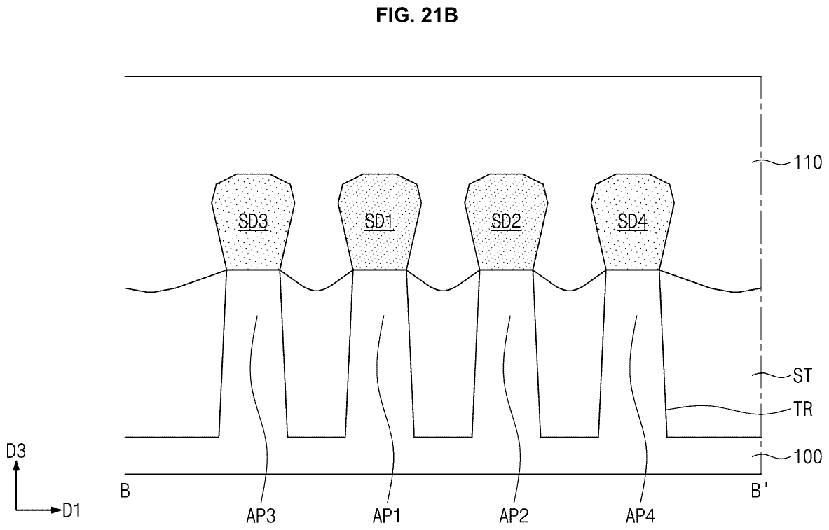

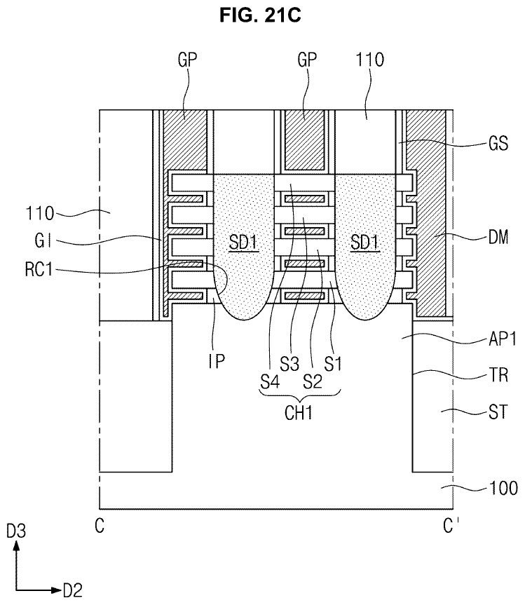

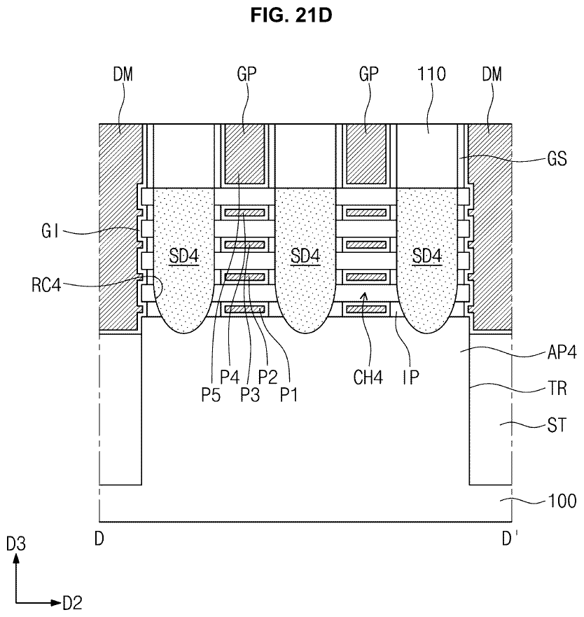

Referring to FIGS. 20 and 21A to 21D, the sacrificial patterns SF may be replaced with gate patterns GP and dummy gate patterns DM. In detail, the gate patterns GP may be formed in the area where the gate sacrificial patterns SF1 are formed, and the dummy gate patterns DM may be formed in the area where the dummy sacrificial patterns SF2 are formed.

The inner spacers IP may be formed in the inner regions on the first, second, third, and fourth active patterns AP1, AP2, AP3, and AP4. The inner spacers IP may be formed by forming the insulating layer covering the first, second, third, and fourth source/drain patterns SD1, SD2, SD3, and SD4 and etching the insulating layer. The inner spacers IP may include at least one of SiO₂, SiN, SiC, SiOC, and AlOx.

The gate insulating layer GI may be conformally formed in the inner region IR (see FIG. 19C and FIG. 19D) and the outer region OR that are exposed above the first, second, third, and fourth active patterns AP1, AP2, AP3, and AP4.

The gate insulating layer GI may include an interfacial layer and a high-k dielectric layer on the interfacial layer. The high-k dielectric layer may be thicker than the interfacial layer. The interfacial layer may include a silicon oxide layer or a silicon oxynitride layer. The high-k dielectric layer may include a high-k material with a higher dielectric constant than silicon oxide. As an example, the high-k material may include at least one of hafnium oxide, hafnium silicon oxide, hafnium zirconium oxide, hafnium tantalum oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, and lead zinc niobate.

The gate patterns GP and the dummy gate patterns DM may be formed on the gate insulating layer GI. The gate patterns GP and the dummy gate patterns DM may be formed to fill the outer region OR and the inner region IR. Each of the gate patterns GP and the dummy gate patterns DM may include the first, second, third, and fourth portions P1, P2, P3, and P4 respectively formed in the inner regions IR and the fifth portion P5 formed in the outer region OR.

The gate patterns GP may include the first metal pattern, the second metal pattern, and the electrode pattern. The first metal pattern may be formed on the gate insulating layer GI. The second metal pattern may be disposed on the first metal pattern. The second metal pattern may include metal carbide with a relatively low work function. The electrode pattern may be disposed on the second metal pattern. The electrode pattern may have a resistance lower than that of the first and second metal patterns.

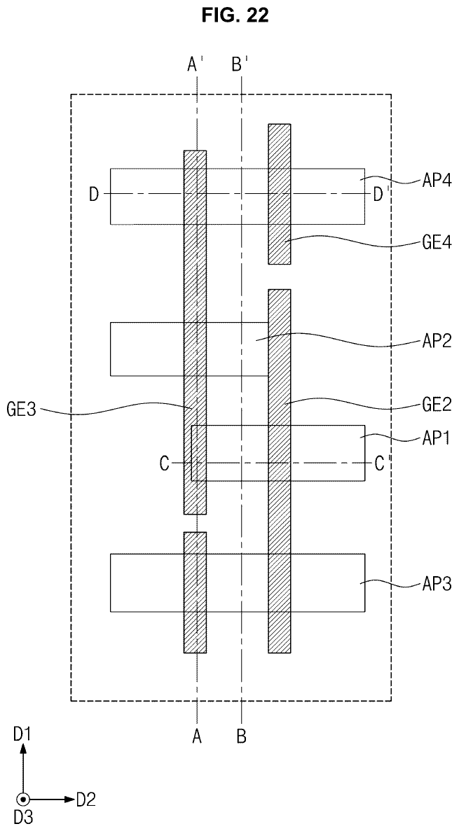

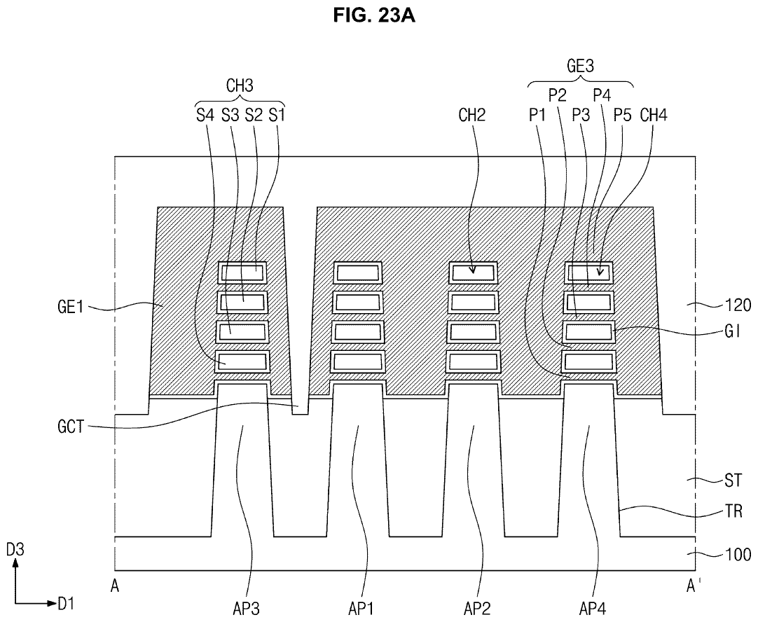

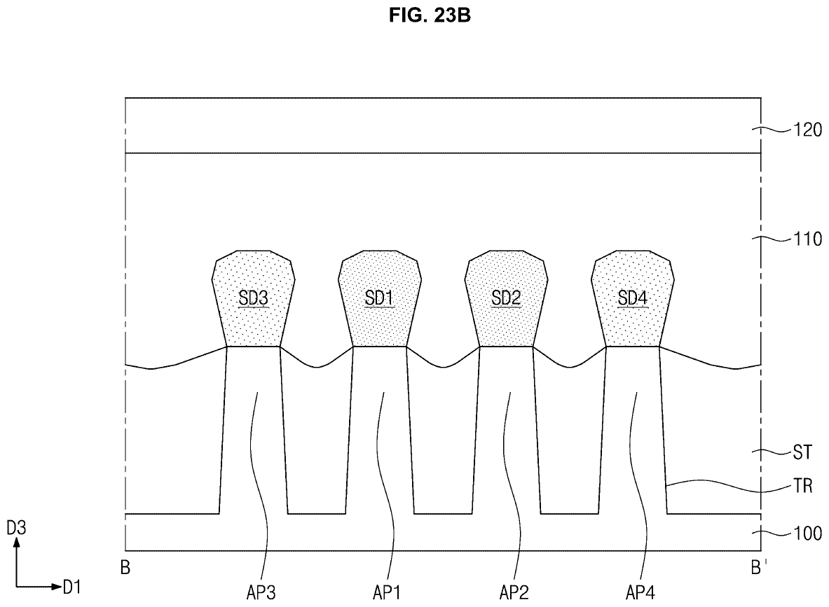

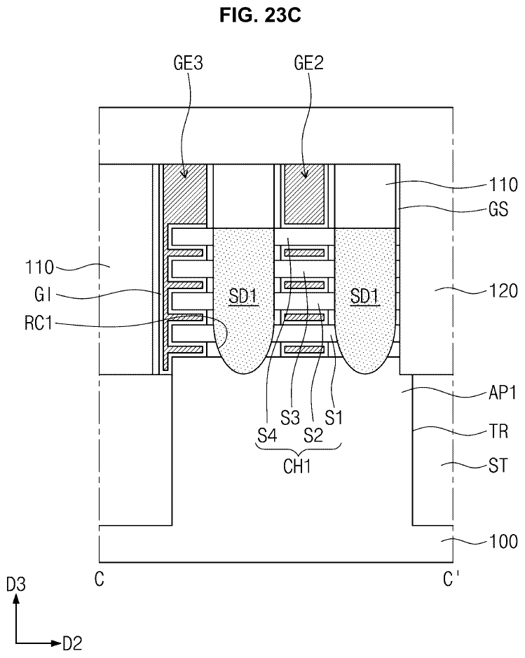

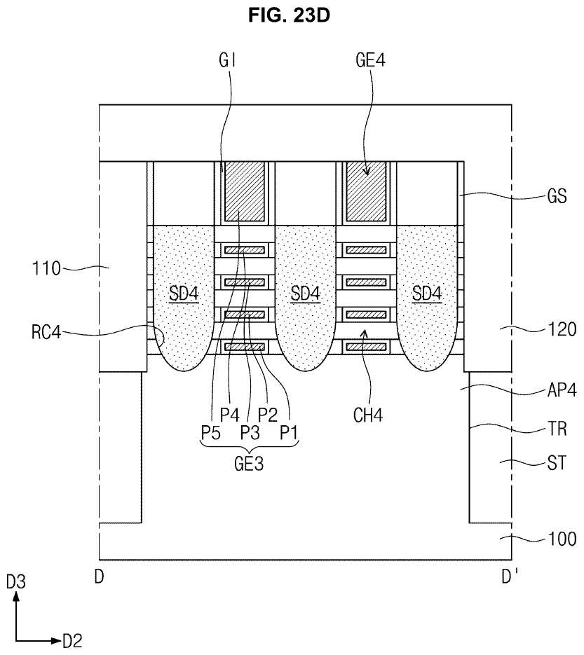

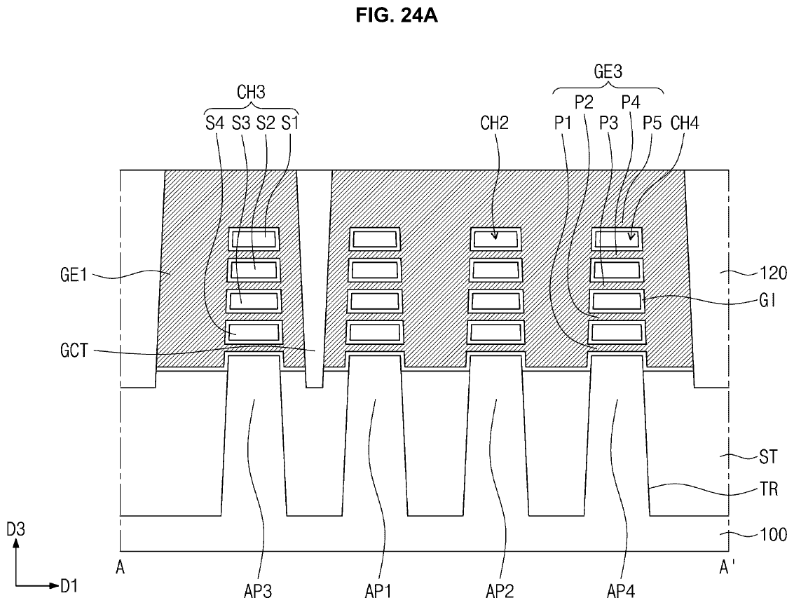

Referring to FIGS. 22 and 23A to 23D, the second interlayer insulating layer 120 may be formed on the substrate 100. A recess to form the gate cutting patterns in the gate cutting region may be formed before the second interlayer insulating layer 120 is formed. In addition, the recesses may be formed in the area where the dummy gate patterns DM are formed to remove the dummy gate patterns DM. According to an embodiment, the recesses may be formed through a dry etching process, however, the present disclosure should not be limited thereto or thereby, and the recesses may be formed through other suitable processes. A bottom surface of the recesses in the gate cutting region and the area where the dummy gate patterns DM are formed may be positioned lower than the upper surface of the device isolation layer ST.

An insulating material may be provided in the recesses and on the substrate 100 to form the second interlayer insulating layer 120. The gate cutting patterns GCT may be formed in the gate cutting region, and the dummy gate patterns DM may be removed. The gate patterns GP may be divided into the first, second, third, and fourth gate electrodes GE1, GE2, GE3, and GE4 by the gate cutting patterns GCT.

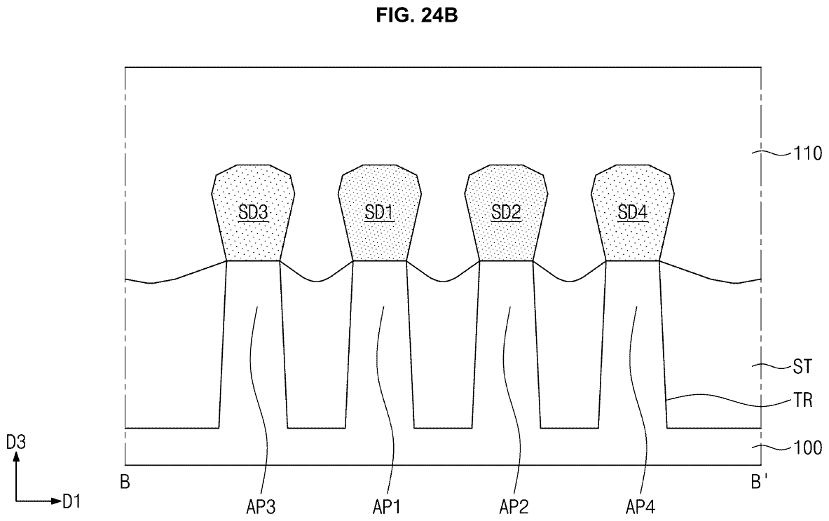

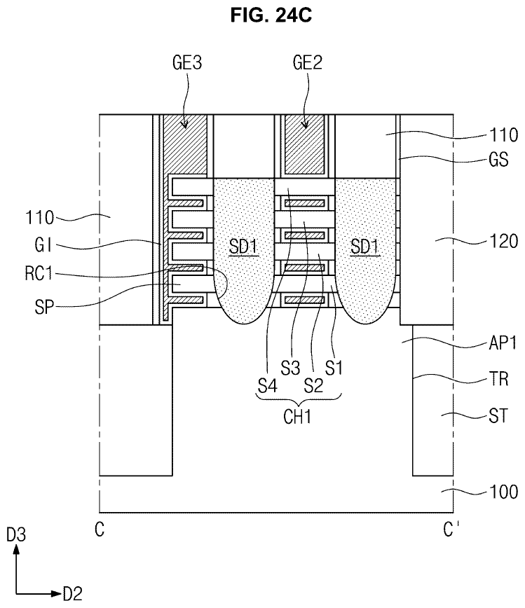

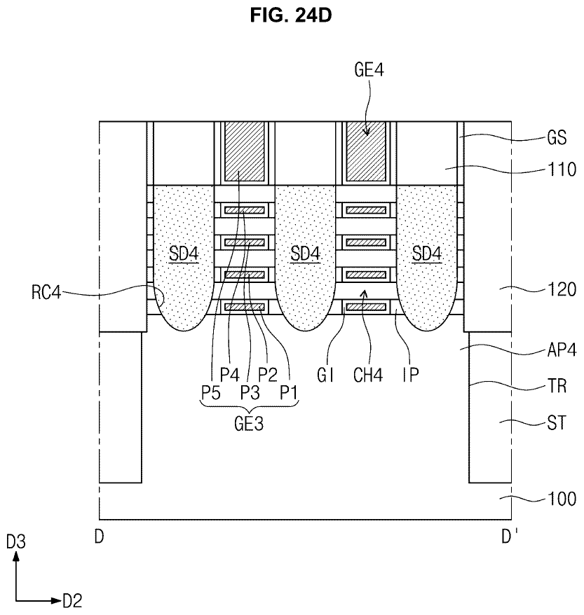

Referring to FIGS. 22 and 24A to 24D, the second interlayer insulating layer 120 may be planarized until the upper surface of the first, second, third, and fourth gate electrodes GE1, GE2, GE3, and GE4 and the upper surface of the first interlayer insulating layer 110 are exposed. The planarization of the second interlayer insulating layer 120 may be performed through an etch back or chemical-mechanical polishing (CMP) process. Consequently, the upper surface of the second interlayer insulating layer 120 may be coplanar with the upper surfaces of the first, second, third, and fourth gate electrodes GE1, GE2, GE3, and GE4 and the upper surface of the first interlayer insulating layer 110.

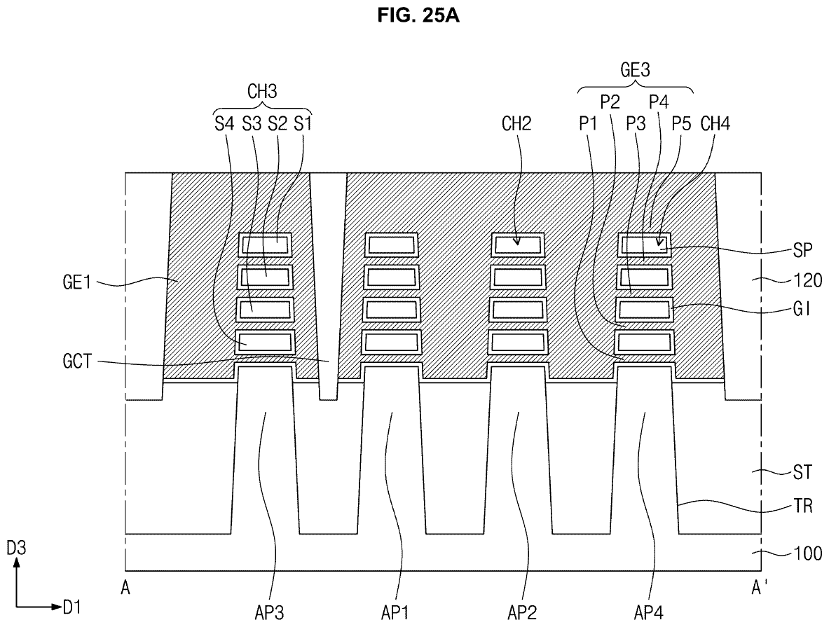

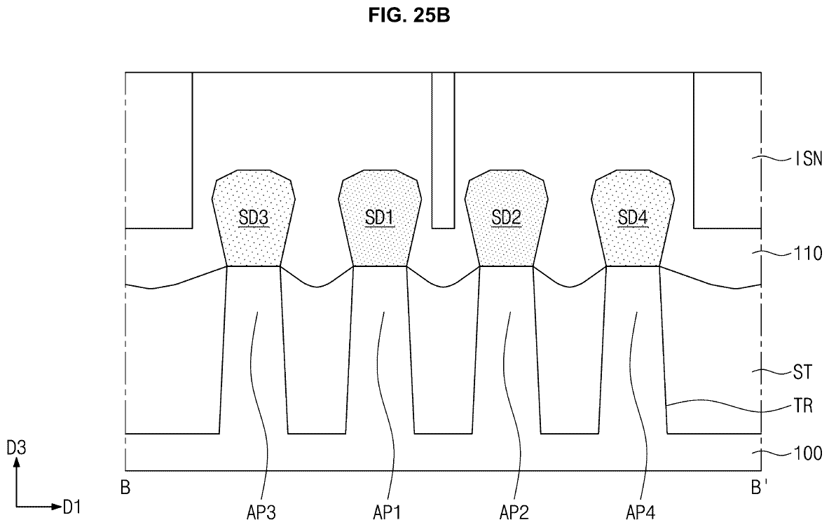

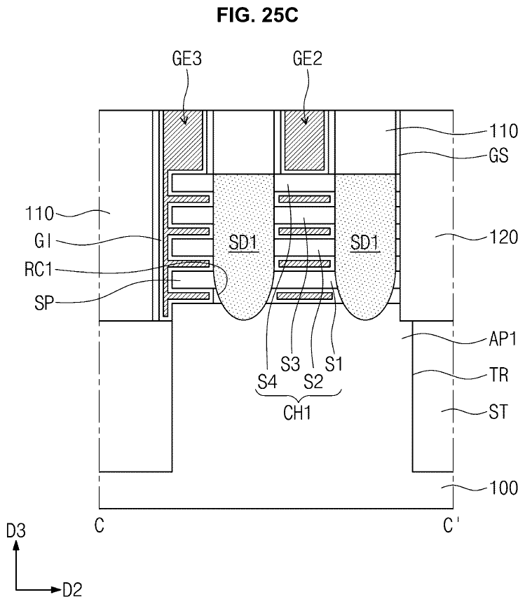

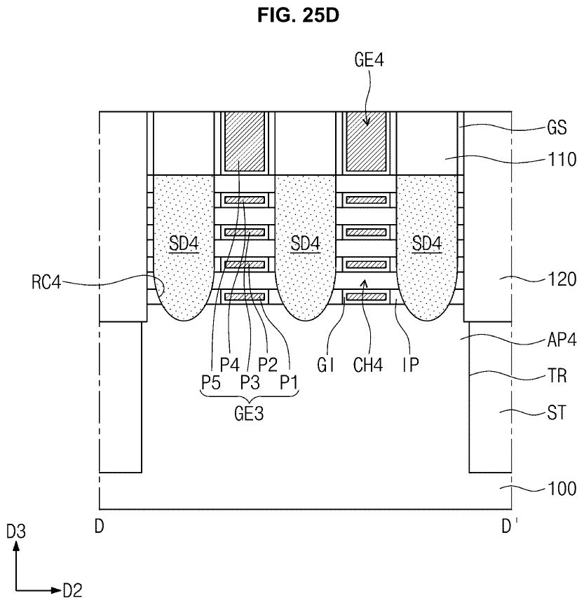

Referring to FIGS. 22 and 25A to 25D, the active contact separation pattern ISN may be formed.

The active contact separation pattern ISN may be formed by forming a plurality of recesses in the first interlayer insulating layer 110 and filling the recesses with an insulating material. The active contact separation patterns ISN may include at least one of SiO₂, SiN, SiC, SiOC, and AlOₓ.

The active contact separation pattern ISN may be planarized until the upper surface of the first interlayer insulating layer 110 is exposed. The planarization of the active contact separation pattern ISN may be performed through an etch back or chemical-mechanical polishing (CMP) process. Consequently, an upper surface of the active contact separation pattern ISN may be coplanar with the upper surface of the first interlayer insulating layer 110. A lower surface of the active contact separation pattern ISN may be positioned higher than the upper surface of the device isolation layer ST and lower than the upper surface of the first and second source/drain patterns SD1 and SD2.

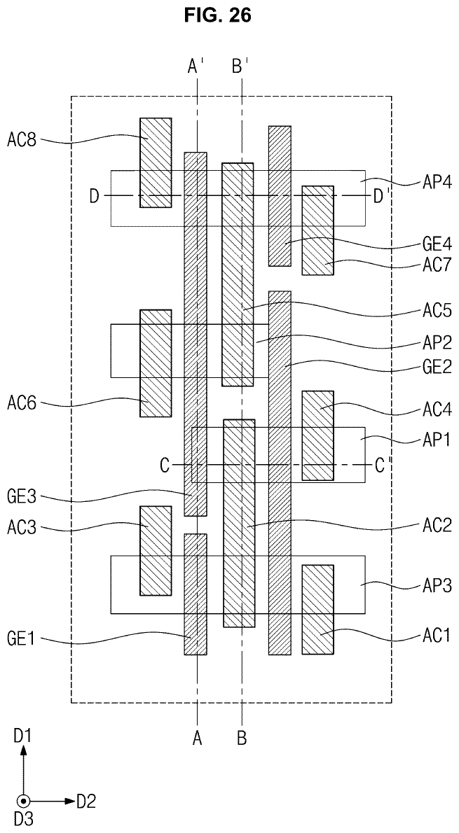

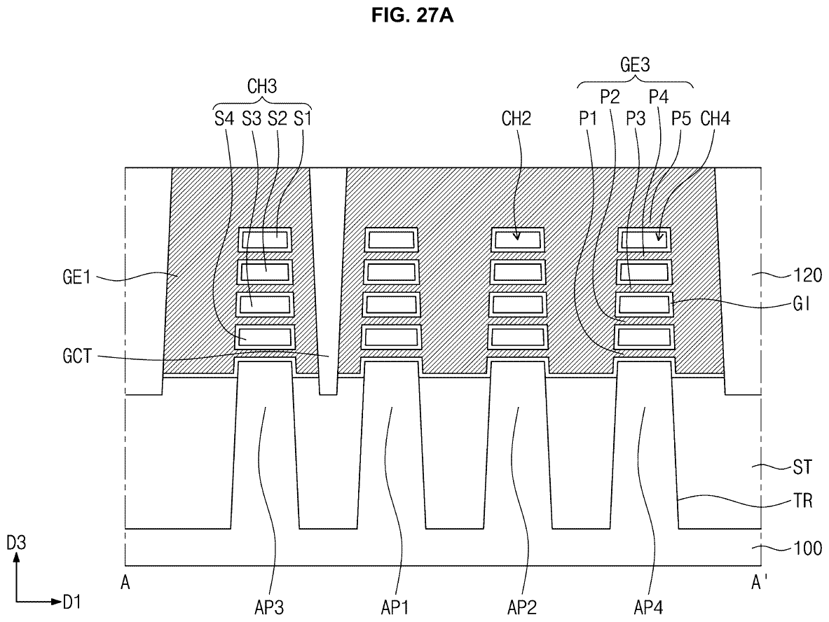

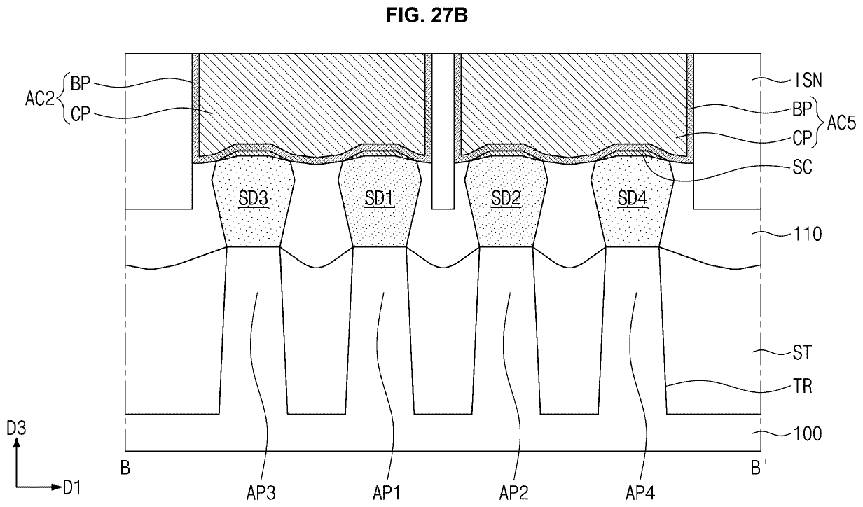

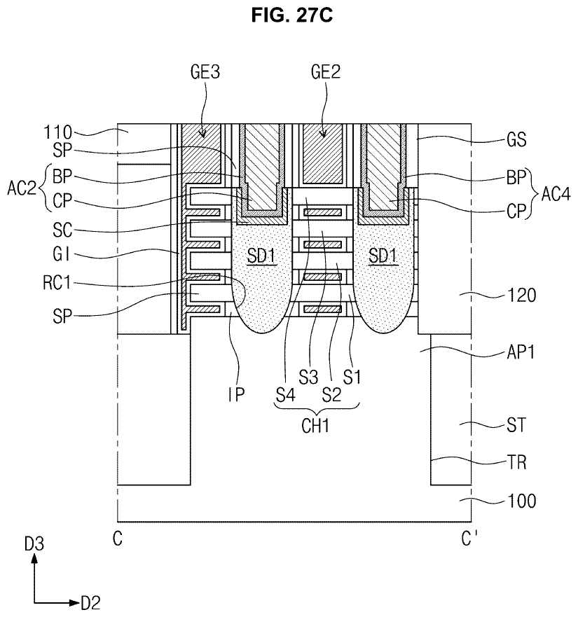

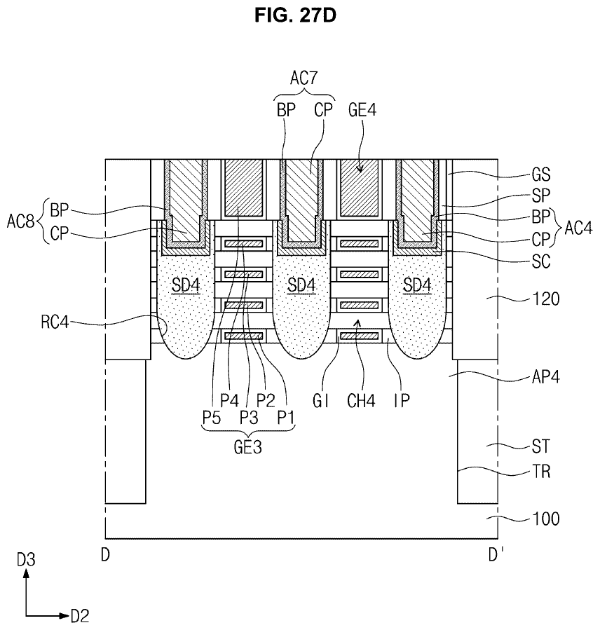

Referring to FIGS. 26 and 27A to 27D, the first interlayer insulating layer 110 disposed between the active contact separation patterns ISN may be removed to expose the first source/drain pattern SD1 to the fourth source/drain pattern SD4, and then, the first to eighth active contacts AC1 to AC8 may be formed on the first source/drain pattern SD1 to the fourth source/drain pattern SD4.

The forming of the first to eighth active contacts AC1 to AC8 may include forming the barrier pattern BP and forming the conductive pattern CP on the barrier pattern BP. The barrier pattern BP may be conformally formed and may include a metal layer/a metal nitride layer. The conductive pattern CP may include a low-resistance metal.

The forming of the first to eighth active contacts AC1 to AC8 may include sequentially forming the barrier pattern BP and the conductive pattern CP and performing the planarization process. The planarization process may be performed until the upper surfaces of the first, second, third, and fourth gate electrodes GE1, GE2, GE3, and GE4 are exposed. The barrier pattern BP may include a metal layer/a metal nitride layer. The conductive pattern CP may include at least one of aluminum, copper, tungsten, molybdenum, and cobalt.

When the first to eighth active contacts AC1 to AC8 are formed, the silicide patterns SC may be formed between each of the active contacts and the first, second, third, and fourth source/drain patterns SD1, SD2, SD3, and SD4, respectively. As an example, the silicide pattern SC may include at least one of titanium-silicide, tantalum-silicide, tungsten-silicide, nickel-silicide, and cobalt-silicide. The spacer SP may be formed on the upper surfaces of the first, second, third, and fourth source/drain patterns SD1, SD2, SD3, and SD4, which are not covered by the silicide patterns SC, and may be disposed between the barrier patterns BP and the gate spacer GS. The spacer SP may also be formed on the silicide pattern SC, and the barrier pattern BP and the conductive pattern CP may be formed on the silicide pattern SC where the spacer SP is not formed.

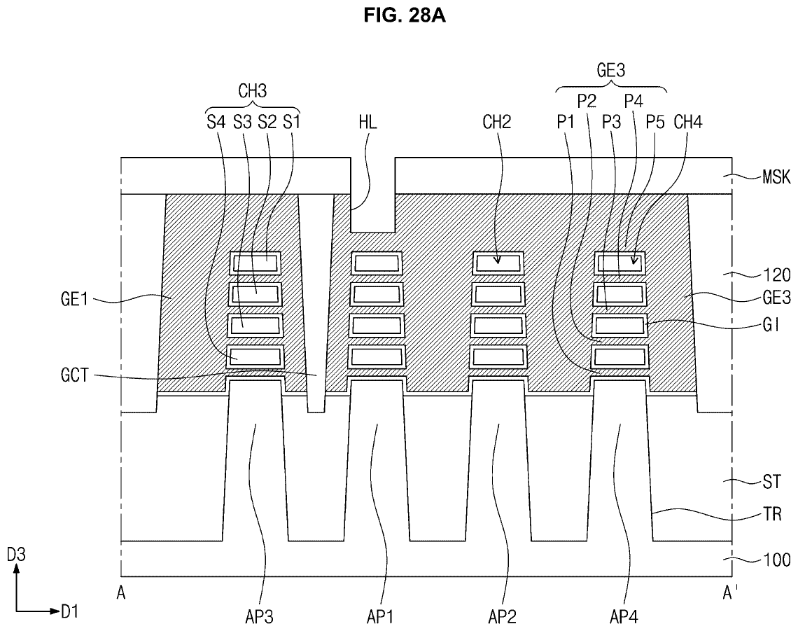

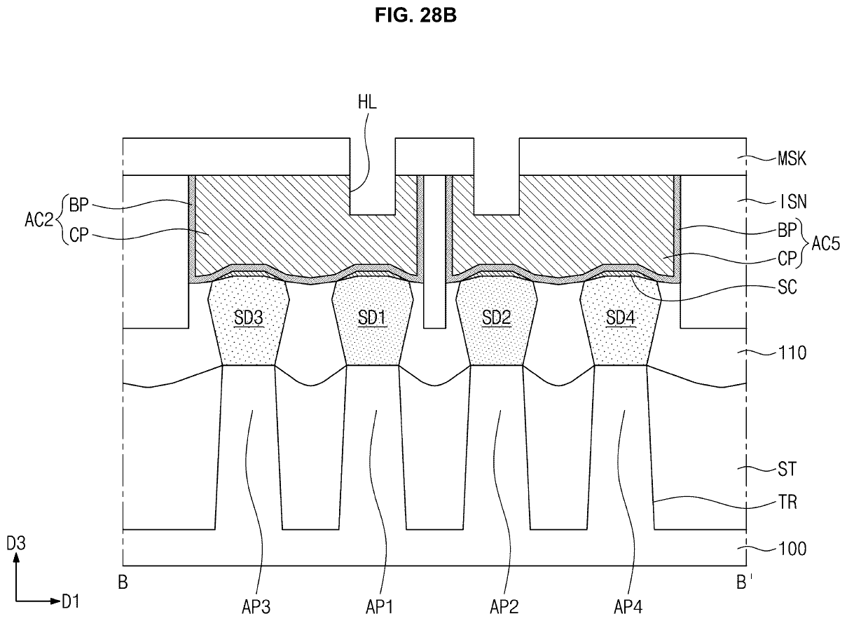

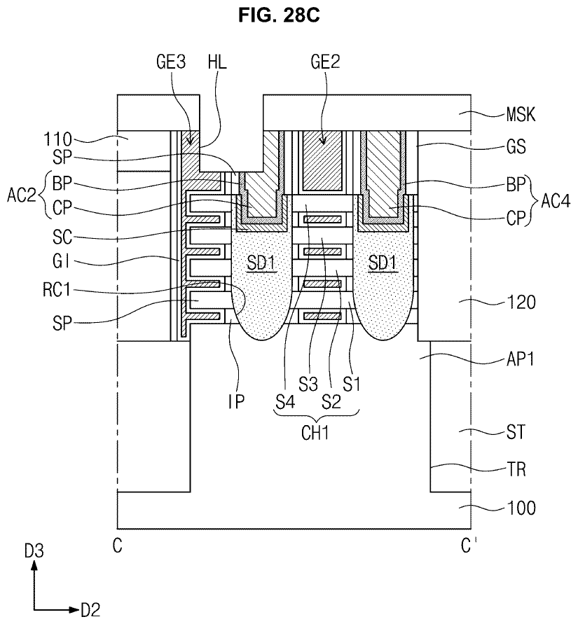

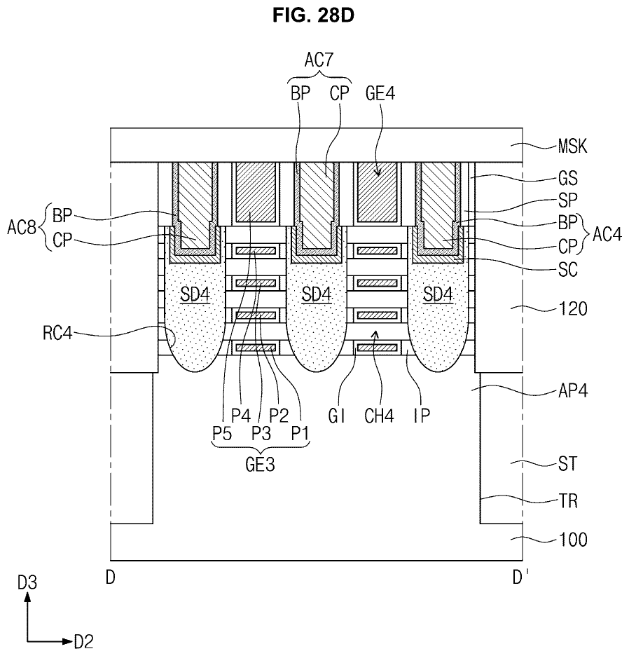

Referring to FIGS. 26 and 28A to 28D, via holes HL may be formed in the second gate electrode GE2 and the third gate electrode GE3. The via holes HL may be respectively defined at positions where the first node connection pattern NP1 and the second node connection pattern NP2 are to be formed. The forming of the via holes HL may be a part of a single damascene process or a part of a general photolithography process.

One of the via holes HL may be formed at a position where the first node connection pattern NP1 is provided, and the other of the via holes HL may be formed at a position where the second node connection pattern NP2 is provided. As an example, the one via hole HL may be formed by removing a portion of the third gate electrode GE3 and a portion of the second active contact AC2. The other via hole HL may be formed by removing a portion of the second gate electrode GE2 and a portion of the fifth active contact AC5. When the portion of the third gate electrode GE3 and the portion of the second active contact AC2 are removed, the gate insulating layer GI and the gate spacer GS between the third gate electrode GE3 and the second active contact AC2 may also be removed. In addition, when the portion of the second gate electrode GE2 and the portion of the fifth active contact AC5 are removed, the gate insulating layer GI and the gate spacer GS between the second gate electrode GE2 and the fifth active contact AC5 may also be removed.

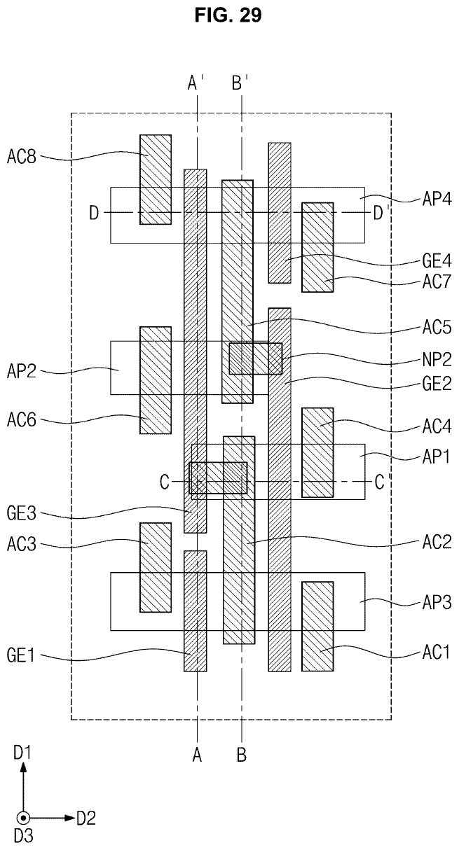

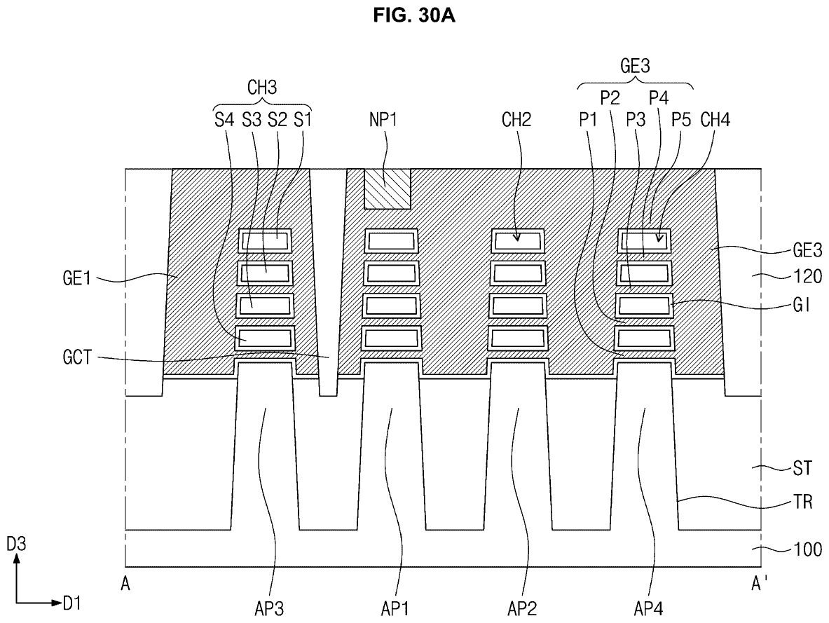

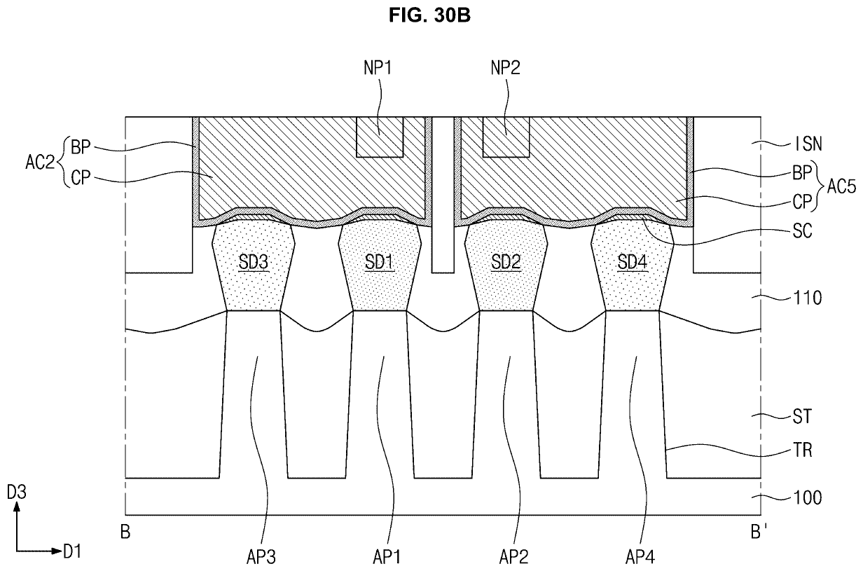

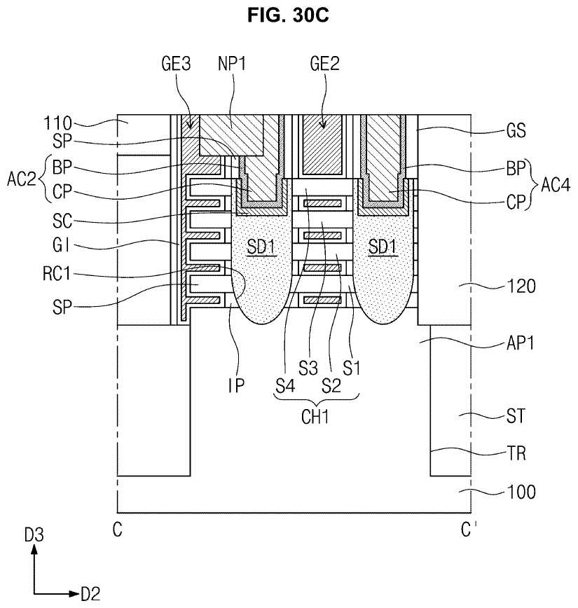

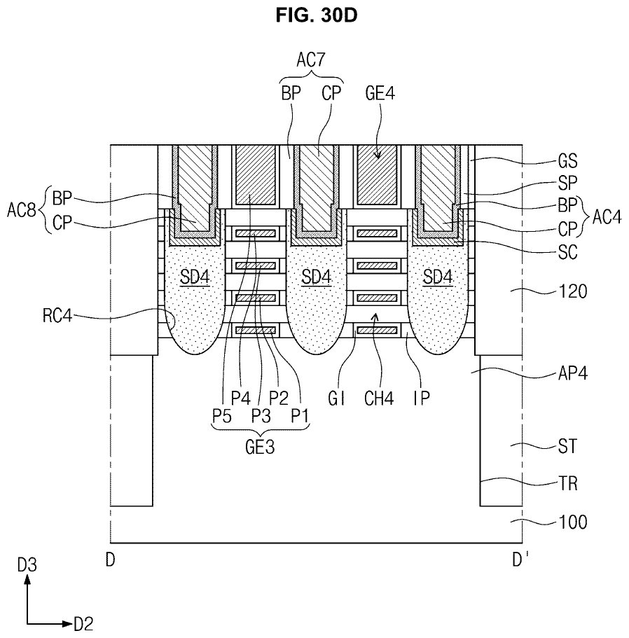

Referring to FIGS. 29 and 30A to 30D, a conductive metal may be filled in the via holes HL to form the first and second node connection patterns NP1 and NP2.

The first and second node connection patterns NP1 and NP2 may be formed through a single damascene process or a general photolithography process. In this case, the barrier pattern BP may be formed before the conductive pattern is formed in the via holes HL, however, the present disclosure should not be limited thereto or thereby. In an embodiment, the conductive pattern may be directly formed in the via holes HL without forming the barrier pattern BP.

Consequently, the first node connection pattern NP1 may connect the third gate electrode GE3 and the second active contact AC2. When viewed in the cross-section, one side surface and a portion of a lower surface of the first node connection pattern NP1 may be in contact with the third gate electrode GE3, and the other side surface and another portion of the lower surface of the first node connection pattern NP1 may be in contact with the second active contact AC2. As an example, the side surface of the first node connection pattern NP1 may be directly in contact with the conductive pattern CP of the second active contact AC2, and the lower surface of the first node connection pattern NP1 may be in contact with the conductive pattern CP and the barrier pattern BP of the second active contact AC2. Although not shown in figures, when viewed in the cross-section, one side surface and a portion of a lower surface of the second node connection pattern NP2 may be in contact with the fifth active contact AC5, and the other side surface and another portion of the lower surface of the second node connection pattern NP2 may be in contact with the second gate electrode GE2. As an example, the side surface of the second node connection pattern NP2 may be directly in contact with the conductive pattern CP of the fifth active contact AC5, and the lower surface of the second node connection pattern NP2 may be in contact with the conductive pattern CP and the barrier pattern BP of the fifth active contact AC5.

After the conductive metal is filled in the via holes HL, the first and second node connection patterns NP1 and NP2 may be planarized until the upper surfaces of the first, second, third, and fourth gate electrodes GE1, GE2, GE3, and GE4 and the upper surfaces of the first to eighth active contacts AC1 to AC8 are exposed. Consequently, the first and second node connection patterns NP1 and NP2 may be coplanar with the upper surfaces of the first, second, third, and fourth gate electrodes GE1, GE2, GE3, and GE4 and the upper surfaces of the first to eighth active contacts AC1 to AC8.

The lower surface of the first node connection pattern NP1 may also be in contact with the gate insulating layer GI and the gate spacer GS. The upper surface of the first node connection pattern NP1 may be coplanar with the upper surface of the third gate electrode GE3 and the upper surface of the second active contact AC2.

Referring to FIGS. 29 and 31A to 31D, the pillars PL may be formed on the first, second, third, and fourth gate electrodes GE1, GE2, GE3, and GE4 and the first to eighth active contacts AC1 to AC8 to form the first vias V1. The pillars PL may be disposed in areas where the first vias V1 are to be provided. The pillars PL may also be disposed on the first and second node connection patterns NP1 and NP2, a portion of the upper surfaces of the second and third gate electrodes GE2 and GE3 adjacent to the first and second node connection patterns NP1 and NP2, and a portion of the upper surfaces of the second and fifth active contacts AC2 and AC5. The pillars PL disposed on the first and second node connection patterns NP1 and NP2 may protect the first and second node connection patterns NP1 and NP2 during the subsequent etching process.

The pillars PL may include at least one of photoresist, silicon nitride, silicon oxide, and silicon oxynitride.

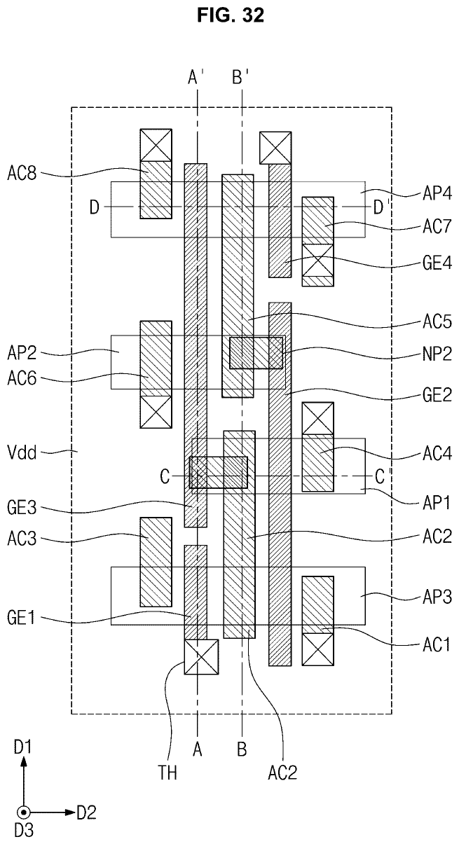

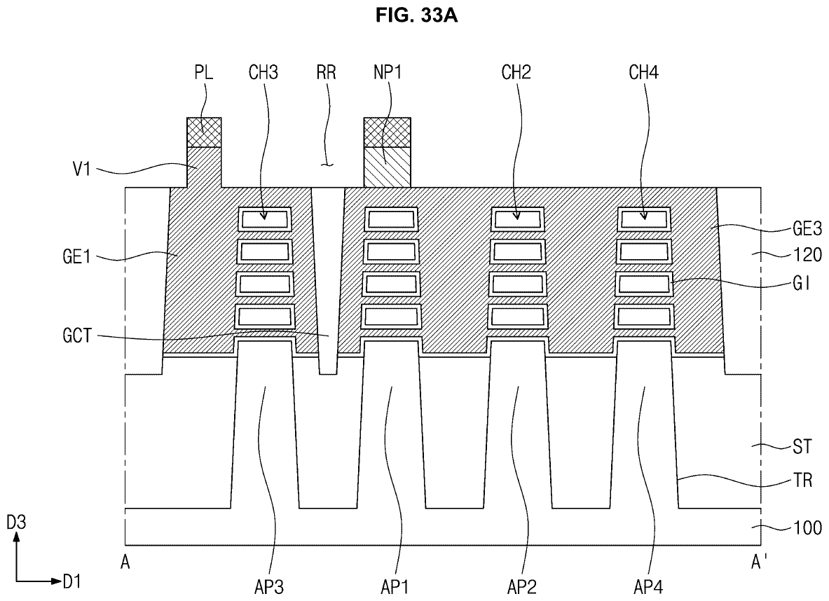

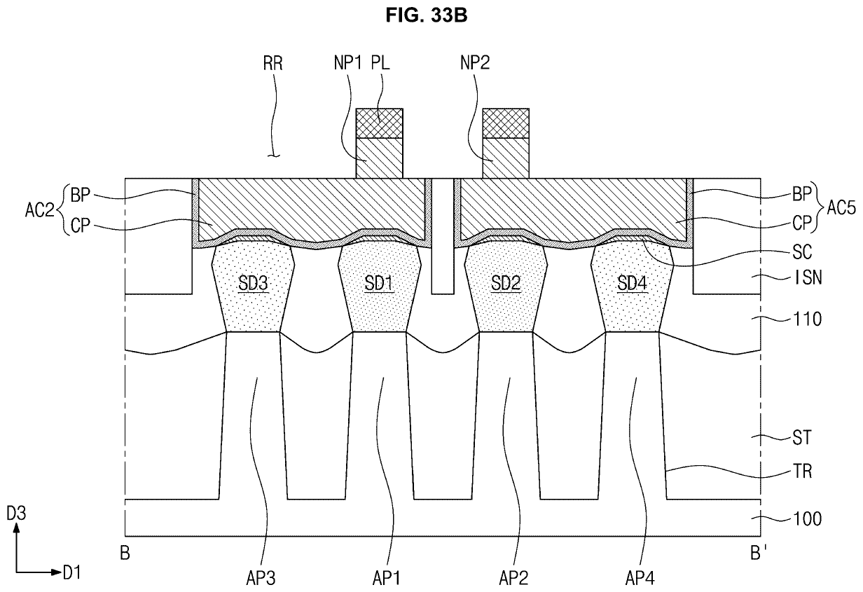

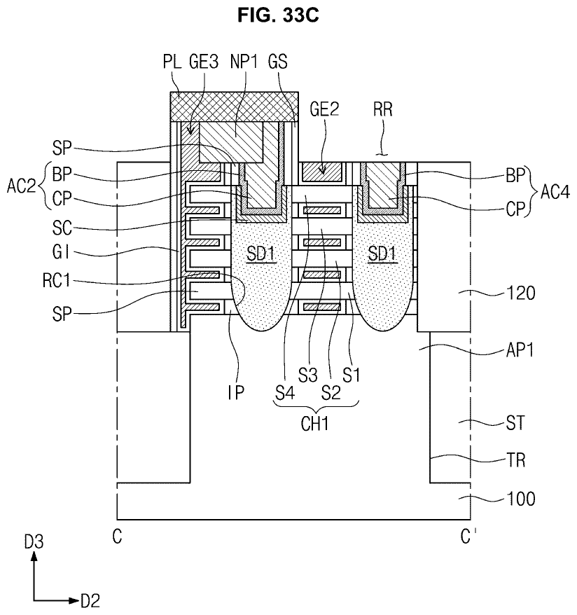

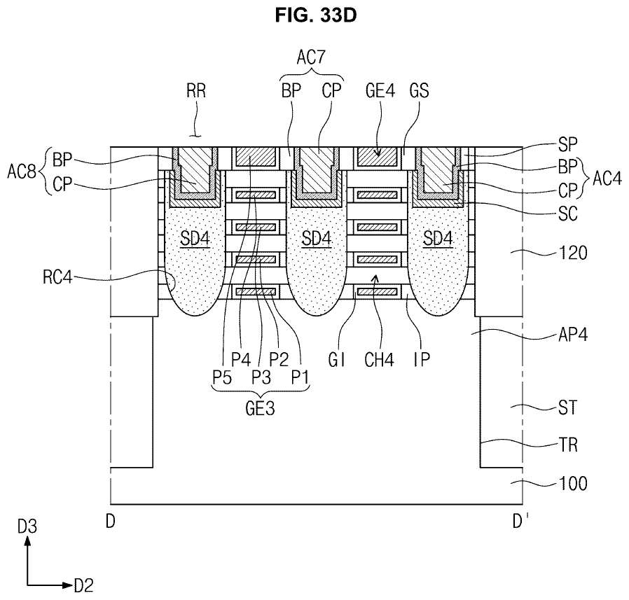

Referring to FIGS. 32 and 33A to 33D, upper portions of the first to fourth gate electrodes GE1, GE2, GE3, and GE4 and upper portions of the first to eighth active contacts AC1 to AC8, which are exposed due to the absence of the pillars PL, may be etched to form the recess region RR. As a result, the first vias V1 may protrude from the upper portion of the first, second, third, and fourth gate electrodes GE1, GE2, GE3, and GE4 and the upper portion of the first to eighth active contacts AC1 to AC8.

The recess region RR may be formed through a dry etching process and/or a wet etching process. According to an embodiment, the recess region may be formed through a non-selective etch process.

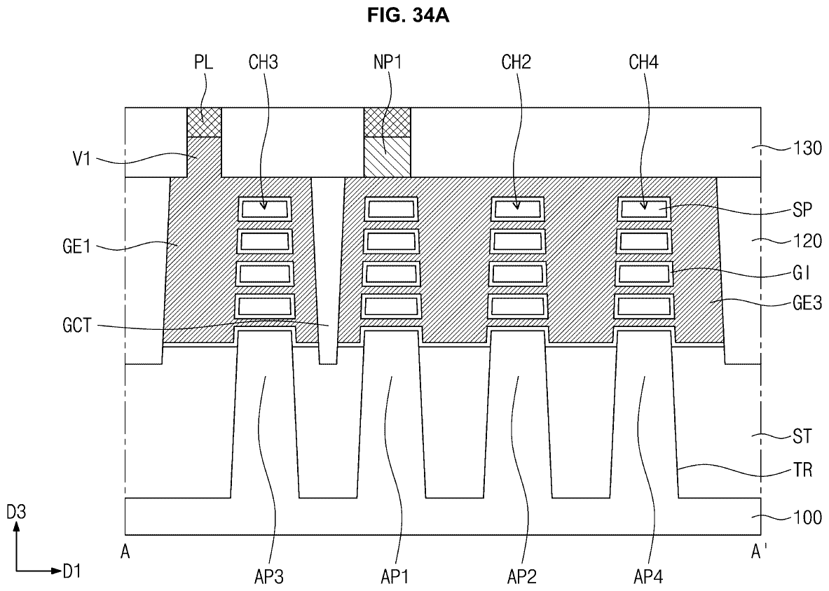

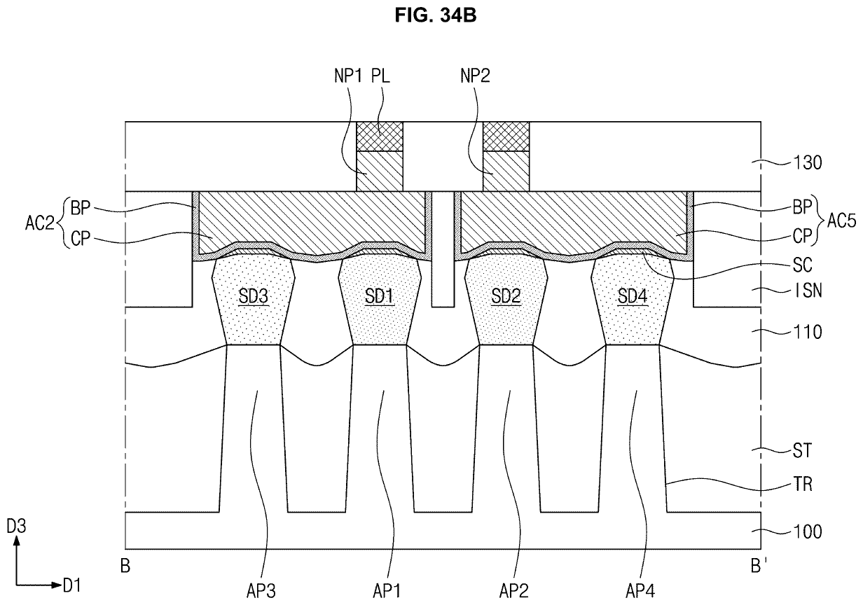

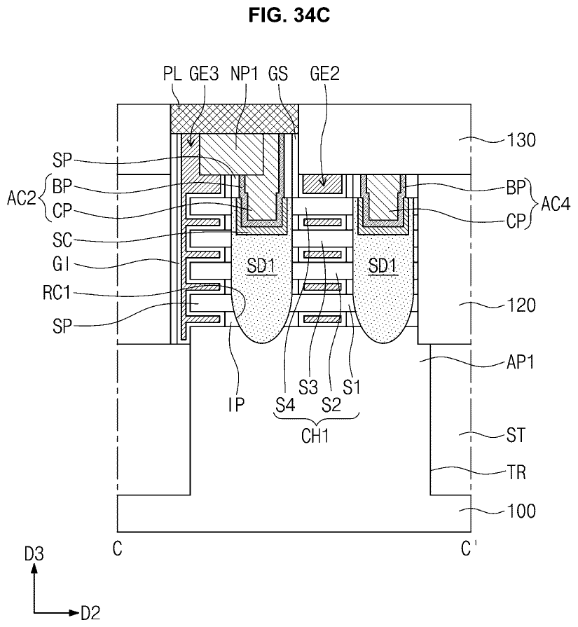

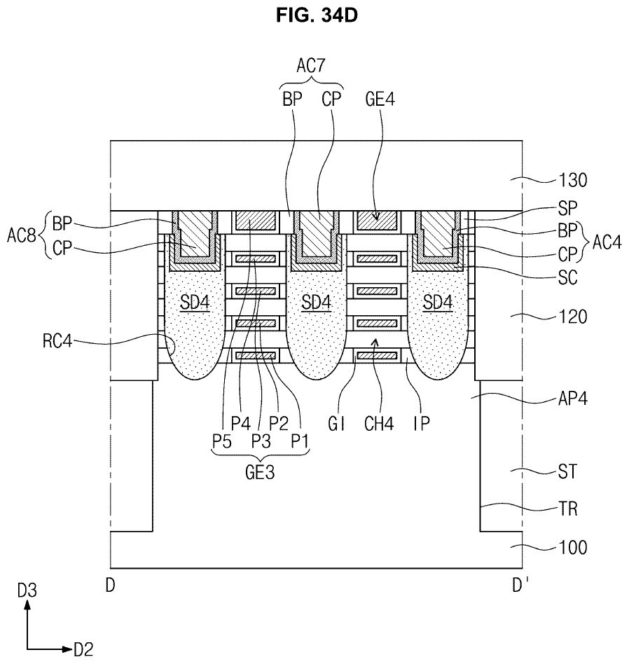

Referring to FIGS. 32 and 34A to 34D, an insulating layer may be formed to fill the recess region RR with the pillars PL maintained, and then, a planarization process may be performed on the insulating layer to form the third interlayer insulating layer 130. The upper surface of the third interlayer insulating layer 130 may be positioned at the same level as the upper surfaces of the pillars PL. The third interlayer insulating layer 130 may include at least one of the SiO₂, SiN, SiC, SiOC, and AlOₓ.

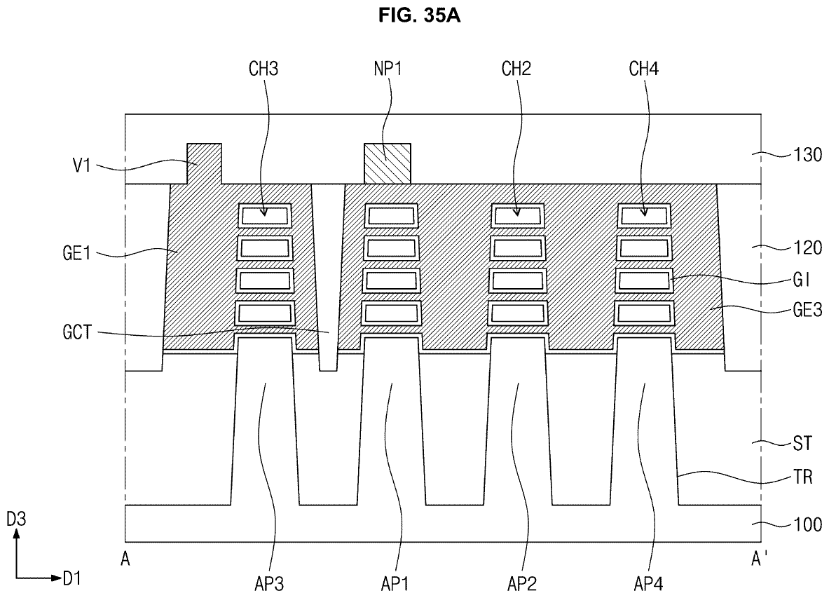

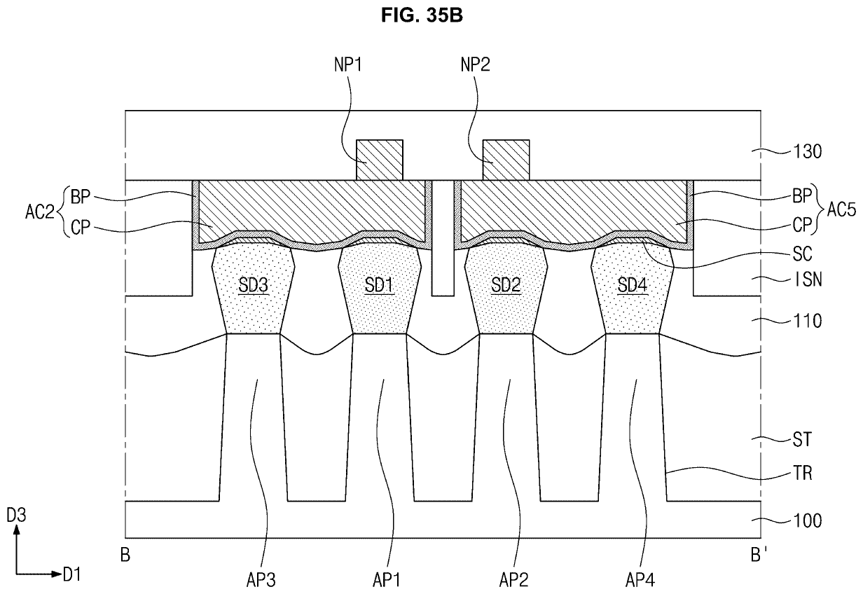

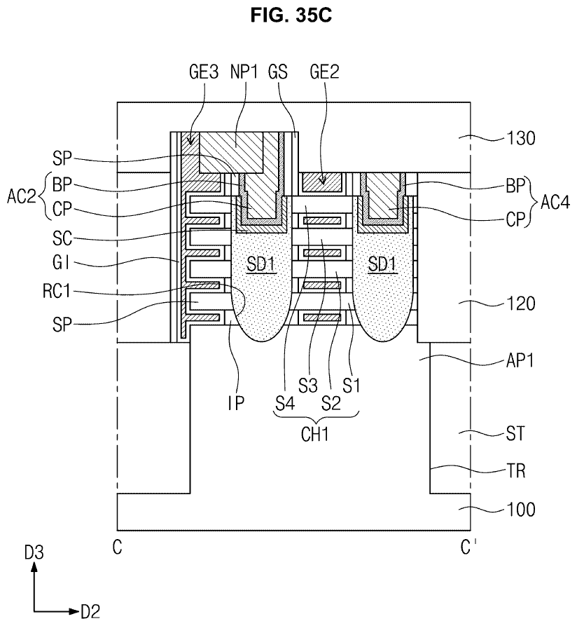

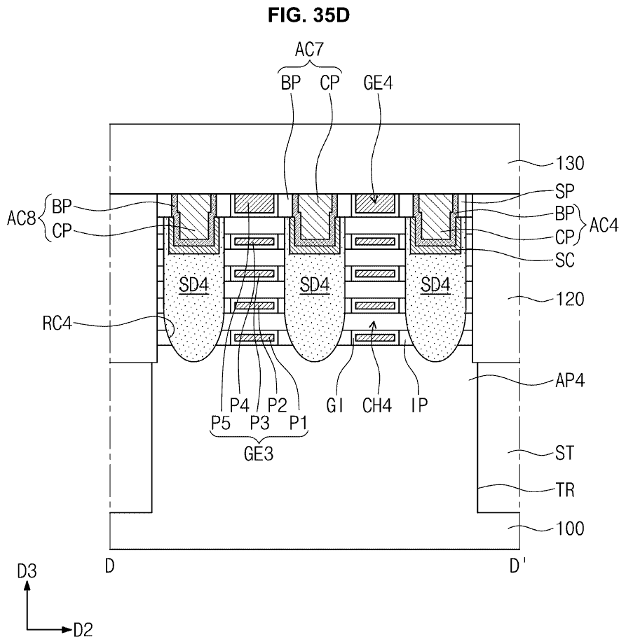

Referring to FIGS. 32 and 35A to 35D, after the pillars PL are removed, an insulating layer is formed to fill the areas from which the pillars PL are removed, and a planarization process may be performed. When viewed in the plane, the areas from which the pillars PL are removed may correspond to an area overlapping the first vias V1 and an area overlapping the first and second node connection patterns NP1 and NP2.

According to an embodiment, the insulating layer filled in the areas from which the pillars PL are removed may include the same material as the third interlayer insulating layer 130. The insulating layer filled in the areas from which the pillars PL are removed may become integral with the third interlayer insulating layer 130. Consequently, the upper surfaces of the first vias V1 and the upper surfaces of the first and second node connection patterns NP1 and NP2 may be covered by the third interlayer insulating layer 130.

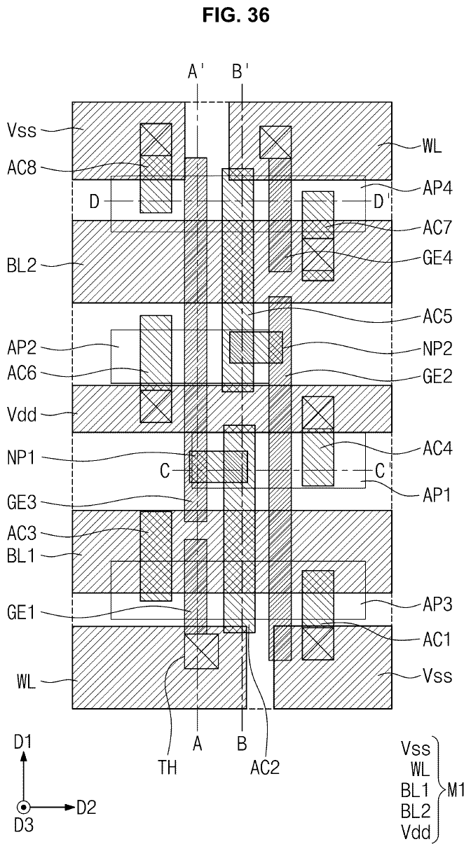

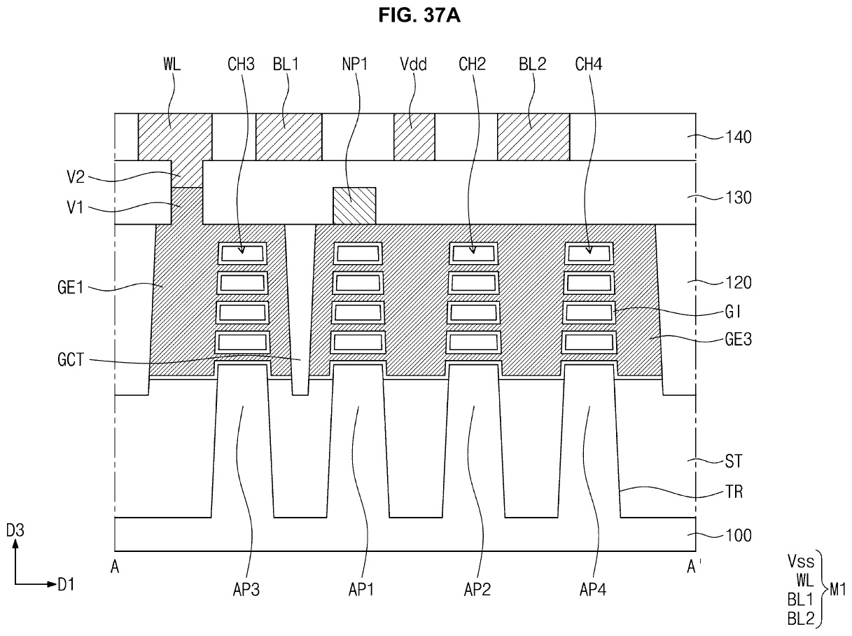

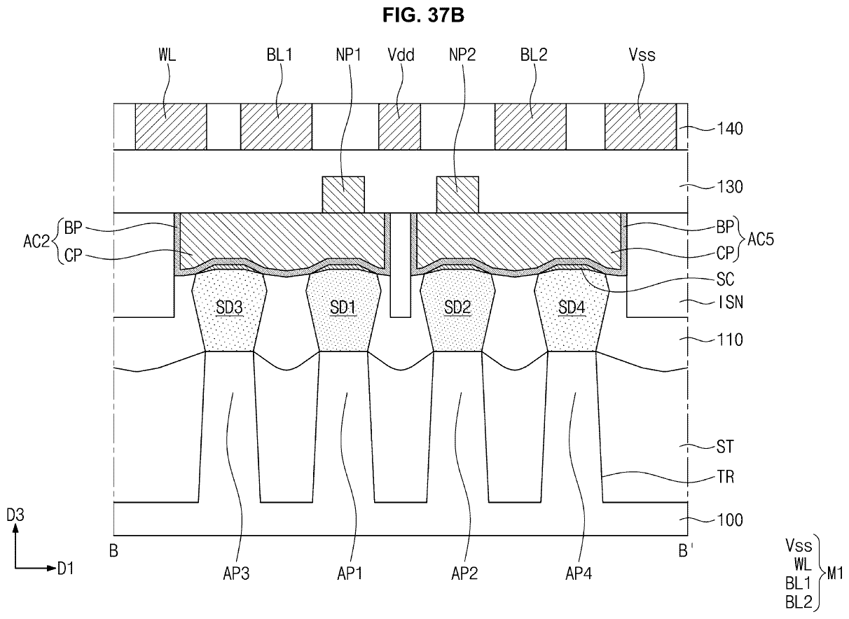

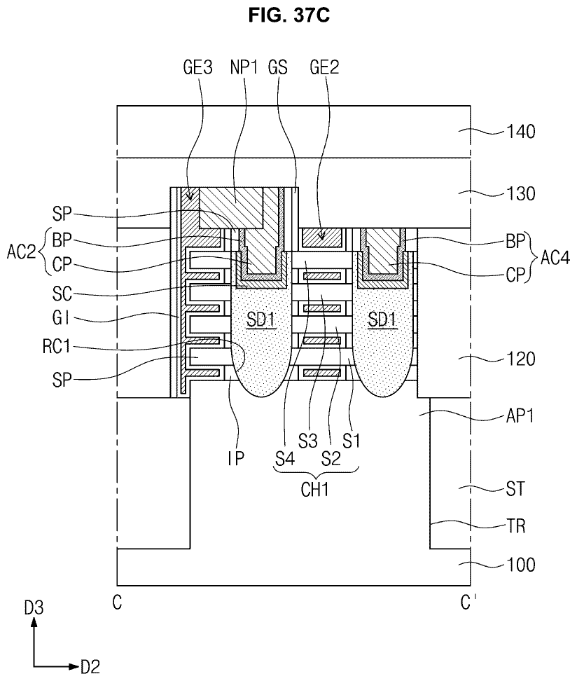

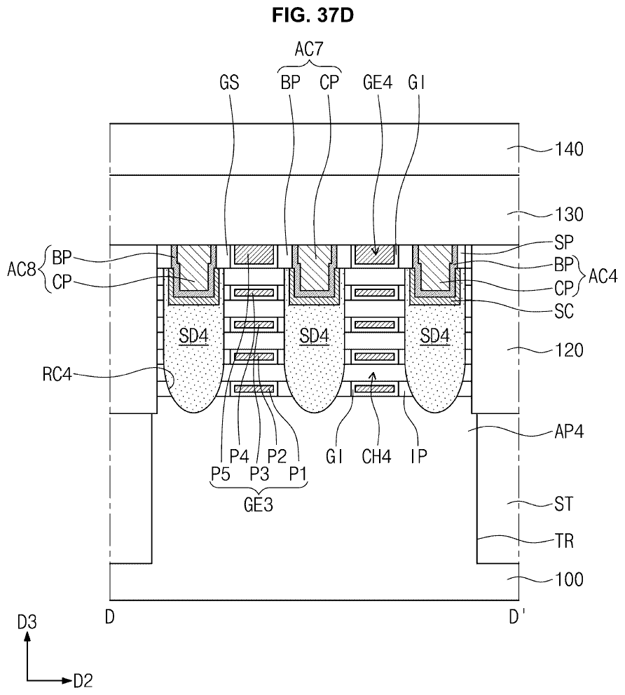

Referring to FIGS. 36 and 37A to 37D, the fourth interlayer insulating layer 140 may be formed on the third interlayer insulating layer 130. The second vias V2 and the first wiring layer M1 may be formed in the fourth interlayer insulating layer 140. The first wiring layer M1 may include the word line WL, the power line Vdd, the ground line Vss, and the first and second bit lines BL1 and BL2. The second vias V2 and the first wiring layer M1 may be formed together by a dual damascene process. The second vias V2 may be formed to correspond to areas where the first vias V1 are disposed.

The first wiring layer M1 may include at least one metal material selected from aluminum, copper, tungsten, molybdenum, and cobalt.

Although the embodiments of the present disclosure have been described, it is understood that the present disclosure should not be limited to these embodiments but various changes and modifications can be made by one ordinary skilled in the art within the spirit and scope of the present disclosure as hereinafter claimed. As an example, while embodiments described in this disclosure are described in the context of MBCFETs or forksheet FETs; however, the implementations of the above-described embodiments of the present disclosure may also be applied to other processes and/or other devices having at least some different configurations from the aforementioned embodiments, such as planar FETs, Fin-FETs, horizontal gate all around (HGAA) FETs, vertical gate all around (VGAA) FETs, and other suitable devices.

Therefore, the disclosed subject matter should not be limited to any single embodiment described herein, and the scope of the present inventive concept shall be determined according to the attached claims.

What is claimed is:

1. A semiconductor device comprising:
active patterns disposed on a front surface of a substrate;
source/drain patterns disposed on the active patterns;
channel patterns disposed on the active patterns and connected to the source/drain patterns;
gate electrodes disposed on the channel patterns;
active contacts disposed on the source/drain patterns;
an interlayer insulating layer disposed on the gate electrodes;
a first wiring layer disposed on the interlayer insulating layer and comprising a plurality of lines; and
a node connection pattern connected to the gate electrode on one of the active patterns and the active contact on another of the active patterns,
wherein the interlayer insulating layer is disposed between the first wiring layer and the node connection pattern to insulate the node connection pattern from the first wiring layer, and
a level of an upper surface of the node connection pattern is different from levels of upper surfaces of other active contacts that are not connected to the node connection pattern.

2. The semiconductor device of claim 1, wherein the upper surface of the node connection pattern is coplanar with an upper surface of the gate electrode connected to the node connection pattern and an upper surface of the active contact connected to the node connection pattern.

3. The semiconductor device of claim 1, wherein the node connection pattern comprises:
a first node connection pattern connected to the gate electrode on the one active pattern and the active contact on the another active pattern; and
a second node connection pattern connected to the gate electrode on the another active pattern and the active contact on the one active pattern.

4. The semiconductor device of claim 1, further comprising a gate insulating layer interposed between the gate electrodes and the channel patterns,
wherein the gate insulating layer extends between the gate electrode on the one of the active patterns and the active contact on the another of the active pattern, and an upper end of an extension portion of the gate insulating layer is in contact with a lower surface of the node connection pattern.

5. The semiconductor device of claim 1, wherein each of the active contacts comprises a conductive pattern and a barrier pattern surrounding the conductive pattern, and a lower surface of the node connection pattern is in contact with an upper end of at least a portion of the barrier pattern of the active contact connected to the node connection pattern.

6. The semiconductor device of claim 1, wherein the interlayer insulating layer comprises:
a main interlayer insulating layer disposed between the node connection pattern and the first wiring layer and disposed on the node connection pattern; and
a recess filling layer disposed between the main interlayer insulating layer and the upper surface of the active contact that is not connected to the node connection pattern, and
the main interlayer insulating layer and the recess filling layer are provided integrally with each other without being separated from each other.

7. The semiconductor device of claim 1, wherein at least a portion of the node connection pattern overlaps at least one of lines of the first wiring layer in a plane view.

8. The semiconductor device of claim 1, wherein each of the channel patterns comprises a plurality of semiconductor patterns vertically stacked and spaced apart from each other, and each of the gate electrodes surrounds each of the semiconductor patterns of a corresponding channel pattern among the channel patterns.

9. The semiconductor device of claim 1, further comprising:
a rear surface wiring layer disposed on a rear surface of the substrate and comprising at least one wiring; and
a rear surface via connected to the at least one wiring of the rear surface wiring layer, wherein the at least one wiring of the rear surface wiring layer is electrically connected to one of the source/drain patterns through the rear surface via.

10. The semiconductor device of claim 9, wherein the at least one wiring of the rear surface wiring layer is a power line.

11. The semiconductor device of claim 1, wherein at least one of the gate electrodes comprises a first via penetrating through a lower portion of the interlayer insulating layer, and at least one of the plurality of lines of the first wiring layer comprises a second via penetrating through an upper portion of the interlayer insulating layer and connected to the first via.

12. The semiconductor device of claim 1, wherein the active patterns comprise first and second active patterns arranged in PMOS transistor areas and third and fourth active patterns arranged in NMOS transistor areas, the channel patterns comprise first and second channel patterns arranged in the PMOS transistor areas and third and fourth channel patterns arranged in the NMOS transistor areas, and the third channel pattern, the first channel pattern, the second channel pattern, and the fourth channel pattern are sequentially arranged along a first direction.

13. The semiconductor device of claim 12, further comprising at least one dielectric wall disposed between two channel patterns adjacent to each other among the third channel pattern, the first channel pattern, the second channel pattern, and the fourth channel pattern.

14. The semiconductor device of claim 13, wherein the gate electrodes comprise:
first and second sub-gate electrodes, between which the at least one dielectric is disposed; and
a bridge disposed on the dielectric wall and connecting the first sub-gate electrode and the second sub-gate electrode.

15. The semiconductor device of claim 12, further comprising:
a rear surface wiring layer disposed on a rear surface of the substrate and comprising at least one wiring; and
a rear surface via connected to the at least one wiring of the rear surface wiring layer, wherein the at least one wiring of the rear surface wiring layer is connected to one of first, second, third, and fourth source/drain patterns through the rear surface via.

16. The semiconductor device of claim 15, wherein the at least one wiring of the rear surface wiring layer is a power line.

17. A semiconductor device comprising:
first and second active patterns disposed on a PMOS area of a substrate;
third and fourth active patterns disposed on an NMOS area of the substrate;
first, second, third, and fourth source/drain patterns disposed on the first, second, third, and fourth active patterns;
active contacts disposed on the first to fourth source/drain patterns;
first, second, third, and fourth channel patterns disposed on the first, second, third, and fourth active patterns;
a first common gate electrode crossing the first and third active patterns and covering the first and third channel patterns;
a second common gate electrode crossing the second and fourth active patterns and covering the second and fourth channel patterns;
a first node contact connecting the second common gate electrode and the active contact on the first source/drain pattern adjacent to the second common gate electrode;
a second node contact connecting the first common gate electrode and the active contact on the second source/drain pattern adjacent to the first common gate electrode;
an interlayer insulating layer disposed on the first and second common gate electrodes; and
a first wiring layer disposed on the interlayer insulating layer and comprising a plurality of wirings,
wherein levels of upper surfaces of the first and second node contacts are different from levels of upper surfaces of other active contacts that are not connected to the first and second node contacts.

18. The semiconductor device of claim 17, wherein at least one of the first and second node contacts overlaps at least one of the plurality of wirings of the first wiring layer.

19. A semiconductor device comprising:
active patterns disposed on a front surface of a substrate;
source/drain patterns disposed on the active patterns;
channel patterns disposed on the active patterns and connected to the source/drain patterns;
gate electrodes disposed on the channel patterns;
active contacts disposed on the source/drain patterns;
an interlayer insulating layer disposed on the gate electrodes;
a wiring layer disposed on the interlayer insulating layer and comprising a plurality of lines; and
a node connection pattern connected to the gate electrode on one of the active patterns and the active contact on another of the active patterns,
wherein the interlayer insulating layer is disposed between the wiring layer and the node connection pattern, and
the active contact connected to the node connection pattern protrudes further than one of the active contacts not connected to the node connection pattern, with respect to the substrate.

20. The semiconductor device of claim 19, further comprising a spacer covering a side surface of the active contact such that a portion of the spacer is disposed between the active contact and the interlayer insulating layer.
